(19) United States
(12) Patent Application Publication
(10) Pub. No.: US 2026/0050719 A1
(43) Pub. Date: Feb. 19, 2026

(54) Digital Twin Agricultural Simulation System for Crop Growth Modeling and Prediction

(71) Applicant: Farmer's Business Network, Inc., San Carlos, CA (US)

(72) Inventors: Matthew Meisner, San Francisco, CA (US); Steele Dennison Lorenz, San Francisco, CA (US); Christopher H. Barron, San Francisco, CA (US); Michael Sesko, Fairfax, CA (US); Rebecca Willison, Manchester, MO (US); Edward Rowe, Los Altos, CA (US); Jose Maria Peschiera, Pinecrest, FL (US); Charles Blair Baron, Omaha, NE (US); Walter T. Dado, Santa Monica, CA (US); Graham Jeffries, Rockland, ME (US); Alexander Macdonald, San Francisco, CA (US)

(21) Appl. No.: 19/331,733

(22) Filed: Sep. 17, 2025

Related U.S. Application Data
(63) Continuation of application No. PCT/US2024/028960, filed on May 10, 2024.
(60) Provisional application No. 63/501,442, filed on May 11, 2023.

(51) Int. Cl. G06F 30/27

(52) U.S. Cl. CPC G06F 30/27

(57) ABSTRACT

A crop growth modeling system includes a memory configured to store computer-readable instructions. The instructions cause to the system to use a digital twin component configured to create and manage a digital twin of a farm. The instructions cause to the system to use a data input component configured to receive data related to a defined set of land characteristics and environmental attributes for the farm. The instructions cause to the system to use a processing component configured to integrate the received data with the digital twin and to simulate at least one crop growth scenario based on the integrated data. The instructions cause to the system to use a prediction component configured to determine a predicted crop growth rate for the farm based on the simulations conducted by the processing component.

### CROSS-REFERENCE TO RELATED APPLICATIONS

This application is a continuation of International App. No. PCT/US24/28960, filed May 10, 2024, which claims the benefit of U.S. Provisional App. No. 63/501,442, filed 11 May 2023. The above applications are hereby incorporated by reference as if fully set forth herein in their entirety.

### FIELD

The present disclosure relates to digital simulations and more particularly to using digital twins to model agricultural environments.

### BACKGROUND

Agriculture has become increasingly dependent upon technology. Agricultural devices and equipment, farmland, agricultural facilities, and the like are now commonly equipped with monitors, sensors, and other instrumentation that allow farmers to record activity. Environmental monitors, sensors, and other instrumentation allow tracking climate data, weather, vegetation, and the like. Such data allow parties in the agriculture industry to make better decisions regarding agricultural practices and measure the results of these decisions. Although vast amounts of data can be gathered, the analysis and use of the data typically lack integration and are therefore limited in their intelligence and capacity for assisting agricultural planning and decision making.

### SUMMARY

The present disclosure generally includes methods and systems for providing an integration system for a system of platforms for obtaining, storing, analyzing and reporting on a plurality of information types relating to agriculture.

In embodiments, a system of platforms and marketplace may be provided for agricultural monitoring and remote decision-making support. The system of platforms may comprise an analysis module, wherein an artificial intelligence module receives external data through a security layer. The analysis module may perform data processing and analytics and share at least one output with a segment analysis module, a configured intelligence service module or a stakeholder service module. A reporting and optimization module may produce reports for distribution, a stakeholder systems integration module may provide results-based analysis and feedback, and a stakeholder systems module may provide stakeholder-adapted services and reporting, and stakeholder-specific configured intelligence services.

In some aspects, the techniques described herein relate to a crop growth modeling system including a memory configured to store computer-readable instructions that, when executed by at least one processor of a computing device, cause the computing device to use: a digital twin component configured to create and manage a digital twin of a farm; a data input component configured to receive data related to a defined set of land characteristics and environmental attributes for the farm; a processing component configured to integrate the received data with the digital twin and to simulate at least one crop growth scenario based on the integrated data; and a prediction component configured to determine a predicted crop growth rate for the farm based on the simulations conducted by the processing component.

In some aspects, the techniques described herein relate to a system, wherein the digital twin component is further configured to update the digital twin in real-time based on continuous data input from at least one device associated with the farm.

In some aspects, the techniques described herein relate to a system, wherein the at least one device includes sensors for measuring soil moisture, temperature, pH levels, and nutrient content.

In some aspects, the techniques described herein relate to a system, wherein the at least one device includes an API associated with an application used in conjunction with operation of the farm.

In some aspects, the techniques described herein relate to a system, wherein the processing component is configured to perform scenario analysis to evaluate and effect of different farming practices on predicted crop growth.

In some aspects, the techniques described herein relate to a system, wherein the different farming practices include variations in irrigation schedules, fertilizer applications, and crop rotation strategies.

In some aspects, the techniques described herein relate to a system, wherein the digital twin component is further configured to simulate an impact of climate variations on crop growth over a defined time period.

In some aspects, the techniques described herein relate to a system, wherein the digital twin component is further configured to simulate an impact on crop growth includes using historical weather data to model potential future environmental conditions.

In some aspects, the techniques described herein relate to a system, wherein the historical weather data is used to model scenarios including droughts and floods.

In some aspects, the techniques described herein relate to a system, wherein the simulation includes variations in CO2 levels, temperature, and precipitation patterns.

In some aspects, the techniques described herein relate to a system, wherein the prediction component is further configured to provide recommendations for optimizing crop yield based on the predicted growth rates.

In some aspects, the techniques described herein relate to a system, wherein the recommendations include at least one specified adjustment to a planting date or harvesting time.

In some aspects, the techniques described herein relate to a system, wherein the system is implemented as part of an integrated farm management platform that includes components for financial planning and market analysis.

In some aspects, the techniques described herein relate to a method for predicting crop growth rates in a farm, the method including: collecting data related to land characteristics and environmental attributes of the farm; creating a digital twin of the farm using the collected data; integrating the collected data with the digital twin; simulating crop growth scenarios using the integrated digital twin; and determining a predicted crop growth rate for the farm based on the simulated crop growth scenarios.

In some aspects, the techniques described herein relate to a method, wherein collecting data includes receiving input from remote sensing technologies.

In some aspects, the techniques described herein relate to a method, wherein the remote sensing technologies are used to assess crop health and detect signs of disease or pest infestation.

In some aspects, the techniques described herein relate to a method, wherein integrating the collected data with the digital twin includes aligning the data with a geographic information system (GIS) to enhance spatial accuracy.

In some aspects, the techniques described herein relate to a method, wherein the GIS integration provides at least one recommendation for an application location of land enhancers including at least one of water or fertilizer based on a defined need of a section of the farm.

In some aspects, the techniques described herein relate to a method, wherein of determining the predicted crop growth rate includes comparing at least one simulated outcome with actual crop performance data to refine a model.

In some aspects, the techniques described herein relate to a method, wherein the actual crop performance data is collected through automated systems integrated within farm machinery.

In some aspects, the techniques described herein relate to a method for predicting an agricultural product need in a geographic region, including: collecting data related to attributes of farmers in the geographic region, transactions made by farmers in the geographic region, and predicted climate characteristics in the geographic region during a prescribed time frame; processing the collected data using a machine learning and artificial intelligence system; and analyzing the processed data to predict at least one agricultural product need for the geographic region.

In some aspects, the techniques described herein relate to a method, wherein the data related to attributes of farmers includes at least one of demographic data, economic data, or farming practice data.

In some aspects, the techniques described herein relate to a method, wherein the transactions made by farmers include sales transactions, purchase transactions, or leasing transactions.

In some aspects, the techniques described herein relate to a method, wherein the predicted climate characteristics include temperature, rainfall, or humidity levels.

In some aspects, the techniques described herein relate to a method, further including updating the predictions in real-time based on real-time environmental data received.

In some aspects, the techniques described herein relate to a method, wherein processing and analyzing utilizes a neural network model.

In some aspects, the techniques described herein relate to a method, wherein processing and analyzing utilizes a decision tree model.

In some aspects, the techniques described herein relate to a method, wherein the predictions are further used to optimize supply chain logistics for at least one agricultural product in the geographic region.

In some aspects, the techniques described herein relate to a method, wherein the predictions are used to advise a farmer on optimal planting and harvesting times.

In some aspects, the techniques described herein relate to a method, wherein the data processing includes data normalization and data cleaning steps.

In some aspects, the techniques described herein relate to a method, wherein the machine learning and artificial intelligence system is configured to learn continuously from new data inputs to improve prediction accuracy.

In some aspects, the techniques described herein relate to a system for predicting an agricultural product need in a geographic region, including a memory configured to store computer-readable instructions that, when executed by at least one processor of a computing device, cause the computing device to use: a data collection component configured to collect data concerning attributes of farmers in the geographic region, transactions made by farmers, and predicted climate characteristics during a prescribed time frame; a machine learning and artificial intelligence component configured to process and analyze the collected data; and an output component configured to provide at least one prediction for an agricultural product need based on the analyzed data.

In some aspects, the techniques described herein relate to a system, wherein the data collection component is further configured to receive inputs from at least one device associated with the geographic region.

In some aspects, the techniques described herein relate to a system, wherein the machine learning and artificial intelligence component uses reinforcement learning techniques.

In some aspects, the techniques described herein relate to a system, wherein the output component is configured to generate visual representations of the predicted agricultural product need.

In some aspects, the techniques described herein relate to a system, wherein the output component is configured to send notifications to stakeholders about the predicted agricultural product need.

In some aspects, the techniques described herein relate to a system, wherein the data collection module includes a user interface for manual data entry by a user associated with the geographic region.

In some aspects, the techniques described herein relate to a system, wherein the machine learning and artificial intelligence module is further configured to perform predictive maintenance on farming equipment based on the collected data.

In some aspects, the techniques described herein relate to a system, wherein the output module includes an integration with a marketplace platform for at least one agricultural product.

In some aspects, the techniques described herein relate to a system, wherein the system is implemented as a cloud-based service accessible to multiple stakeholders in an agricultural sector.

In some aspects, the techniques described herein relate to a computer-implemented method for predicting agricultural product needs and optimizing procurement workflows, the method including: receiving data inputs including attributes of farmers, transaction histories of farmers, and predicted climate characteristics for a geographic region during a prescribed time frame; processing the received data using a machine learning and artificial intelligence system to predict the need for at least one agricultural product in the geographic region; and optimizing a procurement workflow to acquire or ship the at least one predicted needed agricultural product to a location in proximity to the geographic region.

In some aspects, the techniques described herein relate to a method, wherein the attributes of farmers include at least one of: farm size, crop types, historical yield data, and equipment usage.

In some aspects, the techniques described herein relate to a method, wherein the transaction histories include purchases of seeds, fertilizers, and agricultural chemicals.

In some aspects, the techniques described herein relate to a method, wherein the predicted climate characteristics are obtained from a third-party weather forecasting service.

In some aspects, the techniques described herein relate to a method, further including using a neural network within the machine learning and artificial intelligence system to process the data.

In some aspects, the techniques described herein relate to a method, wherein the optimizing of the procurement workflow includes automated contracting with suppliers.

In some aspects, the techniques described herein relate to a method, wherein the automated contracting includes the use of smart contracts on a blockchain platform.

In some aspects, the techniques described herein relate to a method, wherein the optimization includes scheduling shipments based on predicted optimal delivery times.

In some aspects, the techniques described herein relate to a method, wherein the scheduling of shipments is adjusted in real-time based on updates to the predicted climate characteristics.

In some aspects, the techniques described herein relate to a method, wherein the data inputs are further processed to identify trends and anomalies in farmer behavior and climate conditions.

In some aspects, the techniques described herein relate to a method, wherein identified trends are used to adjust the predictions of agricultural product needs.

In some aspects, the techniques described herein relate to a system for predicting agricultural product needs and optimizing procurement workflows, the system including a memory configured to store computer-readable instructions that, when executed by at least one processor of a computing device, cause the computing device to use: a data input component configured to collect data relating to attributes of farmers, transaction histories of farmers, and predicted climate characteristics for a geographic region during a prescribed time frame; a machine learning and artificial intelligence component configured to analyze the collected data and predict the need for at least one agricultural product in the geographic region; and a procurement optimization component configured to manage an acquisition and shipment of the at least one predicted needed agricultural product to a location in proximity to the geographic region.

In some aspects, the techniques described herein relate to a system, wherein the data input component is further configured to receive real-time updates on farmer activities and climate changes.

In some aspects, the techniques described herein relate to a system, wherein the machine learning and artificial intelligence component utilizes regression analysis to predict the agricultural product needs.

In some aspects, the techniques described herein relate to a system, wherein the regression analysis includes polynomial regression techniques.

In some aspects, the techniques described herein relate to a system, wherein the procurement optimization component is configured to select suppliers based on at least one of cost, proximity, and reliability.

In some aspects, the techniques described herein relate to a system, wherein the selection of suppliers is further based on historical performance data stored within the system.

In some aspects, the techniques described herein relate to a system, wherein the procurement optimization component includes an interface for manual override by a system operator.

In some aspects, the techniques described herein relate to a system, wherein the machine learning and artificial intelligence component is further configured to generate reports on predicted product needs for review by stakeholders.

In some aspects, the techniques described herein relate to a system, wherein the machine learning and artificial intelligence component is further configured to update its predictive models based on feedback received from the procurement optimization component regarding a success of previous procurement workflows.

In some aspects, the techniques described herein relate to a computer-implemented method for automatically generating an insurance policy offer for a farm, the method including: receiving, by one or more processors, data relating to climate attributes of a geographic region in which the farm is located; accessing, by the one or more processors, historical insurance claims made by farmers in the geographic region; retrieving, by the one or more processors, data regarding crop productivity of farms in the geographic region; predicting, by the one or more processors, crop performance characteristics in the geographic region during a prescribed time frame; and generating, by the one or more processors, an insurance policy offer for the farm based on the received, accessed, retrieved, and predicted data.

In some aspects, the techniques described herein relate to a method, wherein the data relating to climate attributes includes temperature, rainfall, and humidity data.

In some aspects, the techniques described herein relate to a method, wherein the historical insurance claims data includes data related to crop damage due to weather events.

In some aspects, the techniques described herein relate to a method, wherein the data regarding crop productivity includes yield per acre and quality of crop produced.

In some aspects, the techniques described herein relate to a method, wherein the prediction of crop performance characteristics includes use of a machine learning model trained on historical crop performance data.

In some aspects, the techniques described herein relate to a method, wherein the machine learning model is further trained using real-time climate data.

In some aspects, the techniques described herein relate to a method, further including adjusting the insurance policy offer based on predicted economic conditions in the geographic region.

In some aspects, the techniques described herein relate to a method, wherein the predicted economic conditions include market prices for crops commonly grown in the geographic region.

In some aspects, the techniques described herein relate to a method, wherein calculating a risk score based on the accessed, retrieved, and predicted data.

In some aspects, the techniques described herein relate to a method, wherein the risk score influences a premium of the insurance policy offer.

In some aspects, the techniques described herein relate to a method, further including providing the generated insurance policy offer to the farmer via a digital platform.

In some aspects, the techniques described herein relate to a system for automatically generating an insurance policy offer for a farm, the system including a memory configured to store computer-readable instructions that, when executed by at least one processor of a computing device, cause the computing device to use: a data reception module configured to receive data relating to climate attributes of a geographic region in which the farm is located; a data access module configured to access historical insurance claims made by farmers in the geographic region; a data retrieval module configured to retrieve data regarding crop productivity of farms in the geographic region; a prediction module configured to predict crop performance characteristics in the geographic region during a prescribed time frame; and an insurance policy generation module configured to generate an insurance policy offer for the farm based on the data received, accessed, retrieved, and predicted by the respective modules.

In some aspects, the techniques described herein relate to a system, wherein the data reception module is further configured to receive real-time climate data from Internet of Things (IoT) devices.

In some aspects, the techniques described herein relate to a system, wherein the data access module is further configured to access data from a blockchain ledger containing historical insurance claims.

In some aspects, the techniques described herein relate to a system, wherein the data retrieval module is further configured to interface with agricultural databases for crop productivity data.

In some aspects, the techniques described herein relate to a system, wherein the prediction module utilizes a neural network to predict crop performance characteristics.

In some aspects, the techniques described herein relate to a system, wherein the insurance policy generation module is further configured to customize the insurance policy offer based on farmer preferences.

In some aspects, the techniques described herein relate to a system, wherein the prediction module is further configured to update predictions based on feedback received from policyholders.

In some aspects, the techniques described herein relate to a system, wherein the feedback includes data on accuracy of previous crop performance predictions.

In some aspects, the techniques described herein relate to a system, wherein the insurance policy generation module is integrated with a digital farming management platform.

In some aspects, the techniques described herein relate to a computer-implemented method for improving a productivity metric of a farm, including: automatically monitoring operational data of the farm using a machine learning and artificial intelligence system; wherein the operational data includes sensor data derived from implements associated with the farm, environmental data, financial data, and simulated data; wherein the simulated data is based in part on predicted climate characteristics of a current growing season on the farm; producing automated recommendations of procedural changes to implement to improve the productivity metric of the farm; and providing a generative-AI interface through which a user queries the machine learning and artificial intelligence system for recommended procedural changes.

In some aspects, the techniques described herein relate to a method, wherein the sensor data includes data from soil moisture sensors.

In some aspects, the techniques described herein relate to a method, wherein the sensor data further includes data from weather stations located on the farm.

In some aspects, the techniques described herein relate to a method, wherein the environmental data includes data related to air quality and temperature.

In some aspects, the techniques described herein relate to a method, wherein the financial data includes data related to costs of inputs such as seeds, fertilizers, and pesticides.

In some aspects, the techniques described herein relate to a method, wherein the simulated data includes output from crop growth models.

In some aspects, the techniques described herein relate to a method, wherein the crop growth models take into account historical yield data of the farm.

In some aspects, the techniques described herein relate to a method, wherein the productivity metric is crop yield.

In some aspects, the techniques described herein relate to a method, wherein the procedural changes include changes in irrigation schedules.

In some aspects, the techniques described herein relate to a method, wherein the changes in irrigation schedules are based on soil moisture data.

In some aspects, the techniques described herein relate to a system for improving a productivity metric of a farm, including: a processor; a memory storing instructions that, when executed by the processor, cause the system to: monitor operational data of the farm automatically using a machine learning and artificial intelligence system; wherein the operational data includes sensor data derived from implements associated with the farm, environmental data, financial data, and simulated data; wherein the simulated data is based in part on predicted climate characteristics of a current growing season on the farm; generate automated recommendations of procedural changes to improve the productivity metric of the farm; and provide a generative-AI interface for user interaction to query for recommended procedural changes.

In some aspects, the techniques described herein relate to a system, wherein the generative-AI interface includes a natural language processing model.

In some aspects, the techniques described herein relate to a system, wherein the natural language processing model is trained specifically on agricultural terminology.

In some aspects, the techniques described herein relate to a system, wherein the machine learning and artificial intelligence system includes a neural network.

In some aspects, the techniques described herein relate to a system, wherein the neural network is configured to perform regression analysis to predict future productivity metrics based on current operational data.

In some aspects, the techniques described herein relate to a system, wherein the machine learning and artificial intelligence system is configured to update its models in real-time based on incoming operational data.

In some aspects, the techniques described herein relate to a system, wherein the user can customize a type of procedural changes the system recommends.

In some aspects, the techniques described herein relate to a system, wherein the user can set preferences for cost-effectiveness of the recommended procedural changes.

In some aspects, the techniques described herein relate to a system, wherein the system further includes a module for generating reports on effectiveness of implemented procedural changes.

In some aspects, the techniques described herein relate to a system, wherein the reports include comparisons of predicted and actual changes in the productivity metric.

In some aspects, the techniques described herein relate to a system of platforms for agricultural monitoring and remote decision-making support, the system of platforms including a memory configured to store computer-readable instructions that, when executed by at least one processor of a computing device, cause the computing device to use: an analysis module, wherein an artificial intelligence module receives external data through a security layer, performs data processing and analytics, and shares at least one output with a segment analysis module, a configured intelligence service or a stakeholder service module, and a reporting and optimization module produces a report for distribution; a stakeholder systems integration module, wherein results-based analysis and feedback is performed; and a stakeholder systems module, wherein stakeholder-adapted services and reporting, and stakeholder-specific configured intelligence services are performed.

In embodiments, a yield analysis request for a crop type can be received and based on aggregated crop data, a yield impact of one or more yield factors may be determined for the crop type. The aggregated crop data may be based on planting data and harvest data for a plurality of farm fields. The aggregated crop data may be determined in part by associating the planting data and harvest data for individual farm fields of the plurality of farm fields. A yield analysis may be provided for the crop type based on the yield impact of the yield factors.

An embodiment can be a method for forecasting crop yield, the method comprising: determining an expected yield at a first time; determining a growth function representing how the expected crop yield changes over time; and based at least in part on an intrinsic yield function and the growth function, determining an expected yield at a second time, wherein the second time is later than the first time.

An embodiment can be one or more computer-readable storage media storing computer-executable instructions that, when executed, perform a method for forecasting crop yield, the method comprising: receiving at least one of environmental data or cultural farming practice data for one or more fields growing a crop of a crop type; and constructing a location-specific growth function that estimates a change in an expected crop yield over time for the one or more fields growing the crop of the crop type, the growth function based on the at least one of environmental data or cultural farming practice data.

An embodiment can be one or more computer-readable storage media storing computer-executable instructions that, when executed, perform a method for forecasting crop yield, the method comprising: generating a yield trajectory for each of a plurality of locations in a field or group of fields, the respective yield trajectories representing an expected yield as a function of time for a set of environmental factors and cultural farming practices, the respective yield trajectories generated by: determining an intrinsic yield function for the location, the intrinsic yield function representing a yield determined from a set of empirical observations; determining a growth function having values for the location at each of a plurality of time steps, the growth function based at least in part on a plurality of parameters reflecting at least some of the environmental factors and cultural farming practices; and for each of the plurality of time steps after an initial time step, calculating an expected yield based at least in part on an expected yield of the previous time step, the intrinsic yield function, and the growth function; and combining the yield trajectories for the plurality of locations in the field or group of field to determine an expected yield for a growing season.

The foregoing and other objects, features, and advantages of the claimed subject matter will become more apparent from the following detailed description, which proceeds with reference to the accompanying figures.

### BRIEF DESCRIPTION OF THE DRAWINGS

FIG. 1 is a diagram that depicts a system of platforms and marketplace for the management of agriculture, agricultural practices, processes, planning, supplying, and the prediction of agricultural needs and outcomes in accordance with many embodiments.

FIG. 2 is a diagram that depicts a configured intelligence services module that includes one or more intelligence functions and/or intelligence service clients in accordance with many embodiments.

FIG. 3 is a diagram that depicts an intelligent analytics module that includes modules configured to perform specific analyses with respect to agriculture, agricultural practices, processes, planning, supplying, and prediction in accordance with many embodiments.

FIG. 4 depicts a block diagram of exemplary features, capabilities, and interfaces of a robust generative artificial intelligence platform.

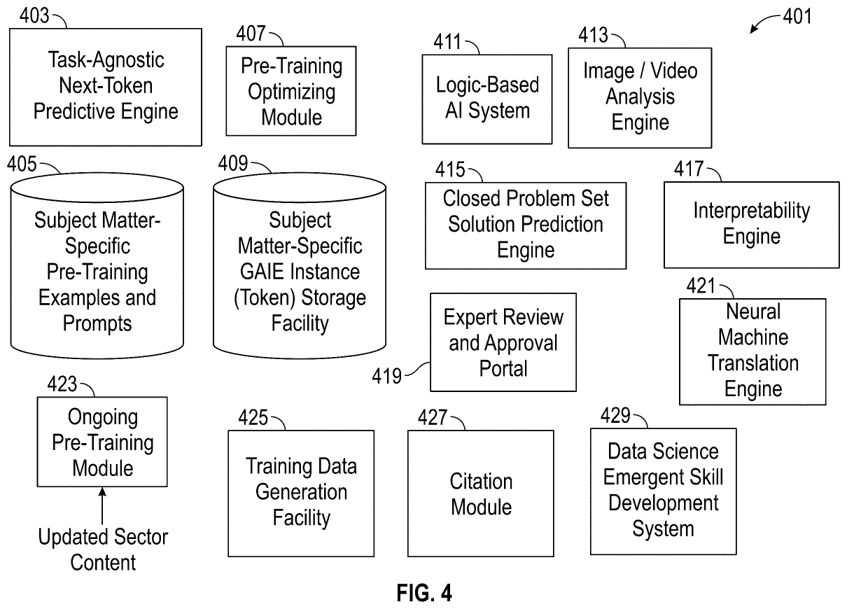

FIG. 5 is a block diagram of an example system implementing an artificial intelligence agricultural advisor chatbot.

FIG. 6 is a flowchart of an example method of implementing an artificial intelligence agricultural advisor chatbot.

FIG. 7 is a flowchart of an example method of responding to a text query input to a chatbot.

FIG. 8 is a flowchart of an example method of generating vector embeddings.

FIG. 9 is a flow diagram for generating vector embeddings.

FIG. 10 is a flowchart of an example method of selecting a database entry relevant to a chatbot query.

FIG. 11 is a block diagram of an example architecture of an artificial intelligence agricultural advisor chatbot.

FIG. 12 is a block diagram of an example computing system in which described embodiments can be implemented.

FIG. 13 is a block diagram of an example cloud computing environment that can be used in conjunction with the technologies described herein.

### DETAILED DESCRIPTION

### Introduction

Information associated with agriculture, agricultural practices, processes, planning, supplying, and the prediction of agricultural needs and outcomes has historically been collected, stored and managed by a plurality of remote entities, each with its own analytic interest, making the centralized usage of such agricultural data difficult, and the creation of derivative data and analyses that may derive from such centralized usage unrealized. As a result, gleaning the intelligence inherent in centralized agricultural information is limited, as is putting to use such intelligence for the optimized management of individual farms, agricultural product management and supply, agricultural best practices, and other agricultural needs and outcomes. Furthermore, conventional agricultural data collection and analytic techniques lack validation for data collected on individual farms. Such data can therefore contain errors, making the data not useful or irrelevant.

In some examples, a farmer might enter in their planter monitor a particular seed hybrid as the one being planted in a field, yet some seeds of a different hybrid might remain in the seed supply bin of the planter as planting begins. As another example, once partially through planting the field, a supply bin might run out, and a farmer may add yet another hybrid to finish on some of the planter rows. In the same manner, a farmer might load a sprayer with a particular chemical but enters in their records the use of a different formulation that he or she assumes to be the same. Thus, in conventional systems, the actual occurrences in the field may not be properly captured and cannot be used to ensure valid data. Conventional harvest results also suffer from lack of validity or consistency because of, for example, poorly calibrated or un-calibrated equipment. For example, flow sensors on a grain combine should be frequently calibrated and compared to an actual weight to ensure accuracy. Failure to monitor and adjust flow sensors frequently enough limits the accuracy of collected data. Although attempts have been made to determine the implications of agricultural decision-making, such as seed selection, use of specific products, or use of specific practices on crop productivity, predicting productivity through modeling has been extremely difficult and of limited utility.

Agricultural outcomes are dynamic and complex, occurring in a natural environment with inherent instability. No two growth conditions are exactly similar or completely understood and thus this chaos that is witnessed is conventionally accepted as much too complex for a model to account for. If a practice or product produces an average response in a cropping system that is economically positive, it is typically accepted that this is the best one can expect. Thus, the recommendation to over-apply the practice to systems thought to be relatively similar is conventionally considered reasonable, even though it may fail to produce a positive response half of the time.

Examples of agricultural management, analysis, prediction and forecasting using a system of platforms and marketplace are described herein. Such examples include, but are not limited to, providing guidance to individual farmers (“farmer” as used herein refers to anyone managing a biological system) to make effective agricultural choices and practices that may benefit their enterprise by more accurately predicting, for example, the response of a crop or other biological system, such as identifying and classifying components, products, actions and practices that might impact and/or optimize the productivity (as used herein, “optimize” and “optimization” refer to an improvement and does not necessarily require a “best” result.) The described examples allow farmers to use their own data to connect to this continuum of response. Using the system of platforms and marketplace, as disclosed herein, may allow an individual farmer or farm to maintain their private data in a confidential format and system, providing an incentive to participate in the practices implemented by the system of platforms while managing their agricultural practices.

Other examples of agricultural management, analysis, prediction and forecasting using the system of platforms and marketplace, described herein, include providing time- and location-specific (e.g., field specific) solutions rather than macro-level solutions that may or may not be applicable to a given parcel of land, region, or the like. In embodiments, the system of platforms and marketplace, described herein, may provide predictions from post-processed data that is determined at least in part by real time conditions associated with a parcel of land and/or agriculture practice or decision.

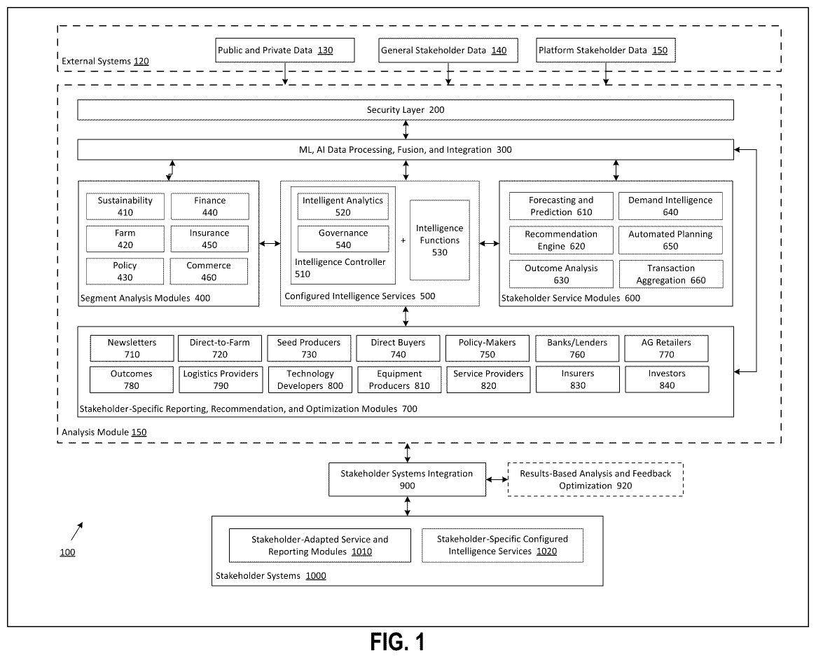

FIG. 1 depicts a block diagram of an example implementation of an analysis module 101 that may form a part of some embodiments of an integration system for a system of platforms and marketplace 100 for assisting agricultural planning, decision making and procurement. External systems 600 associated with the system of platforms and marketplace 100 may include, but are not limited to, public and private data 730, general stakeholder data 830, platform stakeholder data 150, such as parties associated and/or contracting with the system of platforms and marketplace 100, and may access the analysis module 101 through a security layer 200. The security layer 200 may be configured to provide secured access between the analysis module 101 and the external systems 600 only when an external system presents valid credentials, which are authenticated by the security layer. If the external system does not present valid credentials, the security layer 200 may deny communications between the external system and the analysis module 101. In various implementations, the security layer 200 may facilitate the analysis module 101 to read and write to external data sources, such as public and private data sources 730 as described herein. In embodiments, the public and private data 730 may include, but is not limited to, government data (e.g., satellite imagery of crop land, economic data, and the like), data from farming equipment (e.g., combines, irrigation systems, and the like), private industry data (e.g., yield data on proprietary seed cultivars, pest management recommendations, and the like), or some other type of data. In embodiments, the general stakeholder data 830 may include, but is not limited to, financial institutions (e.g., banks, insurers, and the like), government (e.g., state or county agricultural agencies), analytics companies, agricultural implement manufacturers and servicers, seed companies, universities and other academic and non-profit organizations, or some other type of stakeholders. In embodiments, the platform stakeholder data 150 may include data from parties and entities that are direct beneficiaries of the analytics and outputs from the platform 100, including, but not limited to, farmers, banks, agricultural suppliers or some other types of platform stakeholders.

In various implementations, the analysis module 101 may include a machine learning (ML), artificial intelligence (AI), data processing, fusion, and integration module 300, a segment analysis module 400, a configured intelligence services module 500, a stakeholder service modules 600, and a stakeholder-specific reporting, recommendation and optimization modules 700 for assisting agricultural planning, decision making and procurement. In various implementations, the machine learning, artificial intelligence, data processing, fusion, and integration module 300 may include intelligence services.

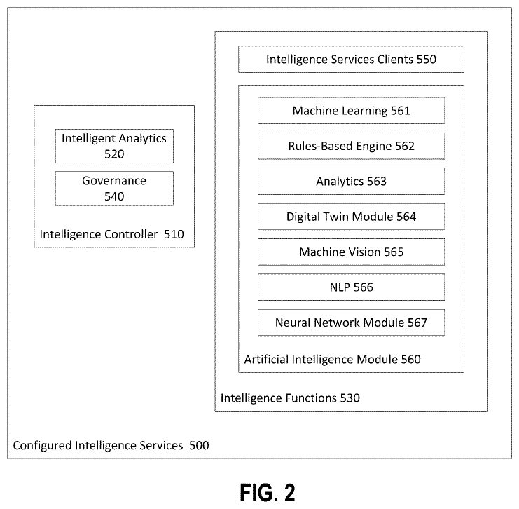

Referring to FIG. 2, in embodiments, the configured intelligence services module 500 may include one or more intelligence functions 530 and/or intelligence service clients 550. In some embodiments, the intelligence services 500 may be adapted to be at least partially replicated in respective intelligence clients 550 (e.g., a stakeholder access layer). In these embodiments, an individual client may include some or all of the capabilities of the intelligence services 500, whereby the intelligence service may be adapted for the specific functions performed by the subsystems of the intelligence client 550. Additionally or alternatively, in some embodiments, the intelligence services may be implemented as a set of microservices, such that different intelligence clients may leverage the intelligence services via one or more APIs exposed to the intelligence clients, such as intelligence clients 550 that are directed towards a particular data field or task(s), such as clients used for monitoring, analyzing and reporting on agricultural devices and equipment, IoT sensors, and the like. In these embodiments, the intelligence services may be configured to perform various types of intelligence services that may be adapted for different intelligence clients. In either of these configurations, an intelligence service client 550 may provide an intelligence request to the intelligence services, whereby the request is to perform a specific intelligence task (e.g., a decision, a recommendation, a report, an instruction, a classification, a prediction, a training action, a natural language processing (NLP) request, or the like). In response, the intelligence services 500 may execute the requested intelligence task and return a response to the intelligence service client 550. Additionally, or alternatively, in some embodiments, the intelligence services 500 may be implemented using one or more specialized chips (e.g., chips adapted to particular analytics, equipment, and the like) that are configured to provide AI assisted microservices such as image processing, diagnostics, location and orientation, chemical analysis, data processing, and so forth.

In embodiments, the configured intelligence services 500 may include an artificial intelligence module 560. In embodiments, artificial intelligence services may receive an intelligence request from an intelligence service client 550 and any required data to process the request from the intelligence service client 550. In response to the request and the specific data, one or more implicated artificial intelligence modules 560 may perform the intelligence task and output an “intelligence response.” Examples of intelligence modules responses may include a decision (e.g., a control instruction, a proposed action, machine-generated text, and/or the like), a prediction (e.g., a predicted meaning of a text snippet, a predicted outcome associated with a proposed action, a predicted fault condition, and/or the like), a classification (e.g., a classification of an object in an image, a classification of a spoken utterance, a classified fault condition based on sensor data, and/or the like), and/or other suitable outputs of an artificial intelligence system. For example, image data relating to a target parcel of land may be analyzed by the platform and compared to other image data from other parcels of land for the purposed of identifying a comparable land parcel set with common characteristics of interest in the target parcel of land. Additional data relating to the comparable land parcel set may be used and analyzed by the analysis module 101 and intelligence services to, for example, identify crop types, seed cultivars, timing of planting and fertilizing or some other characteristics that might be successful if applied to the target parcel of land.

In embodiments, the artificial intelligence module 560 may include a ML module 561, a rules-based module 562, analytics module 563, a digital twin module 564, a machine vision module 565, an NLP module 566, and/or a neural network module 567. It is appreciated that the foregoing are non-limiting examples of artificial intelligence modules 560, and that some of the modules may be included or leveraged by other artificial intelligence modules. For example, the NLP module 566 and the machine vision module 565 may leverage different neural networks that are part of the neural network module 567 in performance of their respective functions.

It is further noted that in some scenarios, artificial intelligence modules 560 themselves may also be intelligence clients. For example, a rules-based intelligence module 562 may request an intelligence task from an ML module 561 or a neural network module 567, such as requesting a classification of an object appearing in a video and/or a motion of the object. In this example, the rules-based intelligence module 562 may be an intelligence service client that uses the classification to determine whether to take a specified action. In another example, a machine vision module 565 may request a digital twin of a specified environment, such as a target farm or parcel of land, from a digital twin module 564, such that the ML module 561 may request specific data from the digital twin, such as modeling crop growth over a specified time frame, as features to train a machine-learned model that is trained for a specific environment.

In embodiments, an intelligence task may require specific types of data to respond to the request. For example, a machine vision task may require one or more images (and potentially other data) to classify objects (e.g., vegetation type on a parcel of land, the presence of water access, and the like) appearing in an image or set of images, to determine features within the set of images (such as locations of items, symbols or instructions, expressions, parameters of motion, changes in status, and many others), and the like. In another example, an NLP task requires audio of speech and/or text data (and potentially other data) to determine a meaning or other element of the speech and/or text. In yet another example, an AI-based control task (e.g., a decision on movement of farm equipment) may require environment data (e.g., maps, coordinates of known obstacles, images, and/or the like) and/or a motion plan to make a decision as to how to control the motion of an implement.

In a platform-level example, an analytics-based reporting task may require data from a number of different databases to generate an analysis and/or report. Thus, in embodiments, tasks that can be performed by the intelligence services may require, or benefit from, specific intelligence service inputs. In some embodiments, the intelligence services may be configured to receive and/or request specific data from the intelligence service inputs to perform a respective intelligence task. For example, a farmer may want to restrict analysis and recommendations received from the platform 100 on planting or fertilizing requirements and amounts to only those inputs that apply to the specific cultivar in use on a parcel of land or planned for use. Additionally or alternatively, the requesting intelligence service client may provide the specific data in the request. For instance, the intelligence services may expose one or more APIs to the intelligence clients, whereby a requesting client may provide the specific data in the request via the API. Examples of intelligence service inputs may include, but are not limited to, sensors that provide sensor data, video streams, audio streams, databases, data feeds, human input, and/or other suitable data.

In embodiments, intelligence modules may include and provides access to an ML module 561 that may be integrated into or be accessed by one or more intelligence clients 550. In embodiments, the ML module 561 may provide machine-based learning capabilities, features, functions, and algorithms for use by an intelligence service client such as training ML models, leveraging ML models, reinforcing ML models, performing various clustering techniques, feature extraction, and/or the like. In examples, a machine learning module 561 may provide machine learning computing, data storage, and feedback infrastructure to a simulation system (e.g., simulations of crop growth under various climate conditions, fertilizer applications, and the like). The machine learning module 561 may also operate cooperatively with other modules, such as the rules-based module 562, the machine vision module 565, and/or the like. For example, a farmer may set rules relating to cost allocation for a target parcel of land such that some data and/or analysis are excluded from the analyses because the implementation of the resulting recommendations would exceed a cost threshold, violating a rule.

The machine learning module 561 may define one or more machine learning models for performing analytics, simulation, decision making, and predictive analytics related to data processing, data analysis, simulation creation, and simulation analysis of one or more components or subsystems of an intelligence service client. In embodiments, the machine learning models are algorithms and/or statistical models that perform specific tasks without using explicit instructions, relying instead on patterns and inference. The machine learning models build one or more mathematical models based on training data to make predictions and/or decisions without being explicitly programmed to perform the specific tasks. In example implementations, machine learning models may perform classification, prediction, regression, clustering, anomaly detection, recommendation generation, and/or other tasks.

In embodiments, the machine learning models may perform various types of classification based on the input data. Classification is a predictive modeling problem where a class label is predicted for a given example of input data. For example, machine learning models can perform binary classification, multi-class or multi-label classification. In embodiments, the machine-learning model may output “confidence scores” that are indicative of a respective confidence associated with the classification of the input into the respective class. In embodiments, the confidence scores can be compared to one or more thresholds to render a discrete categorical prediction. In embodiments, only a certain number of classes (e.g., one) with the relatively largest confidence scores can be selected to render a discrete categorical prediction.

In embodiments, machine learning models may output a probabilistic classification. For example, machine learning models may predict, given a sample input, a probability distribution over a set of classes. Thus, rather than outputting only the most likely class to which the sample input should belong, machine learning models can output, for each class, a probability that the sample input belongs to such class. In embodiments, the probability distribution over all possible classes can sum to one. In embodiments, a SoftMax function, or other types of function or layer can be used to turn a set of real values respectively associated with the possible classes into a set of real values in the range (0, 1) that sum to one. In embodiments, the probabilities provided by the probability distribution can be compared to one or more thresholds to render a discrete categorical prediction. In embodiments, only a certain number of classes (e.g., one) with the relatively largest predicted probability can be selected to render a discrete categorical prediction.

In embodiments, machine learning models can perform regression to provide output data in the form of a continuous numeric value. As examples, machine learning models can perform linear regression, polynomial regression, or nonlinear regression. As described, in embodiments, a SoftMax function or other function or layer can be used to squash a set of real values respectively associated with two or more possible classes to a set of real values in the range (0, 1) that sum to one. For example, machine learning models can perform linear regression, polynomial regression, or nonlinear regression. As examples, machine learning models can perform simple regression or multiple regression. As described above, in some implementations, a SoftMax function or other function or layer can be used to squash a set of real values respectively associated with two or more possible classes to a set of real values in the range (0, 1) that sum to one.

In embodiments, machine learning models may perform various types of clustering. For example, machine learning models may identify one or more previously-defined clusters to which the input data most likely corresponds. In some implementations in which machine learning models perform clustering, machine learning models can be trained using unsupervised learning techniques.

In embodiments, machine learning models may perform anomaly detection or outlier detection. For example, machine learning models can identify input data that does not conform to an expected pattern or other characteristics (e.g., as previously observed from previous input data). As examples, the anomaly detection can be used for fraud detection or system failure detection.

In some implementations, machine learning models can provide output data in the form of one or more recommendations. For example, machine learning models can be included in a recommendation system or engine. As examples, given input data that describes previous outcomes for certain entities (e.g., a score, ranking, or rating indicative of an amount of success or enjoyment), machine learning models can output a suggestion or recommendation of one or more additional entities that, based on the previous outcomes, are expected to have a desired outcome.

As described above, machine learning models can be or include one or more of various different types of machine-learned models. Examples of such different types of machine-learned models are provided below for illustration. One or more of the example models described below can be used (e.g., combined) to provide the output data in response to the input data. Additional models beyond the example models provided below can be used as well.

In some implementations, machine learning models can be or include one or more classifier models such as, for example, linear classification models; quadratic classification models; etc. Machine learning models may be or include one or more regression models such as, for example, simple linear regression models, multiple linear regression models, logistic regression models, stepwise regression models, multivariate adaptive regression splines, locally estimated scatterplot smoothing models, and the like.

In some examples, machine learning models can be or include one or more decision tree-based models such as, for example, classification and/or regression trees, chi-squared automatic interaction detection decision trees, decision stumps, conditional decision trees, and the like.

Machine learning models may be or include one or more kernel machines. In some implementations, machine learning models can be or include one or more support vector machines. Machine learning models may be or include one or more instance-based learning models such as, for example, learning vector quantization models, self-organizing map models, locally weighted learning models, and the like. In some implementations, machine learning models can be or include one or more nearest neighbor models such as, for example, k-nearest neighbor classifications models, k-nearest neighbors regression models, and the like. Machine learning models can be or include one or more Bayesian models such as, for example, naïve Bayes models, Gaussian naïve Bayes models, multinomial naïve Bayes models, averaged one-dependence estimators, Bayesian networks, Bayesian belief networks, hidden Markov models, and the like.

Machine learning models may include one or more clustering models such as, for example, k-means clustering models, k-medians clustering models, expectation maximization models, hierarchical clustering models, and the like.

In some implementations, machine learning models can perform one or more dimensionality reduction techniques such as, for example, principal component analysis, kernel principal component analysis, graph-based kernel principal component analysis, principal component regression, partial least squares regression, Sammon mapping, multidimensional scaling, projection pursuit, linear discriminant analysis, mixture discriminant analysis, quadratic discriminant analysis, generalized discriminant analysis flexible discriminant analysis, autoencoding, and the like.

In some implementations, machine learning models can perform or be subjected to one or more reinforcement learning techniques such as Markov decision processes, dynamic programming, Q functions or Q-learning, value function approaches, deep Q-networks, differentiable neural computers, asynchronous advantage actor-critics, deterministic policy gradient, and the like.

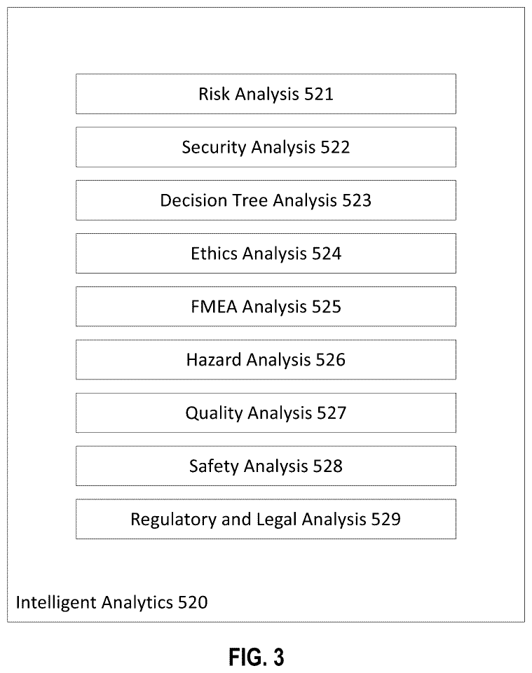

In some embodiments, the intelligent analytics module 520 may determine one or more analyses that are to be performed with respect to a particular decision and may provide corresponding analysis modules that perform those analyses to the artificial intelligence modules 560, such that the artificial intelligence modules 560 leverage the corresponding intelligent analytics modules 520 to analyze a decision before outputting the decision to the requesting client. Referring to FIG. 3, in embodiments, the intelligent analytics module 520 may include modules that are configured to perform specific analyses with respect to certain types of decisions, whereby the respective modules are executed by a processing system that hosts the instance of the intelligence services. Non-limiting examples of analysis modules may include risk analysis module(s) 521, security analysis module(s) 522, decision tree analysis module(s) 523, ethics analysis module(s) 524, failure mode and effects (FMEA) analysis module(s) 525, hazard analysis module(s) 526, quality analysis module(s) 527, safety analysis module(s) 528, regulatory and legal analysis module(s) 529, and/or other suitable analysis modules.

In some embodiments, the intelligent analytics module 520 may be configured to determine which types of analyses to perform based on the type of decision that was requested by an intelligence service client. For example, the platform 100 may use seasonal and climate data to predict the product needs of a given farming region. However different regions may be experiencing different climate or environmental factors (i.e., have different analytic/data needs). Thus, the intelligent analytics module 520 may restrict and/or request particular data and analyses to fit a given region. In some of these embodiments, the intelligent analytics module 520 may include an index or other suitable mechanism that identifies a set of analysis modules based on a requested decision type. In these embodiments, the intelligent analytics module 520 may receive the decision type and may determine a set of analysis modules that are to be executed based on the decision type. Additionally or alternatively, one or more governance standards may define when a particular analysis is to be performed. For example, the engineering standards may define what scenarios necessitate a FMEA analysis. In this example, the engineering standards may have been implicated by a request for a particular type of decision and the engineering standards may define scenarios when a FMEA analysis is to be performed. In this example, artificial intelligence modules 560 may execute a safety analysis module 528 and/or a risk analysis module 521 and may determine an alternative decision if the action would violate a legal standard or a safety standard. In response to analyzing a proposed decision, artificial intelligence modules 560 may selectively output the proposed condition based on the results of the executed analyses. If a decision is allowed, artificial intelligence modules 560 may output the decision to the requesting intelligence service client 550. If the proposed configuration is flagged by one or more of the analyses, artificial intelligence modules 560 may determine an alternative decision and execute the analyses with respect to the alternate proposed decision until a conforming decision is obtained.

In various implementations, the machine learning (ML), artificial intelligence (AI), data processing, fusion, and integration module 300 may include methods and systems for data and analytic optimization, prediction, decision support, simulation, machine learning, process automation, inference modeling, neural network modeling, digital twins modeling, and the like (collectively referred to herein as “intelligence services, “artificial intelligence modules”). Another Sub-heading

The machine learning (ML), artificial intelligence (AI), data processing, fusion, and integration module 300 may enable the analysis module 101 to solve optimization problems according to bracketing algorithms (such as the Fibonacci search, golden-section search, and bisection method algorithms), local descent algorithms (such as the line search algorithm), and/or first order algorithms (such as the gradient descent, momentum, AdaGrad, RMSProp, and Adam algorithms). The machine learning (ML), artificial intelligence (AI), data processing, fusion, and integration module 300 may enable the analysis module 101 to make predictions using classification models, clustering models, forecast models, outliers models, time series models, logistic regression, random forest models, generalized linear models, gradient boosted models, K-means algorithms, and/or Prophet algorithms.

The machine learning (ML), artificial intelligence (AI), data processing, fusion, and integration module 300 may enable and run decision support systems (DSSs), which may be used to manage large volumes of data. In various implementations, DSSs may perform simulations of decision-making procedures taken by the components of the system of platforms and marketplace 100 to determine optimal courses of action, gather and analyze data, and inform overall decision making as to the course of action for the components of the system of platforms and marketplace 100. Simulation may be used by the machine learning (ML), artificial intelligence (AI), data processing, fusion, and integration module 300 to generate synthetic input vectors for training machine learning models (for example, as in generative adversarial networks).

The machine learning (ML), artificial intelligence (AI), data processing, fusion, and integration module 300 may enable and run linear regression models, logistic regression modules, decision true models, support vector machine algorithms, Naïve Bayes algorithms, K-nearest neighbor algorithms, random forest algorithms, dimensionality reduction algorithms, gradient boosting algorithms, and/or AdaBoost algorithms. The machine learning (ML), artificial intelligence (AI), data processing, fusion, and integration module 300 may include process automation for automating any of the processes performed by components of the system of platforms and marketplace 100. The machine learning (ML), artificial intelligence (AI), data processing, fusion, and integration module 300 may use a trained machine learning model to infer a result using real-world data as inputs, such as data relating to a specific farm, farming region, farming practice, farming product, and the like.

The machine learning (ML), artificial intelligence (AI), data processing, fusion, and integration module 300 may enable and run convolutional neural networks, long short-term memory (LSTM) networks, recurrent neural networks, generative adversarial networks, radial basis function networks, multilayer perceptrons, self-organizing maps, deep belief networks, restricted Boltzmann machines, and autoencoders. The machine learning (ML), artificial intelligence (AI), data processing, fusion, and integration module 300 may generate digital twins to create virtual representations of components of the system of platforms and marketplace 100 that serve as the real-time digital counterparts of the real components. Simulations may be performed on the digital counterparts to allow users to understand how the system is performing in the present, as well as to allow users to understand how the system will perform under hypothetical conditions or in the future.\

In embodiments, the artificial intelligence modules 560 may include and/or provide access to an analytics module 563. In embodiments, an analytics module 563 may be configured to perform various analytical processes on data output from a plurality of entities or other data sources. In example embodiments, analytics produced by the analytics module 563 may facilitate the quantification of system performance as compared to a set of goals and/or metrics. The goals and/or metrics may be preconfigured, determined dynamically from operating results, and the like. Examples of analytics processes that can be performed by an analytics module 563 are discussed herein. In some example implementations, analytics processes may include tracking farming goals (e.g., crop yield targets) and/or specific metrics that involve coordination of agricultural activities and demand intelligence, such as involving forecasting agricultural product demand for a set of relevant items by location and time (among many others).

In embodiments, artificial intelligence modules may include and/or provide access to a digital twin module 564. The digital twin module 564 may encompass any of a wide range of features and capabilities as described herein, such as a digital twin of a target parcel of land with which to simulate the predicted crop yields of a plurality of crop types (e.g., corn, soybeans), seed cultivars (e.g., genetically modified varieties) and climate/environmental factors (e.g., rainfall amounts, temperature), and agricultural practices (e.g., supplemental irrigation, application of specific fertilizers, time of planting). In embodiments, a digital twin module 564 may be configured to provide, among other things, execution environments for and different types of digital twins, such as twins of physical environments, twins of robot operating units, logistics twins, executive digital twins, organizational digital twins, role-based digital twins, and the like. In embodiments, the digital twin module 564 may be configured in accordance with digital twin systems and/or modules described elsewhere throughout the disclosure. In example embodiments, a digital twin module 564 may be configured to generate digital twins that are requested by intelligence clients. Further, the digital twin module 564 may be configured with interfaces, such as APIs, and the like for receiving information from external data sources. For instance, the digital twin module 564 may receive real-time data from sensor systems from various machinery, vehicles, robots, or other devices, and/or sensor systems of the physical environment in which a device operates. In embodiments, the digital twin module 564 may receive digital twin data from other suitable data sources, such as third-party services (e.g., weather services, traffic data services, logistics systems and databases, and the like). In embodiments, the digital twin module 564 may include digital twin data representing features, states, or the like of specific farms, parcels of land, regions, areas sharing climate factors, or the like. The digital twin module 564 may be integrated with or into, link to, or otherwise interact with an interface (e.g., a dashboard), for coordination of supply of agricultural products and/or farming management activities. In embodiments, a digital twin module may provide access to and manage a library of digital twins. Artificial intelligence modules 560 may access the library to perform functions, such as a simulation of actions in a given environment in response to certain stimuli.

In various implementations, the machine learning (ML), artificial intelligence (AI), data processing, fusion, and integration module 300 may include libraries, one or more data stores, data services, and bridging and integration services. In various implementations, the libraries may be a collection of non-volatile resources used by modules and applications of the analysis module 101. In various implementations, the data stores may be shared volatile or non-volatile computer readable storage media on which the components the segment analysis module 400, configured intelligence services modules 500, stakeholder service modules 600, and stakeholder-specific reporting, recommendation and optimization modules 700 may be stored or may use.

In various implementations, data services may include data processing, data handling, data analysis, data enrichment, and data aggregation. Data processing may include processing data from entities external to the system of platforms and marketplace 100 or from various components of the system of platforms and marketplace 100. Data handling may include data received from entities external to the system of platforms 100 or from various components of the system of platforms and marketplace 100. Data analysis may include analysis on data received from entities external to the system of platforms 100 or from various components of the system of platforms and marketplace 100. Data aggregation may aggregate data received from entities external to the system of platforms 100 or from various components of the system of platforms and marketplace 100.

In embodiments, artificial intelligence modules 560 may include and/or provide access to a machine vision module. In embodiments, a machine vision module 565 may be configured to process images (e.g., captured by a camera) to detect and classify objects in the image. In embodiments, the machine vision module 565 receives one or more images (which may be frames of a video feed or single still shot images) and identifies diffuse areas in an image (e.g., using edge detection techniques or the like). The machine vision module 565 may then classify the diffuse areas. In some embodiments, the machine vision module 565 leverages one or more machine-learned image classification models and/or neural networks (e.g., convolutional neural networks) to classify the diffuse areas in the image. In some embodiments, the machine vision module 565 may perform feature extraction on the images and/or the respective areas in the image prior to classification. In some embodiments, the machine vision module 565 may leverage classification made in a previous image to affirm or update classification(s) from the previous image. For example, if an object that was detected in a previous frame was classified with a lower confidence score (e.g., the object was partially occluded or out of focus), the machine vision module 565 may affirm or update the classification if the machine vision module 565 is able to determine a classification of the object with a higher degree of confidence. In embodiments, the machine vision module 565 is configured to detect occlusions, such as objects that may be occluded by another object. In embodiments, the machine vision module 565 receives additional input to assist in image classification tasks, such as from a radar, a sonar, a digital twin of an environment (which may show locations of known objects), and/or the like.

In embodiments, the artificial intelligence modules 560 may include and/or provide access to a natural language processing (NLP) module 566. In embodiments, an NLP module 566 may perform natural language tasks on behalf of an intelligence service client. Examples of natural language processing techniques may include, but are not limited to, speech recognition, speech segmentation, creation of speaker diaries, text-to-speech, lemmatization, morphological segmentation, parts-of-speech tagging, stemming, syntactic analysis, lexical analysis, and the like. In embodiments, the NLP module 566 may enable voice commands that are received from a human. For example, a farmer may interact with the platform 100, in part, by issuing an analytic request by a voice command (e.g., “What is the recommended application amount and timing for Fertilizer X on my Y parcel of land with soybeans?” and/or “Where may I obtain X amount of Acme Fertilizer at the least cost, and when is the recommended timing of purchase to obtain the best price?”). In embodiments, the NLP module 566 receives an audio stream (e.g., from a microphone) and may perform voice-to-text conversion on the audio stream to obtain a transcription of the audio stream. The NLP module 566 may process text (e.g., a transcription of the audio stream) to determine a meaning of the text using various NLP techniques (e.g., NLP models, neural networks, and/or the like). In embodiments, the NLP module 566 may determine an action or command that was spoken in the audio stream based on the results of the NLP. In embodiments, the NLP module 566 may output the results of the NLP to an intelligence service client.

In embodiments, the NLP module 566 provides an intelligence service client with the ability to parse one or more conversational voice instructions provided by a human user to perform one or more tasks as well as communicate with the human user. The NLP module 566 may perform speech recognition to recognize the voice instructions, natural language understanding to parse and derive meaning from the instructions, and natural language generation to generate a voice response for the user upon processing of the user instructions. In some embodiments, the NLP module 566 enables an intelligence service client 550 to understand the instructions and, upon successful completion of the task by the intelligence service client 550, provide a response to the user. In embodiments, the NLP module 566 may formulate and ask questions to a user if the context of the user request is not completely clear. In embodiments, the NLP module 566 may utilize inputs received from one or more sensors including vision sensors, location-based data (e.g., GPS data) to determine context information associated with processed speech or text data.

In embodiments, the NLP module 566 uses neural networks when performing NLP tasks, such as recurrent neural networks, long short term memory (LSTMs), gated recurrent unit (GRUs), transformer neural networks, convolutional neural networks, and/or the like.

In various implementations, the segment analysis module 400 may include a sustainability analysis module 410, a finance analysis module 440, a farm analysis module 420, an insurance analysis module 450, a policy analysis module 430, and a commerce analysis module 460. The segment analysis module 400 may be further associated with the configured intelligence services 500 and the stakeholder service modules 600.

In embodiments, the sustainability analysis module 410 may provide data handling, analytics, prediction and recommendation methods and systems, as described herein relating to sustainable agricultural practices, government and other programs and incentives relating to sustainable agricultural practices, financial and economic factors relating to sustainable agricultural practices, and the like. In embodiments, the finance analysis module 440 may provide data handling, analytics, prediction and recommendation methods and systems, as described herein relating to agricultural finance, agricultural product finance and procurement, farmland finance and procurement, equipment finance and procurement, and the like. In embodiments, the farm analysis module 420 may provide data handling, analytics, prediction and recommendation methods and systems, as described herein relating to farm performance, predicted agricultural outcomes (e.g., crop yield), product selection, the timing of farming activities, the selection and application of agricultural products and services, and the like. In embodiments, the insurance analysis module 450 may provide data handling, analytics, prediction and recommendation methods and systems, as described herein relating to agricultural insurance, agricultural product and equipment insurance, farmland and crop failure/damage insurance, and the like. In embodiments, the policy analysis module 430 may provide data handling, analytics, prediction and recommendation methods and systems, as described herein relating to agricultural policies (e.g., federal, state, county) impacting farming practices, finance, regulatory compliance, subsidy benefits, product and equipment pricing, labor usage, and the like. In embodiments, the commerce analysis module 460 may provide data handling, analytics, prediction and recommendation methods and systems, as described herein relating to commercial and product procurement activities, and the like.

The segment analysis module 400 may be further associated with the configured intelligence services 500 and stakeholder service modules 600. In various implementations, the configured intelligence services module 500 may include an intelligence controller module 510 that includes an analysis module 520 and a governance module 522. The configured intelligence services module 500 may also include an intelligence functions module 530.

The analysis and analytics module 520 may analyze components of the system of platforms 100 (and interactions between components) for compliance with various federal and state laws, regulations, and rules governing financial institutions. This may include ethics analysis for analyzing ethical rules governing financial institutions. The analysis module may analyze blockchains and markets and exchanges based on pricing metrics, news, and performance data (such as technical data). In various implementations, the analysis and analytics module 520 may perform technical analysis on markets and exchanges by analyzing price movements and trading volumes over specific periods of time to calculate metrics such as relative strength and/or moving averages, and/or performs regressions on market data to determine relationships between variables. In various implementations, the analysis and analytics module 520 may use mathematical indicators to evaluate statistical trends to predict price direction in the agricultural, commodities and/or other markets, such as by analyzing past price changes and volume data to predict future price changes. The analysis and analytics module 520 may analyze components of the system of platforms and marketplace 100 (and interactions between components) for legal compliance with various federal and state laws, regulations, and rules governing financial institutions.

In various implementations, the governance library 540 may include a training model standards library, a legal standards library, a regulatory standards library, and a custom standards library. The training model standards library may contain data governing the training of each of the various machine learning models of the analysis module 101. The legal standards library may contain rules related to federal and state laws that are suitable for use by the analysis and analytics module 520. The regulatory standards library may contain rules related to federal and state regulations and rules that are suitable for use by the analysis and analytics module 520. The custom standards library may contain custom rules set by users that are suitable for use by the analysis and analytics module 520.

In embodiments, artificial intelligence modules 560 may include and/or provide access to a rules-based module 562 that may be integrated into or be accessed by an intelligence service client 550. In some embodiments, a rules-based module 562 may be configured with programmatic logic that defines a set of rules and other conditions that trigger certain actions that may be performed in connection with an intelligence client. In embodiments, the rule-based module 562 may be configured with programmatic logic that receives input and determines whether one or more rules are met based on the input. If a condition is met, the rules-based module 562 determines an action to perform, which may be output to a requesting intelligence service client 550. The data received by the rules-based engine may be received from an intelligence service input source and/or may be requested from another module in artificial intelligence modules 560, such as the machine vision module 565, the neural network module 567, the ML module 561, and/or the like. For example, a rule-based module 562 may receive classifications of objects in a field of view (e.g., a satellite image, a view from a farming vehicle, or the like) from a machine vision system and/or sensor data. In embodiments, the rules-based module 562 may be configured to make other suitable rules-based decisions on behalf of a respective client, examples of which are discussed throughout the disclosure. In some embodiments, the rules-based engine may apply governance standards and/or analytics, which are described in greater detail herein.

In embodiments, intelligence services 500 may be configured to determine a type of request issued by an intelligence service client 550 and, in response, may determine a set of governance standards and/or analyses that are to be applied by the artificial intelligence modules 560 when responding to the request. In embodiments, the intelligence services 500 may include an analysis management module, a set of analysis modules, and a governance library. In embodiments, the intelligent analytics module 520 may receive an artificial intelligence module 560 request and determines the governance standards and/or analyses implicated by the request. In embodiments, the intelligent analytics module 520 may determine the governance standards that apply to the request based on the type of decision that was requested and/or whether certain analyses are to be performed with respect to the requested decision. For example, a request for a control decision that results in an intelligence service client 550 performing an action may implicate a certain set of governance standards that apply, such as safety standards, legal standards, regulatory standards, quality standards, or the like, and/or may implicate one or more analyses regarding the control decision, such as a risk analysis, a safety analysis, an engineering analysis, or the like.

In some embodiments, the intelligent analytics module 520 may determine the governance standards that apply to a decision request based on one or more conditions. Non-limiting examples of such conditions may include the type of decision that is requested, a geolocation in which a decision is being made, an environment that the decision will affect (e.g., a farm or specific parcel or region of land), current or predicted environment conditions of the environment (e.g., weather data, precipitation history, climatology forecasts) and/or the like. In embodiments, the governance standards may be defined as a set of standards libraries stored in a governance library. In embodiments, standards libraries may define conditions, thresholds, rules, recommendations, or other suitable parameters by which a decision may be analyzed. Examples of standards libraries may include, legal standards library, a regulatory standards library, a quality standards library, an engineering standards library, a safety standards library, a financial standards library, and/or other suitable types of standards libraries. In embodiments, the governance library may include an index that indexes certain standards defined in the respective standards library based on different conditions. Examples of conditions may be a jurisdiction or geographic areas to which certain standards apply, environmental conditions to which certain standards apply, device types to which certain standards apply, materials or products to which certain standards apply, and/or the like.

In some embodiments, the intelligent analytics module 520 may determine the appropriate set of standards that must be applied with respect to a particular decision and may provide the appropriate set of standards to the artificial intelligence modules 560, such that the artificial intelligence modules 560 leverage the implicated governance standards when determining a decision. In these embodiments, the artificial intelligence modules 560 may be configured to apply the standards in the decision-making process, such that a decision output by the artificial intelligence modules 560 is consistent with the implicated governance standards. It is appreciated that the standards libraries in the governance library may be defined by the platform provider, customers, and/or third parties. The standards may be government standards, industry standards, customer standards, or other suitable sources. In embodiments, each set of standards may include a set of conditions that implicate the respective set of standards, such that the conditions may be used to determine which standards to apply given a situation.

In various implementations, the stakeholder service modules 600 may include a forecasting and prediction module 610, a demand intelligence module 640, a recommendation engine 620, an automated planning module 650, an outcome analysis module 630, and a transaction aggregation analysis module 660. In embodiments, the forecasting and prediction module 610 may provide data handling, analytics, prediction and recommendation methods and systems, as described herein relating to agricultural practices, decision making, procurement and other agricultural activities. In embodiments, the demand intelligence module 640 may provide data handling, analytics, prediction and recommendation methods and systems, as described herein relating to economic and market factors impacting agricultural practices, decision making, procurement and other agricultural activities, including but not limited to market demand, market preference, market forecasting, and the like. In embodiments, the recommendation engine 620 may provide data handling, analytics, prediction and recommendation methods and systems, as described herein relating to agricultural practices, decision making, procurement and other agricultural activities, such as crop and product recommendations, vendor and supplier recommendations, recommendations related to crop planning, timing and selection, and the like. In embodiments, the automated planning module 650 may provide data handling, analytics, prediction and recommendation methods and systems, as described herein relating to the automated generation of agricultural plans, such as the timing of planting, the timing of the application of agricultural products to a crop or parcel of land, equipment planning including the sale or procurement of equipment based at least in part on a crop plan or other recommendation generated by the platform 100.

In embodiments, the outcome analysis module 630 may provide data handling, analytics, prediction and recommendation methods and systems, as described herein relating to agricultural practices, products, land management, and the like.

In embodiments, the transaction aggregation module 660 may classify transactions performed by the components of the system of platforms and marketplace 100 (and transactions between components), classifying each transaction into one or more categories. The transaction aggregation module 660 may monitor transactions between the components of the system of platforms and marketplace 100 for each transaction or group of transactions, or for each user or group of users. In various implementations, the transaction aggregation module 660 may monitor transactions within each transaction or group of transactions (or for each user or group of users) to determine whether the monitored transaction fits a generated profile, and whether a plurality of transactions may be aggregated into a single transaction in order to, for example, benefit the transactors by the transaction aggregation reducing overall cost of the transacted goods or services, speeding the production or delivery of the transacted goods or services, or producing some other benefit by aggregating the transactions. In various implementations, if the monitored transaction does not fit a generated profile, the transaction aggregation module 660 may generate an alert and/or halt the monitored transaction from participating in a would-be transaction aggregation.

In various implementations, the stakeholder-specific reporting, recommendation and optimization modules 700 may include a newsletters module 710, a direct-to-farm module 720, a seed producer module 730, a direct buyer module 740, a policy maker module 750, a bank and lender module 760, an agricultural retailer module 770, an outcomes module 780, a logistics provider module 790, a technology developers module 800, an equipment producers module 810, a service providers module 820, an insurers module 830, and an investors module 840. In embodiments, the system of platforms and marketplace 100 may include bridging and integration modules including a stakeholder systems integration module 900. In various implementations, the stakeholder systems integration module 900 may include portals and distributed apps (dApps), a blockchain services, smart contract services, payment automation services, and distributed ledger services bridging components of the analysis module 101 with external portals, decentralized apps, and the like. Blockchain services may bridge components of the analysis module 101 with external blockchain services. Smart contract services may bridge components of the analysis module 101 with external smart contract applications. Payment automation services may bridge components of the analysis module 101 with external payment automation applications. Distributed ledger services may bridge components of the analysis module 101 with external payment automation applications.

In various implementations, a stakeholder systems integration module 900 may be included in the system of platforms and marketplace 100. The analysis module 101 may communicate with stakeholder systems 1000 based at least in part by using the stakeholder systems integration module 900. The stakeholder systems integration module 900 may be further associated with a results-based analysis and feedback optimization module 920. In embodiments, stakeholder systems 1000 may include a stakeholder-adapted service and reporting modules 1010 and stakeholder-specific configured intelligence services 1020. In embodiments, the stakeholder systems integration module 900 may include a system integration services, a user interface (UI), applications library, application programming interface (API), data visualization services, a software development kit. The stakeholder systems integration module 900 may perform system integration functions between components of the analysis module 101 and external devices. The user interface may generate and output user interfaces accessible by components of the system of platforms and marketplace 100. The applications library may contain applications that may be accessed by the external systems 600 through the API. The applications may interface with other components of the analysis module 101 and/or the other components of the system of platforms and marketplace 100. The API may facilitate communications between the applications and modules of the analysis module 101 and the external systems 600, such as the various components of the system of platforms and marketplace 100, including data visualization that may generate visual models that may be stored and/or output to the user interface (and subsequently rendered on the user interface). The SDK may contain a collection of software development tools suitable for creating and modifying applications, such as those of the applications library.

In embodiments, the system of platforms and marketplace 100, as described herein, may include a system having a farm profile data structure, wherein the farm profile data structure represents a set of attributes selected from a set of geographic attributes, a set of geological attributes, a set of soil attributes, a set of climate attributes, a set of weather attributes, a set of farm economic attributes, a set of crop attributes, and a set of farmer preference attributes.

In embodiments, the system of platforms and marketplace 100, as described herein, may include a system having a digital twin of a farm, wherein the digital twin has a communication connection to a set of IoT devices that collect sensor data representing farm attributes.

In embodiments, the system of platforms and marketplace 100, as described herein, may include a system having a farm profile data structure, wherein the farm profile data structure including at least a set of geographic attributes, a set of geological attributes, a set of soil attributes, a set of climate attributes, a set of weather attributes, a set of farm economic attributes, a set of crop attributes, and a set of farmer preference attributes.

In embodiments, the system of platforms and marketplace 100, as described herein, may include a system having a farm profile data structure, wherein the farm profile data structure represents a set of attributes selected from a set of geographic attributes, a set of geological attributes, a set of soil attributes, a set of climate attributes, a set of weather attributes, a set of farm economic attributes a set of crop attributes, and a set of farmer preference attributes, wherein the farmer preference attributes are inferred based on a data set representing a set of transactions undertaken by the farmer in a marketplace.

In embodiments, the system of platforms and marketplace 100, as described herein, may include a system having a digital twin of a farm, wherein the digital twin has a communication connection to a set of IoT devices that collect sensor data representing farm attributes, wherein the set of attributes includes at least a set of geographic attributes, a set of geological attributes, a set of soil attributes, a set of climate attributes, a set of weather attributes, a set of farm economic attributes, a set of crop attributes, and a set of farmer attributes.

In embodiments, the system of platforms and marketplace 100, as described herein, may include a system having a platform having a set of services configured to collect farm attribute data, farmer attribute data and economic data into a unified data set.

In embodiments, the system of platforms and marketplace 100, as described herein, may include a system having a fused data set having a farm profile data set having a set of attributes selected from a set of geographic attributes, a set of geological attributes, a set of soil attributes, a set of climate attributes, a set of weather attributes, a set of farm economic attributes and a set of crop attributes; a farmer data set having a set of farmer preference attributes, a set of farmer psychographic attributes, a set of farmer behavioral attributes, a set of farmer demographic attributes, a set of farmer location attributes, a set of farmer physiological attributes and a set of farmer economic attributes; and an economic data set having a set of current market price attributes for a set of crops, a set of forward market price attributes for a set of crops, a set of current market price attributes for a set of livestock, a set of forward market price attributes for a set of livestock, a set of current market price attributes for a set of animal products, a set of forward market price attributes for a set of animal products, a set of macroeconomic attributes for a jurisdiction, and set of microeconomic attributes for an entity.

In embodiments, the system of platforms and marketplace 100, as described herein, may include a system having a fused data set having a farm profile data set having a set of attributes selected from a set of geographic attributes, a set of geological attributes, a set of soil attributes, a set of climate attributes, a set of weather attributes, a set of farm economic attributes and a set of crop attributes and a farmer data set having a set of farmer preference attributes, a set of farmer psychographic attributes, a set of farmer behavioral attributes, a set of farmer demographic attributes, a set of farmer location attributes, a set of farmer physiological attributes and a set of farmer economic attributes.

In embodiments, the system of platforms and marketplace 100, as described herein, may include a system having a fused data set having a farm profile data set having a set of attributes selected from a set of geographic attributes, a set of geological attributes, a set of soil attributes, a set of climate attributes, a set of weather attributes, a set of farm economic attributes and a set of crop attributes and an economic data set having a set of current market price attributes for a set of crops, a set of forward market price attributes for a set of crops, a set of current market price attributes for a set of livestock, a set of forward market price attributes for a set of livestock, a set of current market price attributes for a set of animal products, a set of forward market price attributes for a set of animal products, a set of macroeconomic attributes for a jurisdiction, and set of microeconomic attributes for an entity.

In embodiments, the system of platforms and marketplace 100, as described herein, may include a system having a fused data set having a farmer data set having a set of farmer preference attributes, a set of farmer psychographic attributes, a set of farmer behavioral attributes, a set of farmer demographic attributes, a set of farmer location attributes, a set of farmer physiological attributes and a set of farmer economic attributes; and an economic data set having a set of current market price attributes for a set of crops, a set of forward market price attributes for a set of crops, a set of current market price attributes for a set of livestock, a set of forward market price attributes for a set of livestock, a set of current market price attributes for a set of animal products, a set of forward market price attributes for a set of animal products, a set of macroeconomic attributes for a jurisdiction, and set of microeconomic attributes for an entity.

In embodiments, the system of platforms and marketplace 100, as described herein, may include a system having a clustering engine that clusters a set of farms based on similarity of attributes.

In embodiments, the system of platforms and marketplace 100, as described herein, may include a system having an aggregation engine that aggregates a set of farms based on a set of shared attributes.

In embodiments, the system of platforms and marketplace 100, as described herein, may include a system having a clustering engine that clusters a set of farms based on similarity of farm attributes selected from a set of geographic attributes, a set of geological attributes, a set of soil attributes, a set of climate attributes, a set of weather attributes, a set of farm economic attributes, a set of farm economic attributes and a set of crop attributes.

In embodiments, the system of platforms and marketplace 100, as described herein, may include a system having a clustering engine that clusters a set of farms based on similarity farmer attributes selected from a set of farmer preference attributes, a set of farmer psychographic attributes, a set of farmer behavioral attributes, a set of farmer demographic attributes, a set of farmer location attributes, a set of farmer physiological attributes and a set of farmer economic attributes.

In embodiments, the system of platforms and marketplace 100, as described herein, may include a system having an aggregation engine that aggregates demand for a set of farms based on shared demand attributes of the farms.

In embodiments, the system of platforms and marketplace 100, as described herein, may include a system having an aggregation engine that aggregates demand for a set of farm-related products or services across a set of farmers based on a shared set of preferences of the farmers.

In embodiments, the system of platforms and marketplace 100, as described herein, may include a system having an aggregation engine that aggregates demand for a set of farm-related products or services for a set of farms that have been clustered based on shared attributes, where the aggregate demand is based on a shared set of needs of the farms that is determined based on a shared set of farm attributes and based on a shared set of farmer preferences for farmers that own or operate the set of farms.

In embodiments, the system of platforms and marketplace 100, as described herein, may include a system having a profile data structure having a set of farmer attributes that include a set of demographic attributes, a set of psychographic attributes and a set of behavioral profile attributes.

In embodiments, the system of platforms and marketplace 100, as described herein, may include a system having a profile data structure having a set of farmer attributes that include a set of demographic attributes selected from a set of income attributes, a set of wealth attributes, a set of education attributes, a set geolocation attributes, a set of age attributes, and a set of health attributes.

In embodiments, the system of platforms and marketplace 100, as described herein, may include a profile data structure having a set of farmer attributes selected from a set of psychographic attributes selected from a set of product affinity attributes, a set of religious affinity attributes, a set of personality attributes, a set of political affinity attributes, and a set of brand affinity attributes.

In embodiments, the system of platforms and marketplace 100, as described herein, may include A system having a profile data structure having a set of farmer attributes selected from a set of farmer behavioral profile attributes selected from a set of purchasing behavior attributes, a set of price elasticity behavior attributes, a set of product selection behavior attributes, a set of crop rotation behavior attributes, a set of crop selection behavior attributes, a set of crop planting behavior attributes, and a set of crop harvesting behavior attributes.

In embodiments, the system of platforms and marketplace 100, as described herein, may include a clustering engine that clusters a set of farmers based on similarity of attributes.

In embodiments, the system of platforms and marketplace 100, as described herein, may include an aggregation engine that aggregates a set of farmers based on a set of shared attributes.

In embodiments, the system of platforms and marketplace 100, as described herein, may include a clustering engine that clusters a set of farmers based on similarity of farm attributes of the farms they own or operate, where the farm attribute are selected from a set of geographic attributes, a set of geological attributes, a set of soil attributes, a set of climate attributes, a set of weather attributes, a set of farm economic attributes, a set of farm economic attributes and a set of crop attributes.

In embodiments, the system of platforms and marketplace 100, as described herein, may include a clustering engine that clusters a set of farmers based on similarity farmer attributes selected from a set of farmer preference attributes, a set of farmer psychographic attributes, a set of farmer behavioral attributes, a set of farmer demographic attributes, a set of farmer location attributes, a set of farmer physiological attributes and a set of farmer economic attributes.

In embodiments, the system of platforms and marketplace 100, as described herein, may include a marketplace platform for the marketing and exchange of farm-related products and services, the marketplace platform having a set of interfaces, which each interface is configured for a stakeholder selected from among a farm owner, a farm operator, a farm product vendor, a farm services vendor, a lender, an insurer, a regulator and a farm worker.

In embodiments, the system of platforms and marketplace 100, as described herein, may include a marketplace platform for the marketing and exchange of farm-related products and services, the marketplace platform having a set of application programming interfaces by which a set of external programs and services may access a set of services of the platform to enable a set of transactions among stakeholders of the platform.

In embodiments, the system of platforms and marketplace 100, as described herein, may include a method comprising remotely detecting a plurality of plant varieties under cultivation on a plurality of defined parcels of land, based at least in part on aerial imagery, land photography, transaction history and the like, remotely detecting an agricultural outcome (e.g., yield), and modeling the association of a plant variety with yield while controlling for characteristics of the plurality of defined parcels of land (e.g., soil type, climate, geolocation etc.).

In embodiments, the system of platforms and marketplace 100, as described herein, may include a method comprising an analytic engine for optimizing a parameter of crop protection based on a set of yield outcomes for a set of crops.

In embodiments, the system of platforms and marketplace 100, as described herein, may include a method comprising a machine learning system that is trained on a data set of crop parameters, crop protection parameters, and set of crop yield outcomes to provide a recommendation for optimization of crop protection parameters for a set of crops having a set of crop parameters.

In embodiments, the system of platforms and marketplace 100, as described herein, may include a system comprising an analytic engine for calculating and storing a financial value associated with a land attribute, a profile data structure having a set of land attributes related to a defined parcel of land selected from a set of land attributes.

In embodiments, the system of platforms and marketplace 100, as described herein, may include a system comprising an analytic engine for calculating and storing a financial value associated with a land attribute, a profile data structure having a set of land attributes related to a defined parcel of land selected from a set of land attributes, and a valuation engine for calculating a value of the defined parcel of land based at least in part on the stored financial values associated with the set of land attributes related to the defined parcel.

In embodiments, the system of platforms and marketplace 100, as described herein, may include a system comprising an analytic engine for calculating and storing a financial value associated with a crop performance attribute, a profile data structure having a set of crop performance attributes related to a defined parcel of land selected from a set of crop performance attributes, and a valuation engine for calculating a value of the defined parcel of land based at least in part on the stored financial values associated with the set of crop performance attributes related to the defined parcel.

In embodiments, the system of platforms and marketplace 100, as described herein, may include a system comprising an analytic engine for calculating a recommended loan amount for a defined parcel of land, where the loan amount is based at least in part on stored valuations associated with crop performance attributes and land attributes that are associated with the defined parcel.

In embodiments, the system of platforms and marketplace 100, as described herein, may include a system comprising an analytic engine for calculating a recommended insurance parameter amount for a defined parcel of land based at least in part on stored valuations associated with land characteristics.

In embodiments, the system of platforms and marketplace 100, as described herein, may include a system comprising an analytic engine for calculating a recommended insurance coverage amount for a defined parcel of land, where the insurance coverage amount is based at least in part on stored valuations associated with crop performance attributes and land attributes that are associated with the defined parcel.

In embodiments, the system of platforms and marketplace 100, as described herein, may include a system comprising an analytic engine for calculating a recommended insurance premium amount for a defined parcel of land, where the insurance premium amount is based at least in part on stored valuations associated with crop performance attributes and land attributes that are associated with the defined parcel.

In embodiments, the system of platforms and marketplace 100, as described herein, may include a system comprising a clustering engine that clusters a set of farm properties based on a similarity of stored attributes; an imaging engine that documents a current crop status of at least a subset of the set of farm properties; a comparison engine for comparing a current crop status between two or more properties, where the properties are selected based on at least one shared attribute; and a recommendation engine for selecting an adjuvant for at least one of the properties based at least in part on the adjuvant being used on at least one of the properties that has a favorable current crop status.

In embodiments, the system of platforms and marketplace 100, as described herein, may include a method comprising monitoring a bovine's diet and measuring amino acids present during digestion; measuring the amount of microbial protein that flows in digestion, analyzing the measured microbial protein in conjunction with other measured microbial protein samples taken from other bovines, where the other bovines are matched to the bovine based at least in part on one criterion, and making a diet augmentation recommendation for the bovine where the recommendation probabilistically improves the bovine's amino acid processing during digestion based on the analysis.

In embodiments, the system of platforms and marketplace 100, as described herein, may include a method comprising monitoring a bovine's diet and measuring amino acids present during digestion; measuring the amount of microbial protein that flows in digestion, analyzing the measured microbial protein in conjunction with other measured microbial protein samples taken from other bovines, where the other bovines are matched to the bovine based at least in part on one criterion, and making a recommendation for a liquid feed formulation the bovine where the liquid feed formulation includes amino acids selected in part on the components of the bovine's diet.

In embodiments, the system of platforms and marketplace 100, as described herein, may include a system comprising a farm profile data structure, wherein the farm profile data structure represents a set of farming practice attributes selected from a set of attributes associated with a parcel of land, a set of farming practice attributes from a plurality of parcels of land, where the set is further associated with carbon emission measurements related to the farming practice attributes, a set of soil attributes, a set of climate attributes, a set of weather attributes, a set of farm economic attributes, a set of crop attributes, and an analytic engine, where the analytic engine models carbon emission on the parcel of land based at least in part on the set of farming practice attributes selected from a set of attributes associated with a parcel of land.

In embodiments, the system of platforms and marketplace 100, as described herein, may include a system comprising a farm profile data structure, wherein the farm profile data structure represents a set of attributes selected from a set of geographic attributes, a set of farming practice attributes selected from a set of attributes associated with a parcel of land, a set of geological attributes, a set of soil attributes, a set of climate attributes, a set of weather attributes, a set of farm economic attributes, a set of crop attributes, a set of farmer preference attributes, and an analytic engine, where the analytic engine models the farm profile data structure to generate a recommendation for a product for use on the parcel of land.

In embodiments, the system of platforms and marketplace 100, as described herein, may include a method comprising storing a plurality of characteristics of a plurality of defined parcels of land, modeling environmental data and associations with an agricultural outcome while controlling for the characteristics of a plurality of defined parcels of land, detecting a current environmental datum in proximity to the defied parcels of land, and recommending a cultivation change for at least one of the plurality of defined parcels based on the modeled impact of the current environmental datum.

In embodiments, the system of platforms and marketplace 100, as described herein, may include a system comprising a prediction engine for calculating and storing a future state for a defined parcel of land based at least in part on a profile data structure related to a plurality of land parcels having at least one attribute in common with the defined parcel.

In embodiments, the system of platforms and marketplace 100, as described herein, may include a system comprising a prediction engine for calculating and storing a future crop performance metric for a defined parcel of land based at least in part on a profile data structure related to a plurality of land parcels having at least one attribute in common with the defined parcel, including a past crop performance attribute or a land attribute.

In embodiments, the system of platforms and marketplace 100, as described herein, may include a system comprising a prediction engine for calculating and storing a future product need for a defined parcel of land based at least in part on a profile data structure related to a plurality of land parcels having at least one attribute in common with the defined parcel, including a crop type or a land attribute or a climate attribute or a geographic attribute.

In embodiments, the system of platforms and marketplace 100, as described herein, may include a system comprising an inventory system for tracking the purchase, delivery and storage of agricultural products, a prediction engine for calculating a future product need for a defined geolocation based at least in part on a profile related to a plurality of land parcels within the geolocation.

In embodiments, the system of platforms and marketplace 100, as described herein, may include a system comprising an inventory system for optimizing the timing of purchase and the amount of agricultural product purchased for a defined geolocation based at least in part on a detected condition associated with agricultural property within the geolocation, wherein the detected condition is a crop type or a land attribute or a climate attribute or a geographic attribute.

In embodiments, the system of platforms and marketplace 100, as described herein, may include a system comprising an inventory system for optimizing the shipment of an agricultural product from a first defined geolocation to a second defined geolocation based at least in part on a detected condition associated with agricultural property within the first and second geolocations, wherein the detected condition is a crop type or a land attribute or a climate attribute or a geographic attribute.

In embodiments, the system of platforms and marketplace 100, as described herein, may include a method comprising screening a plurality of ploidy levels in a plurality of crop cultivars, where the screening is conducted on a plurality of parcels of land and within a controlled lab environment and where the plurality of land parcels are selected and matched based at least on a criterion (e.g., soil type, climate), and ranking the plurality of crop cultivars based in part on the ploidy screening, where the ranking is based in part on an economically advantageous trait of the cultivar (e.g., plant morphology).

In embodiments, the system of platforms and marketplace 100, as described herein, may include a method comprising selecting a plurality of parcels of land under cultivation based at least upon the parcels having a shared characteristic (e.g., soil type, climate type, crop cultivate and the like), and a unique cultivation practice not fully shared among the plurality of parcels; collecting data related to an agricultural outcome (e.g., yield) from the plurality and using the data to model the association of the unique cultivation practices with the agricultural outcome.

In embodiments, the system of platforms and marketplace 100, as described herein, may include a method comprising selecting a plurality of parcels of land under cultivation based at least upon the parcels having a shared characteristic and a unique fertilization practice not fully shared among the plurality of parcels; collecting data related to an agricultural outcome (e.g., yield) from the plurality and using the data to model the association of the unique fertilization practice with the agricultural outcome.

In embodiments, the system of platforms and marketplace 100, as described herein, may include selecting a plurality of parcels of land under cultivation based at least upon the parcels having a set of shared characteristics and a set of unique pairs of cultivation practices not fully shared among the plurality of parcels; collecting data related to an agricultural outcome (e.g., yield) from the plurality and using the data to model the association of the unique pairs of cultivation practices with the agricultural outcome to provide an analytic result indicating what cultivation practices are favorably paired.

In embodiments, the system of platforms and marketplace 100, as described herein, may include a method comprising aggregating a transaction for at least one product, wherein the aggregated transaction includes multiple entities that are parties to the transaction who are automatically identified as appropriate for the transaction based at least in part on a characteristic of a parcel of land they are associated with, and structuring a smart contract to record each of the multiple entities' proportionate ownership of the product subject to the transaction, and recording proportionate ownership and payment in a blockchain upon transaction settlement.

In embodiments, the system of platforms and marketplace 100, as described herein, may include a method comprising predicting a product need for a defined parcel of land based at least in part on a profile data structure related to a plurality of land parcels having at least one attribute in common with the first and second defined parcels, including a crop type or a land attribute or a climate attribute or a geographic attribute; identifying a producer of a product associated with the product need; structuring a smart contract term related to an offer for sale of the product, and presenting the offer for sale to a party associated with the defined parcel of land.

In embodiments, the system of platforms and marketplace 100, as described herein, may include a system comprising a prediction engine for calculating and storing a future product need for a first defined parcel of land and a second defined parcel of land based at least in part on a profile data structure related to a plurality of land parcels having at least one attribute in common with the first and second defined parcels, including a crop type or a land attribute or a climate attribute or a geographic attribute, and a transaction aggregation engine for combining, into a single transaction request, an order that includes a product associated with the future product need of the first and second parcels of land.

In embodiments, the system of platforms and marketplace 100, as described herein, may include a method comprising identifying a program having a benefit for a type of parcel of land and the data and reporting requirements for participation in the program; structuring a data pipeline to stream data related to a parcel of land matching the type, wherein the data that is streamed is selected at least based in part on conforming to the reporting requirements.

In embodiments, the system of platforms and marketplace 100, as described herein, may include a method comprising an analytic engine for optimizing a parameter of crop protection based on a set of yield outcomes for a set of crops.

In embodiments, a generative artificial intelligence engine (GAIE) may be integrated with a system of platforms and marketplace system 100. This integration may enhance the capabilities of the agricultural platforms and marketplace system 100 by enabling advanced data processing, predictive analytics, and personalized stakeholder interactions. Terms such as “generative artificial intelligence engine,” “generative-AI” and the like, as used herein, include large language models (LLMs), deep learning models, fine tuning, reinforcement learning with human feedback, neural network models, retrieval augmented generation, variational autoencoders, transformers, generative adversarial networks, diffusion models, and other artificial methods, systems, techniques, applications and processes.

In embodiments, the system of platforms and marketplace 100 may include various modules such as data collection, analysis, reporting, and marketplace functionalities. The GAIE may be integrated to enhance these functionalities, in part, by providing advanced generative and predictive capabilities. The GAIE may be capable of processing diverse data types including images, text, and sensor data. The GAIE may utilize advanced machine learning algorithms to generate predictive models and insights. In embodiments, key capabilities may include, but are not limited to, generating textual and visual content based on agricultural data, predicting agricultural outcomes such as crop yield and soil health, and/or personalizing content and recommendations for different stakeholders.

In embodiments, the GAIE may interface with the system of platforms and marketplace 100 through various touchpoints including, but not limited to 1) Data processing—the GAIE may receive raw data from the system of platforms and marketplace's data collection modules and processes it to generate insights and predictions; 2) Decision support—analytic insights may be generated by the GAIE and fed back into the system of platforms and marketplace 100 to aid in decision-making processes; 3) Marketplace functionality—the GAIE may enhance the marketplace platform by generating personalized product recommendations and facilitating intelligent matchmaking between buyers and sellers.

In embodiments, a digital twin of a farm, or other agricultural entity, may use the GAIE-generated data to optimize operations. The system of platforms and marketplace 100 may use the GAIE to, for example, cluster farmers based on preferences and behaviors, enhancing the relevance of marketplace interactions. Predictive models generated by the GAIE may help in forecasting future product needs and optimizing the supply chain. The integration of a GAIE with the system of platforms and marketplace 100 may enhance the intelligence, efficiency, and user engagement of agricultural technology platforms. This integrated system may not only improve agricultural outcomes but also streamline marketplace transactions, making it a valuable advancement in agricultural technology.

In embodiments, the integrated system of platforms and marketplace 100, enhanced by the GAIE, may optimize crop management and sales in the marketplace. In embodiments, the GAIE may improve a sales strategy in the marketplace by utilizing, for example, the following steps: 1) Data collection-data may be continuously transmitted to the system of platforms and marketplace 100, where it is stored and categorized for further processing. This data may include soil moisture, weather conditions, crop health, and the like; 2) Data processing and analysis by GAIE—the GAIE may receive the agricultural raw data and process it using advanced machine learning algorithms to analyze patterns in the data, such as the relationship between weather conditions and crop health, and then may generate predictive models. The GAIE may also identify optimal planting and harvesting times based on historical data and current conditions; 3) Decision support—the GAIE may generate a series of recommendations which may include, but are not limited to, adjustments to irrigation schedules to optimize water usage, recommendations for fertilizer application tailored to current soil health, and predictions on the best times to plant and harvest for maximum yield. 4) Marketplace interaction—the GAIE may assist in planning a sales strategy, analyze current market trends and demand forecasts in the system of platforms and marketplace 100, and the GAIE may generate personalized sales, suggesting the best times to sell crops and recommending potential buyers who might be interested based on their purchasing history. 5) Transaction facilitation—the GAIE may help optimize a list of upcoming crop yield in the marketplace by suggesting pricing strategies and promotional content based on what has worked well for similar products, and the system may automatically match the listings with interested buyers, facilitating negotiations and transactions directly within the platform. 6) Feedback and optimization—the system may collect feedback from the buyers after the sales transaction, and the GAIE may process this feedback to further refine its predictive models and recommendations, continuously improving the accuracy and relevance of its support. 7) Continuous learning and adaptation—the GAIE may continue to learn from ongoing data collected from farmers and others in the network. It may also adapt its models to changes in climate patterns, market dynamics, and farming practices. The GAIE may give regular updates to the farmers to help them stay ahead of potential issues and opportunities in farming operations.

In embodiments, the integration of the GAIE with the system of platforms and marketplace 100 may transform traditional farming into a data-driven, optimized practice. By leveraging real-time data analysis and predictive modeling, farmers may then make informed decisions that enhance both agricultural productivity and business outcomes.

In embodiments, the GAIE may be integrated with the system of platforms and marketplace 100, and may produce updated recommendation and insights based on new data ingested and processed, from, for example, a farmer's operation.

In embodiments, the GAIE may be capable of data ingestion and processing by the workflow outline, consisting of: 1) Data collection—identifying various data sources on the farm, including IoT devices (e.g., sensors for soil moisture, weather conditions, crop health), farm equipment (e.g., tractors, harvesters with GPS and performance tracking), and manual inputs from, for example, a farmer. Data collected from these sources may be transmitted in real-time or at scheduled intervals to the system of platforms and marketplace 100 via secure internet connections. 2) Data ingestion—the system of platforms and marketplace 100 may receive the data and log it into a preliminary staging area where initial validation checks for completeness and integrity are performed. Data then may be normalized to ensure consistency in format and units across different sources, facilitating easier analysis. 3) Data storage—after normalization, data may be stored in a structured database designed to support quick retrieval and complex querying, essential for effective analysis. Data may then be tagged with metadata (e.g., source type, date, geographic location) and categorized for easier segmentation and retrieval. 4) Data processing by GAIE—the GAIE may access the stored data, pulling relevant datasets based on the current analytical needs. Utilizing machine learning algorithms, the GAIE may perform advanced analytics. This may include trend analysis, pattern recognition, and predictive modeling. The GAIE may generate insights such as optimal planting times, pest control recommendations, and predictive yield estimates. 5) Decision support generation—based on the insights generated, the GAIE may formulate actionable recommendations tailored to the specific conditions and needs of the farm. The GAIE may run simulations to predict the outcomes of different decision scenarios, helping the farmer understand potential impacts before implementing changes. 6) Delivery of recommendations—recommendations and insights may be integrated into the user interface of the system of platforms and marketplace 100, where a user may easily access and review them. Users may receive notifications through the platform, alerting them to new recommendations and important insights. 7) Feedback loop—the user may implement the recommendations, and the system may continue to monitor the results and ongoing data. Feedback on the effectiveness of the recommendations may be collected either through direct input from the user or by analyzing subsequent data showing the results of implemented actions. The GAIE may use this feedback to refine its models and improve the accuracy and relevance of future recommendations. 8) Continuous learning and adaptation—the GAIE may continuously analyze new data as it comes in, adapting its models to changes in environmental conditions, market trends, and farming practices. In embodiments, the cycle of insight and recommendation generation may be ongoing, ensuring that the user always has access to the most current and relevant information.

In embodiments, the GAIE may be used for analysis and decision-making support within the system of platforms and marketplace 100 and may collect various types of data from a user's operations and equipment. In embodiments the data may include: environmental data, (e.g., weather data (e.g., temperature, humidity, rainfall, wind speed, and solar radiation) and soil data (e.g., moisture levels, pH levels, soil temperature, and nutrient content)); crop data (including growth metrics (e.g., plant height, leaf area index, and stages of growth) and health indicators (e.g., signs of disease, pest infestation, and overall plant health assessed through visual or sensor-based monitoring)); equipment data (operational data (e.g., hours of operation, fuel consumption, and maintenance records of farm machinery like tractors, combines, and sprayers) and performance data (efficiency metrics, such as area covered per hour, amount of seed or fertilizer dispensed per area, and yield measurements from harvesters)); irrigation systems data (water usage (e.g., amount of water used, timing of irrigation, and distribution patterns) and system performance (e.g., efficiency of water distribution and status of irrigation equipment)); input application data (fertilizer Usage (e.g., types and quantities of fertilizers applied, application dates, and methods of application (e.g., broadcast, drip)) and pesticide and herbicide usage (types, quantities, and application timing of pesticides and herbicides)); geospatial data (field mapping (e.g., GPS-based data for field boundaries, crop rows, and specific areas of interest within fields) and topography and land use (e.g., elevation data, slope of the land, and current vs. historical land use data)); labor and management data (work logs (e.g., records of labor hours, tasks performed, and personnel involved in various farming activities) and resource allocation (e.g., distribution and usage of resources like manpower, machinery, and financial inputs across different farm operations)); market and economic data (sales data (e.g., information on crop sales, prices received, and quantities sold) and expense records (e.g., costs associated with inputs, labor, machinery, and other operational expenses)); sensor data (remote sensing (e.g., data from drones or satellite imagery providing insights into crop vigor, area coverage, and stress indicators) and on-the-ground sensors (sensors placed in fields that provide real-time data on environmental conditions, soil health, and crop status)); and IoT device data (connected devices: (e.g., data from IoT devices embedded in farm equipment or worn by livestock, providing a continuous stream of operational and health data). In embodiments, these diverse data types, when collected and analyzed, may provide a comprehensive view of an agricultural entity's operations, enabling the GAIE to generate precise and actionable insights tailored to the specific needs and conditions of the farm. This data-driven approach may facilitate optimized decision-making, leading to improved productivity, efficiency, and sustainability in agricultural practices.

In embodiments, the GAIE capabilities within the system of platforms and marketplace 100 may add new products or services into the marketplace platform using a seven step process consisting of: 1) Product/service registration—in embodiments, vendors may register on the platform, providing necessary business and product details, vendors may submit detailed descriptions of new products or services, including specifications, pricing, intended use, and any regulatory compliance information, and the platform may then conduct an initial check to ensure that the submissions meet basic listing criteria and compliance standards. 2) Data enrichment—in embodiments, each product or service may be tagged with relevant metadata, such as category, target audience, geographic relevance, and seasonal timing and the platform may integrate external data sources, such as market trends, consumer behavior data, and competitive analysis, to enrich the product profiles. 3) GAIE analysis for market fit and optimization—in embodiments, the analysis may include, but are not limited to, historical data on similar products/services to predict market demand, potential sales volume, and optimal pricing strategies. The GAIE may use machine learning algorithms to match products/services with potential buyers based on buyer history, preferences, and search behavior, and the GAIE may provide vendors with recommendations on how to improve their product offerings, such as bundling with other products, seasonal promotions, or adjustments in pricing. 4) Listing optimization—in embodiments, based on GAIE insights, product descriptions, images, and keywords may be optimized for better visibility and engagement on the platform, the GAIE may assist in implementing dynamic pricing models that adjust based on demand, inventory levels, and market conditions, and the platform may use the GAIE to create personalized marketing campaigns that may target users who are most likely to be interested in the new products or services. 5) Launch and monitoring—in embodiments, products/services may be launched on the marketplace platform with initial settings optimized by the GAIE, the platform may continuously monitor the performance of each listing through metrics such as views, clicks, sales, and customer feedback, and the GAIE may periodically re-evaluate the product/service data to adjust recommendations and optimizations based on real-time performance and changing market conditions. 6) Feedback loop and continuous improvement—in embodiments, vendors may provide feedback on the effectiveness of the GAIE recommendations and marketplace performance, customer reviews and ratings may be analyzed by the GAIE to gauge consumer satisfaction and areas for improvement and based on feedback and ongoing analysis. The GAIE may iteratively refine the marketing strategies, product placements, and vendor recommendations to enhance marketplace success. 7) Expansion and scaling—in embodiments, successful products/services may be identified for scaling opportunities, such as geographic expansion or targeting new customer segments, and the GAIE may provide insights and strategies for effectively scaling the products/services, leveraging data on similar successful expansions.

In embodiments, this outlined process may ensure that new products or services added to the marketplace are not only compliant and well-integrated but are also optimized for maximum engagement and sales potential through the intelligent capabilities of the GAIE. This approach may help vendors achieve better market penetration and sustained success in the competitive marketplace environment.

In embodiments, the GAIE may be integrated within an agricultural platform and marketplace 100 and may run various types of simulations to model different scenarios and predict outcomes for key decisions such as planting schedules, irrigation strategies, and fertilizer applications.

In embodiments, a simulation may include, but is not limited to, planting schedule simulations that may consist of a seasonal variability simulation (e.g., models the impact of different planting dates on crop yield by considering historical weather data and future weather forecasts. This simulation may help determine the optimal planting window to maximize growth and yield) and crop rotation scenarios (e.g., simulates the effects of various crop rotation strategies on soil health and subsequent crop yields. This includes modeling nutrient depletion and replenishment cycles based on different sequences of crop types).

In embodiments, a simulation may include irrigation management simulations, that may consist of a water usage efficiency (e.g., simulates irrigation schedules under varying weather conditions to optimize water usage without compromising crop health. This can include testing different irrigation methods like drip versus sprinkler systems) and drought response strategies (e.g., models crop responses to different irrigation levels during drought conditions to identify the minimal water requirements that will keep crops healthy and reduce water waste).

In embodiments, a simulation may include fertilizer application simulations, that may consist of nutrient impact analysis (e.g., simulates the impact of different types and amounts of fertilizers on crop growth and soil health. This can help in determining the optimal fertilizer mix and application schedule that maximizes nutrient uptake and minimizes runoff) and cost-benefit scenarios (e.g., evaluates the economic impact of various fertilizer strategies, balancing the cost of fertilizer against the expected increase in yield and market prices).

In embodiments, a simulation may include pest and disease management simulations that may consist of pest infestation models (e.g., simulates the spread of pest infestations across different farming practices and environmental conditions to evaluate the effectiveness of various pest control methods) and disease impact projections (e.g., models the progression of plant diseases under different climatic conditions and agricultural practices to assess the potential impact on crop yield and quality).

In embodiments, a simulation may include climate adaptation simulations, that may consist of climate change scenarios (e.g., projects the long-term impacts of climate change on agricultural productivity by simulating changes in temperature, precipitation, and CO2 levels. This helps in developing adaptation strategies such as selecting climate-resilient crop varieties) and extreme weather preparedness (e.g., simulates farm responses to extreme weather events (e.g., floods, heatwaves) to plan mitigation strategies and emergency responses to minimize damage).

In embodiments, a simulation may include yield optimization simulations, that may consist of genetic variance analysis (e.g., models the performance of different crop varieties under various environmental conditions to identify the varieties that offer the best yield and quality) and technological impact assessment (e.g., simulates the impact of adopting new agricultural technologies, such as automated planting systems or advanced genetic engineering techniques, on farm productivity and sustainability).

In embodiments, a simulation may include market demand forecasting, that may consist of supply-demand matching (e.g., uses historical market data and current crop growth simulations to predict future market demands and align them with production schedules to optimize market supply and pricing strategies).

In embodiments, these simulations, powered by the GAIE, may leverage historical data, real-time inputs, and predictive analytics to provide farmers and agricultural businesses with actionable insights. These insights may help in making informed decisions that enhance productivity, sustainability, and profitability in the agricultural sector.

In embodiments, developing an integrated agricultural platform and marketplace system, especially one that incorporates a GAIE may involve navigating a complex landscape of regulatory requirements and compliance considerations. These regulations may be designed to ensure the safety, privacy, accuracy, and fairness of the technology and its applications. Here are some key regulatory and compliance considerations:

In embodiments, data privacy and security used by the GAIE and the system of platforms and marketplace 100 may include personal data protection: compliance with data protection regulations such as the General Data Protection Regulation (GDPR) in the EU or the California Consumer Privacy Act (CCPA) in the U.S. This may include ensuring that personal data collected through the platform, such as farmer and user details and operational data, are handled securely and transparently, and data security measures: implementing robust cybersecurity measures to protect data from unauthorized access, breaches, and other cyber threats. This may include encryption, secure data storage solutions, and regular security audits.

In embodiments, agricultural compliance may include agricultural standards, such as adherence to local, national, and international agricultural standards and practices. This may include regulations related to crop production, animal husbandry, organic certification, and use of agricultural chemicals, and environmental regulations: compliance with environmental laws and regulations, such as those governing water usage, soil conservation, and pesticide use. This might involve integrating environmental impact assessments into the platform's decision-making processes. In embodiments, AI and machine learning specific regulations may include algorithmic transparency: ensuring that the AI models used are transparent and explainable, particularly when these models impact critical farming decisions. This may assist in maintaining trust and for regulatory purposes where explanations of decisions may be required, and bias and fairness, addressing potential biases in AI algorithms to prevent unfair treatment of certain farmers or regions. Regular audits and updates may be required to ensure AI-driven recommendations are equitable.

In embodiments, the system of platforms and marketplace 100 may include methods and systems for specifying data ownership, for example, clear policies regarding the ownership of data generated and collected by the platform, including data contributed by users and data generated by AI, and proprietary technology: protection of the data rights related to the platform's technology, including patents for unique algorithms and trade secrets for operational methodologies.

In embodiments, the system of platforms and marketplace 100 may include methods and systems for trade and commerce and may include e-commerce regulations, compliance with regulations governing online transactions, including consumer protection laws that ensure transparency of product information and fair trading practices, and cross-border trade, if the platform operates across borders, compliance with international trade laws and regulations, including tariffs, export controls, and customs regulations.

In embodiments, the system of platforms and marketplace 100 may include methods and systems for tracking product and service standards and may include quality assurance, ensuring that all products and services listed on the marketplace meet specific quality standards and are accurately represented to buyers, and certification and labeling, and compliance with certification requirements for agricultural products, such as organic or non-GMO certifications, and proper labeling practices as per local and international laws.

In embodiments, the system of platforms and marketplace 100 may include methods and systems for reporting and documentation and may include regulatory reporting and the ability to generate reports and documentation needed for compliance with agricultural, environmental, and business regulations, and audit trails, including maintaining detailed logs and records of all platform activities to facilitate audits and compliance checks.

In embodiments, the system of platforms and marketplace 100 may include methods and systems for accessibility and inclusion and may include accessibility standards ensuring the platform is accessible to all users, including those with disabilities, in compliance with regulations such as the Americans with Disabilities Act (ADA) or similar legislation in other jurisdictions.

In embodiments, developers of such platforms might engage with legal experts and regulatory consultants early in the development process to ensure all potential legal and compliance issues are addressed. Regular updates and audits to the system of platforms and marketplace 100 may be made to keep up with changing regulations and standards.

In embodiments, the system of platforms and marketplace 100 may include methods and systems for ensuring model fairness and mitigating bias in GAIE algorithms, especially when applied to real-world agricultural decisions.

In embodiments, diverse and representative data may include data collection (e.g., ensure that the data used to train the GAIE algorithms is comprehensive and representative of the diverse conditions and scenarios in agriculture. This may include data from various geographic locations, different types of farms, and diverse farming practices) and continuous data monitoring (regularly monitor and update the dataset to include new information and correct any imbalances or underrepresented segments). In embodiments, bias detection and assessment may include bias audits (e.g., conduct regular audits of the algorithms to identify and measure potential biases. This can be done through statistical tests that assess how model predictions vary across different groups defined by sensitive attributes (e.g., farm size, location, type of crops)) and third-party reviews (engage independent experts to review and validate the fairness of the algorithms. This external review may help identify bias that internal teams might overlook).

In embodiments, algorithmic transparency may include transparent modeling (e.g., using explainable AI techniques to make the decision-making process of the GAIE algorithms transparent. This may help stakeholders understand how decisions are made and identify potential points of bias) and documentation (e.g., maintain comprehensive documentation of the data sources, modeling techniques, and decision processes used by the GAIE. This documentation should be accessible to users and regulators).

In embodiments, fairness metrics and benchmarks may include define fairness metrics (e.g., establish specific metrics for fairness based on the agricultural context, such as equal error rates across different groups or equitable distribution of benefits and recommendations) and benchmarking (e.g., regularly compare the performance of the GAIE against these fairness benchmarks to monitor progress and detect any deviations from desired fairness standards).

In embodiments, incorporating feedback mechanisms may include user feedback (e.g., implement mechanisms for users to provide feedback on the outcomes of the GAIE's decisions. This feedback can be used to identify unforeseen biases and areas for improvement) and feedback loop integration (e.g., integrate this feedback directly into the training loop of the GAIE to allow for dynamic adjustments and improvements in real-time).

In embodiments, model retraining and updating may include periodic retraining (e.g., regularly retrain the GAIE models with updated and expanded datasets to adapt to changing agricultural practices and market conditions) and adaptive algorithms (e.g., develop adaptive algorithms that can adjust their parameters in response to detected biases or shifts in data distributions).

In embodiments, ethical and legal compliance may include ethical guidelines (e.g., develop and adhere to ethical guidelines for AI development and deployment in agriculture, focusing on fairness, accountability, and transparency) and regulatory compliance (e.g., ensure compliance with local and international regulations regarding AI and data usage, which may include specific provisions to prevent discrimination and protect user privacy).

In embodiments, diversity in development teams may include inclusive teams (foster diversity within the teams developing and managing the GAIE. Diverse teams are more likely to recognize and address potential biases in AI systems).

In embodiments, collaboration and community engagement may include stakeholder engagement (e.g., regularly engage with a broad range of stakeholders, including farmers, agricultural experts, and community leaders, to understand their perspectives and concerns regarding AI fairness) and collaborative research (e.g., partner with academic institutions or other research organizations to study and improve the fairness of AI applications in agriculture).

In embodiments, by implementing these methods, developers and users of GAIE in agriculture may be able work towards creating more equitable and effective AI solutions that serve the diverse needs of the agricultural community.

In embodiments, developing and deploying an integrated agricultural platform and marketplace system with a GAIE may include a scalable software architecture and infrastructure. This system may be capable of handling large volumes of data, complex processing, and real-time analytics, both in cloud and on-premises environments. Underlying software architecture and infrastructure may be used to develop and deploy this complex integrated system across potential cloud and on-premises environments. In embodiments, software architecture may include, but is not limited to, microservices architecture, which may include: modularity (e.g., break down the application into smaller, independent modules (microservices) that handle specific tasks such as data ingestion, processing, AI model training, user interface, and marketplace management and scalability (e.g., each microservice can be scaled independently, allowing for efficient resource management based on demand for specific services). Data pipeline architecture, which may include: ingestion (e.g., use data ingestion services to collect data from various sources like IoT devices, sensors, and external databases), processing (e.g., implement data processing microservices that clean, transform, and store data in a format suitable for analysis), and analytics (e.g., develop microservices for running GAIE analytics, generating insights, and creating actionable recommendations). Event-driven architecture may include reactivity (e.g., utilize an event-driven architecture to enable real-time data processing and immediate response to changes in data or conditions, crucial for agricultural decisions) and message queuing (e.g., use message brokers to handle communications between services, ensuring decoupling and asynchronous processing).

In embodiments, infrastructure options may include, but are not limited to, cloud-based infrastructure, which may include Platform as a Service (PaaS) to abstract away the underlying infrastructure, focusing on application development and deployment; infrastructure as a service (IaaS) gain control over the infrastructure while leveraging scalable resources, and managed services (e.g., incorporate managed databases, AI and machine learning services, and analytics tools provided by cloud vendors to enhance development speed and reduce maintenance overhead). On-premises infrastructure, which may include data centers (set up dedicated data centers to host servers, storage systems, and networking equipment, ensuring full control over the physical infrastructure) and hybrid solutions (e.g., combine on-premises infrastructure with cloud services for flexible data processing and storage solutions, accommodating regulatory and data sovereignty requirements).

In embodiments, hybrid cloud environment may include integration (e.g., use hybrid cloud solutions to integrate on-premises systems with cloud services, allowing data and applications to move seamlessly between environments) and cloud bursting (e.g., implement cloud bursting to handle peak loads in the cloud while maintaining normal operations on-premises).

In embodiments, containerization and orchestration may include containers (e.g., deploy applications in containers for consistency across different environments and ease of scalability) and orchestration (e.g., use container orchestration tools (e.g., Kubernetes) to manage containerized applications, automate deployment, scaling, and operations).

In embodiments, security and compliance may include data security (e.g., implement robust encryption, access controls, and network security protocols both in cloud and on-premises setups) and compliance (e.g., ensure the infrastructure supports compliance with relevant regulations (e.g., GDPR, HIPAA) through auditing tools and compliance-ready services offered by cloud providers).

In embodiments, monitoring and management may include monitoring tools (e.g., utilize tools to monitor the health and performance of applications and infrastructure) and automation (e.g., employ infrastructure as code (IaC) tools for automating the provisioning and management of infrastructure).

In embodiments, this architecture and infrastructure framework supports the development and deployment of a scalable, flexible, and robust integrated agricultural platform and marketplace system, that may be capable of leveraging GAIE for enhanced agricultural decision-making.

In embodiments, generating agricultural insights using the GAIE within the system of platforms and marketplace 100 may include methods and systems for machine learning techniques. These techniques are chosen based on their ability to handle specific data types commonly found in agriculture and to perform tasks such as prediction, classification, and optimization effectively. Machine learning techniques would be best suited for the data types and prediction tasks involved in agricultural insights generation.

In embodiments, regression models used by the system of platforms and marketplace 100 may include purpose (e.g., used for predicting continuous outcomes, such as yield estimation, soil nutrient levels, and growth rates) and techniques (e.g., linear regression, polynomial regression, and ridge regression are common for simpler relationships, while more complex relationships might require methods like support vector regression or ensemble methods like random forest and gradient boosting).

In embodiments, time series forecasting may include predicting future values based on previously observed values, crucial for weather forecasting, crop price predictions, and disease outbreak predictions, and techniques, such as, ARIMA (AutoRegressive Integrated Moving Average), seasonal ARIMA, and more advanced deep learning approaches like long short-term memory (LSTM) networks.

In embodiments, classification models may be used to categorize data into predefined classes, useful for tasks like pest identification, disease detection, and crop type classification, and techniques, such as, logistic regression used for binary classification, decision trees, random forests, and support vector machines (SVM). Deep learning models like Convolutional Neural Networks (CNNs) are particularly effective for image-based classification).

In embodiments, clustering may include segmenting farms or crops into groups based on similarities in conditions or behaviors without predefined labels. This may help in targeted interventions and understanding diverse agricultural patterns, and techniques, such as, k-means clustering, hierarchical clustering, and DBSCAN (density-based spatial clustering of applications with noise)).

In embodiments, dimensionality reduction may reduce the number of random variables to consider, useful in processing high-dimensional data like genetic information or multispectral images) and techniques, such as, principal component analysis (PCA), t-distributed stochastic neighbor embedding (t-SNE), and autoencoders may be used.

In embodiments, neural networks and deep learning may be effective for complex pattern recognition and prediction tasks, such as predicting crop performance under various conditions or automated monitoring of crop health through drone imagery), and techniques, such as, multilayer perceptrons (MLP), Convolutional Neural Networks (CNNs) for spatial data analysis, recurrent neural networks (RNNs) for sequential data like time series, and transformer models for large-scale data integration may be used.

In embodiments, reinforcement learning may include optimizing decision-making processes by learning to take actions that maximize a reward, useful for resource allocation, irrigation management, and automated machinery operations, and techniques, such as, Q-learning, deep Q-networks (DQN), and proximal policy optimization (PPO) may be used.

In embodiments, ensemble methods may improve prediction performance by combining the predictions of multiple models, thereby reducing variance and bias and techniques (e.g., bagging, boosting, and stacking. Random forests and gradient boosting machines (GBMs) may also be used.

In embodiments, anomaly detection may identify unusual patterns that do not conform to expected behavior, crucial for early warning systems in disease outbreaks or equipment failures, and techniques, such as, isolation forest, one-class SVM, and autoencoders may be used.

In embodiments, when selecting machine learning techniques, the system of platforms and marketplace 100 may consider the nature of the data (e.g., structured vs. unstructured, temporal vs. spatial), the specific agricultural task, and the computational resources available. Additionally, integrating domain knowledge into the model development process may enhance the relevance and accuracy of the predictions.

In embodiments, integrating third-party data sources such as weather data or market price information into an agricultural platform may enhance the quality and applicability of the insights generated. The system of platforms and marketplace 100 may include methods and systems for integrating third-party data sources like weather data or market price information into the platform to enrich the insights.

In embodiments, API integration may include application programming interfaces (APIs) provided by third-party data providers. APIs can allow for real-time data retrieval, which can be essential for dynamic and up-to-date insights. An example of this may be integrating weather APIs like Open WeatherMap or Weatherstack to fetch real-time weather conditions or forecasts.

In embodiments, data feeds and web scraping may include subscribing to data feeds that provide regular updates. Alternatively, web scraping may be used to extract data from websites that do not offer an API. An example of this may be scraping commodity market websites or agricultural news sites for the latest market price information and trends.

In embodiments, data warehousing may include using a data warehouse to store and manage data collected from various third-party sources. This centralized approach may facilitate efficient data analysis and integration. An example of this may be implementing a cloud-based data warehouse like Amazon Redshift or Google BigQuery that aggregates weather data, market prices, and other relevant datasets.

In embodiments, ETL Processes may include implementing extract, transform, load (ETL) processes to gather data from different sources, transform it into a consistent format, and load it into a system. An example of this may be using tools like Apache NiFi, Talend, or Informatica to automate ETL processes for continuous data integration.

In embodiments, IoT and sensor integration may include integrating Internet of Things (IoT) technologies to collect real-time data directly from, for example, equipment and sensors on a farm. An example of this may be connecting soil moisture sensors or weather stations directly to the platform to provide real-time data for more accurate and localized weather and soil conditions.

In embodiments, cloud integration services may include utilizing cloud integration services that offer tools and environments specifically designed for integrating and managing external data sources. An example of this may be using services like AWS Data Pipeline, Azure Data Factory, or Google Cloud Dataflow to orchestrate and automate data integration workflows.

In embodiments, blockchain for data verification may include using blockchain technology to ensure the integrity and verifiability of third-party data, particularly useful for sensitive or critical data like organic certification or supply chain data. An example of this may be implementing a blockchain-based system to track and verify the authenticity of organic produce through the supply chain.

In embodiments, data collaboration platforms may include participating in data collaboration platforms where multiple stakeholders share and access a pool of aggregated data. An example of this may be joining platforms like Ag Data Coalition or similar cooperative data exchange platforms that facilitate data sharing among farmers, researchers, and agribusinesses.

In embodiments, custom data connectors may include developing custom data connectors if standard integration methods are not available. This might involve direct database access or custom-built middleware. An example of this may be creating a custom connector to integrate proprietary market analysis tools or databases that do not support standard API connections.

In embodiments, machine learning for data integration employing machine learning models to predict missing data or to integrate and reconcile discrepancies between different data sources. An example of this may be using predictive models to estimate missing weather data points or to harmonize data from different market sources for consistency.

In embodiments, by leveraging these integration options, the agricultural platform can enrich its data ecosystem, leading to more comprehensive insights and better-informed decision-making. Each integration strategy may be chosen based on the specific requirements, reliability, and the strategic value of the data source.

In embodiments, the system of platforms and marketplace 100 may develop partnerships with external data providers for an agricultural platform, addressing data privacy, security, and ownership is crucial to ensure the integrity of the system and maintain trust among all stakeholders. Some key factors may be considered regarding data privacy, security, and ownership when developing partnerships with external data providers.

In embodiments, data security may include encryption to ensure that data transmitted between the platform and external data providers is encrypted both in transit and at rest, use strong encryption standards to protect data from unauthorized access, access controls (e.g., implement strict access controls) and authentication mechanisms to restrict data access to authorized personnel only. This may include using multi-factor authentication (MFA) and maintaining detailed access logs, and regular audits (e.g., conduct regular security audits and vulnerability assessments to identify and mitigate potential security risks. Ensure that external data providers also adhere to these practices).

In embodiments, data ownership may include clear ownership rights to define data ownership rights in the partnership agreements, and specify who owns the data at each stage of the process and what rights each party has regarding the use, distribution, and sale of the data, and usage rights and restrictions (e.g., clearly outline what each party is allowed to do with the data. This may include limitations on data sharing, commercialization, and the ability to sublicense data to third parties), and data portability (e.g., ensure agreements include provisions for data portability, allowing for the transfer of data back to the user or to another service provider if needed).

In embodiments, data integrity and quality accuracy and reliability may be used to establish standards and ensure that data provided by external sources meets these standards, and data validation (e.g., implement processes to regularly validate and update data to maintain its accuracy and relevance. This includes mechanisms for correcting any identified errors or discrepancies).

In embodiments, legal and contractual considerations may include confidentiality agreements to ensure that parties involved adhere to confidentiality agreements to protect sensitive information, liability and indemnity clauses (e.g., include liability clauses that specify the responsibilities of each party in the event of data breaches or other security incidents. Indemnity clauses can protect against legal actions from data misuse), and termination and data retention (e.g., define terms for contract termination and outline procedures for data retention and deletion post-termination. This may ensure data is handled appropriately even after the partnership ends).

In embodiments, transparency and accountability may include disclosure policies (e.g., develop clear policies regarding the disclosure of data sharing practices to users. This enhances transparency and builds trust) and audit trails (e.g., maintain comprehensive audit trails for all data access and processing activities. This helps in ensuring accountability and compliance with regulatory requirements).

In embodiments, ethical considerations may include ethical data use (e.g., establish guidelines for the ethical use of data, particularly when using data for AI training or other sensitive applications. Consider the societal impacts of data usage and strive for fairness and non-discrimination).

### Example 1—Example Overview

A provider can provide access to an AI agricultural (e.g., agronomic) advisor chatbot system powered by Large Language Models (LLMs) and customized for the agriculture domain using a blend of agricultural datasets. The technology can leverage an LLM chatbot architecture and customize it for agriculture by integrating a unique corpus of agricultural data, a custom context extraction process, as well as domain-specific prompt-based learning inputs and fine-tunings. The sources for the agricultural knowledge corpus include public agronomic information (e.g., public datasets such as USDA-NASS survey data or the like), semi-public agronomic information, academic and professional literature, social media, traditional media, and proprietary data sources (e.g., proprietary agronomic information).

The chatbot system can include tools that provide custom context relevant to a user's question and enable the chatbot to access the detailed agricultural knowledge corpus efficiently. Accordingly, an LLM implemented in the chatbot system can formulate a conversational response to the question based on the custom context, rather than based on the LLM's baked-in training data. Fine-tuning and prompt-based learning approaches make the chatbot interact with a user in a way similar to an agricultural professional.

One example tool that can be included in the chatbot system is a product label tool which extracts data from digital files (e.g., Portable Document Format (PDF) files) that contain label data for agricultural products such as chemical products to be applied to crops. The label data for a given agricultural product can include usage instructions for the product, among other data. The product label tool can perform custom processing on the extracted data to generate semantically coherent text segments and question-answer pairs from the extracted text. The semantically coherent text segments and question-answer pairs are transformed into vector embeddings and stored in a custom vector database of the chatbot system to facilitate retrieval of relevant information when a user inputs a query related to the product's label data.

Other example tools that can be included in the chatbot system include a product finder and usage tool and a complementary product recommendation tool. The product finder and usage tool can allow users to quickly check whether a product (e.g., chemical product) on-hand might also be labeled for use with a new pest, weed, or disease issue they are attempting to mitigate. The complementary product recommendation tool can provide product recommendations to users for specific chemical products in response to queries.

In addition to the use cases associated with the example tools described herein, the chatbot is designed to serve a variety of other purposes, such as answering basic agronomy questions; assisting a user in the design of a specific and executable program of crop protection, seed, fertility, and livestock nutrition inputs tailored to their farm; aiding in the scheduling of product delivery; writing agronomic content for a blog; and writing appraisal narratives for a land loans business. Taken together, the robust blend of public and proprietary agronomic data sources, the unique approach to industry-specific training of the model, and the novel use cases associated with the AI agricultural advisor chatbot system described herein constitute a wholly new approach to providing agricultural advice to farmers.

### Example 2—Example System Implementing an Artificial Intelligence Agricultural Advisor Chatbot

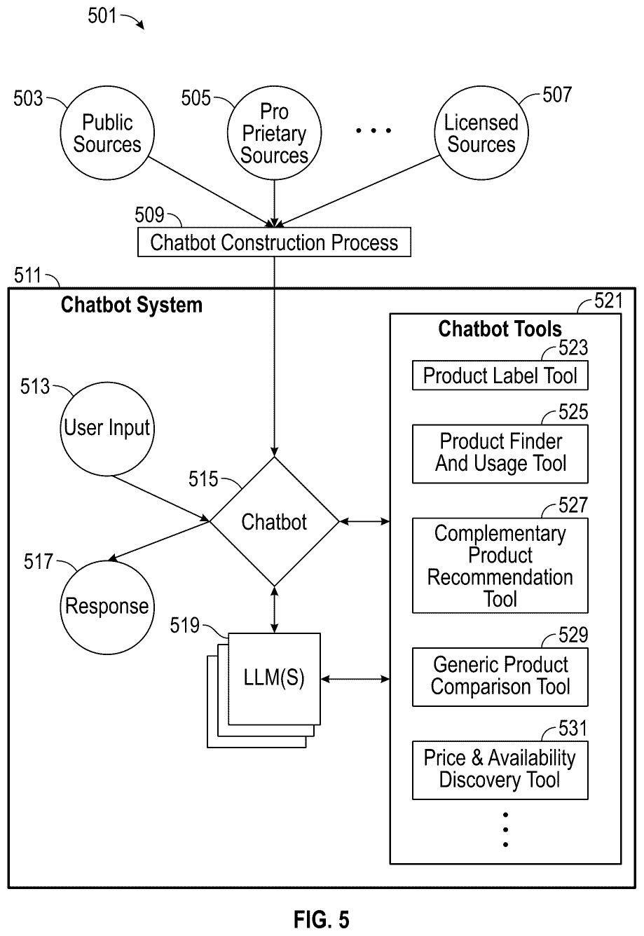

FIG. 5 is a block diagram of an example system 501 implementing an AI agricultural advisor chatbot. In the example, a plurality of data sources 503 . . . . N serve as inputs to a chatbot construction process 509. The process 509 creates an AI agricultural advisor chatbot system 511 including a chatbot 515 and a plurality of chatbot tools 521. Chatbot 515 is operable to receive user input 513 and output a response 517. To formulate the response 517, chatbot 515 can employ one or more of the chatbot tools 521 and one or more LLMs 519. In practice, a conversation between a user and the chatbot 515 can be supported on a variety of agronomic topics.

The data sources 503 . . . . N can be sources of agronomic information including, for example, public sources 503 (e.g., USDA-NASS survey data, EPA data, or the like), proprietary sources 505 (e.g., seed performance data, provider data, or the like), and licensed sources 507 (e.g., third party sources of data such as product label data).

The chatbot construction process 509 can include data pre-processing and normalization, assembling an agricultural knowledge corpus, and the like. For example, as described herein, data from the data sources 503 . . . . N can be extracted from digital files and processed to generate semantically coherent text segments and question-answer pairs which are embedded as vectors and stored in a database (e.g., a vector database). The database can be part of a knowledge corpus of the chatbot system 511.

Chatbot system 511 further includes a plurality of chatbot tools 521. Each “tool” can include computer-executable instructions that, when executed by a computing system, cause the computing system to perform operations to achieve the functionality of the tool described herein. In the depicted example, chatbot tools include a product label tool 523, a product finder and usage tool 525, a complementary product recommendation tool 527, a generic product comparison tool, and a price and availability discovery tool 531. Chatbot tools 521 can also include other tools in addition to those depicted in FIG. 1.

The product label tool 523 can be configured to perform custom processing on product label data received from data sources 503 . . . . N (e.g., licensed product label data received from a data aggregator). For example, the product label tool 523 can apply a natural language processing algorithm to group text extracted from digital files containing product label data (e.g., PDF files) into semantically coherent text segments which contain relevant context for a specific subsection of the product label, and applying LLMs to generate question-answer pairs from the extracted text. As used herein, a “semantically coherent text segment” refers to a text segment which contains the necessary context and information to be interpreted independently from the rest of the text in the digital file from which it was extracted. The semantically coherent text segments and question-answer pairs are transformed into vector embeddings and stored in a custom vector database of the chatbot system. Storing the label data in this manner facilitates retrieval of relevant information by the chatbot in response to user queries regarding associated product. For example, when a user submits a query to the chatbot that references a particular product, the chatbot system can initiate a retrieval process which searches the vector database for relevant entries (e.g., entries with similar semantic information and which originated from the label data for that product). As described herein, an additional LLM can be applied during the retrieval process to improve the accuracy of the results.

The product finder and usage tool 525 can be configured to assist the chatbot in handling unstructured queries related to identifying appropriate agricultural products and/or agricultural product usage details for a specified application. For example, when a user enters an unstructured query to the chatbot, the chatbot can employ the product finder and usage tool 525 to determine whether the query relates to checking chemical registrations for specific pests and/or crops. If so, the product finder and usage tool 525 can further analyze the query to determine whether the user wishes to check the registration of a specific chemical in the database or whether it should instead provide a selection of products in the database which match the user's filters (e.g., the crop and pest/disease/weed referenced in the query). In addition, the product finder and usage tool 525 can assist the chatbot with determining the labeled rates of product usage for the referenced crop(s) so that the chatbot can provide this information if prompted by the user.

The complementary product recommendation tool 527 can provide product recommendations to users for specific chemical products in response to queries. For example, when a user submits a natural language query requesting a recommendation for a complementary product, the chatbot system can employ the complementary product recommendation tool to determine an appropriate response by querying an internal database which maps chemical products to complementary products (e.g., adjuvant pairings).

The generic product comparison tool 529 can provide similar and alternative products to a particular agricultural chemical product. Farmers have a wide array of branded crop protection products to choose from, and each year the major crop protection manufacturers release new products into the market. These products are often merely novel combinations of generically available products, but are branded with names that provide the appearance of a new product. In addition, the names chosen for these products typically have nothing to do with the actual formulations. Rather, the product names provide the cache of a branded product and often allow the manufacturer to charge significantly higher product margin than equivalent blends of generic products. However, for a farmer, it is not always clear whether the constituent products in a branded blend are available in the generic market. The generic product comparison tool 529 can be employed in the chatbot system to address these issues. For example, using the generic product comparison tool 529, the chatbot system can answer questions about the composition of a blended product and recommend generic alternatives. This can help farmers have more control over their purchases and save significant amounts of money.

For example, when a user submits a natural language query regarding this topic (e.g. “What are generic or branded alternatives to [insert branded product name]?”), the chatbot system 511 can employ the generic product comparison tool 529 to detect the user's intent with the question and query an internal database which maps chemical products to one or more similar products (e.g., based on usage, active ingredient, and active ingredient concentrations). In order to effectively query the database, the chatbot system 511 leverages its context extraction module which can accurately detect the official product name based on the user's natural language query. The chatbot system can then produce a response which includes the relevant products.

The price and availability discovery tool 531 can be employed by the chatbot system 511 to respond to user queries regarding price, availability, and other details of agricultural products. For example, users can submit natural language queries to check on price, availability, active ingredient composition, typical spray rates, and other details of agricultural products (e.g., agricultural chemical products). In response to such a query, the chatbot system 511 detects the user's intent using the context extraction module, identifying both (1) the type of information about the product the user is seeking and (2) the particular product the user is asking about. The price and availability discovery tool 531 can then search an internal database of the chatbot system 511 for desired information regarding the product in question and return an answer with those details. Towards this end, the price and availability discovery tool 531 can be configured to access per-unit prices, total prices, as well as prices for different variations within a product (e.g., different bulk quantities which may impact the per-unit price).

Chatbot system 511 further includes one or more LLMs 519. While the LLMs 519 are depicted as being part of (e.g., internal to) the chatbot system 511, one or more of the LLMs can alternatively be hosted by an entity external to the chatbot system 511. As described herein, the LLMs 519 can include a first LLM configured to receive a prompt formulated by the chatbot system 511 and generate an answer based on the prompt, a second LLM configured to perform a database retrieval process, a third LLM configured to identify database entries relevant to a query, and a fourth LLM configured to generate question-answer pairs from text. In some examples, the first, second, third, and fourth LLMs are different LLMs (e.g., different types of LLMs). In other examples, the same LLM serves as two or more of the first, second, third, and fourth LLMs. While four LLMs are described herein, a smaller or larger number of LLMs 519 can be employed by the chatbot system 511.

Any of the systems herein, including the system 501, can comprise at least one hardware processor and at least one memory coupled to the at least one hardware processor.

The system 501 can also comprise one or more non-transitory computer-readable media having stored therein computer-executable instructions that, when executed by the computing system, cause the computing system to perform any of the methods described herein.

In practice, the systems shown herein, such as system 501, can vary in complexity, with additional functionality, more complex components, and the like. For example, the chatbot 515 can interact with numerous users in a cloud-based scenario. There can be additional functionality within the construction process. Additional components can be included to implement security, redundancy, load balancing, report design, and the like.

The described computing systems can be networked via wired or wireless network connections, including the Internet. Alternatively, systems can be connected through an intranet connection (e.g., in a corporate environment, government environment, or the like).

The system 501 and any of the other systems described herein can be implemented in conjunction with any of the hardware components described herein, such as the computing systems described below (e.g., processing units, memory, and the like). In any of the examples herein, the data sources 503-N, chatbot 515, chatbot tools 521, user input 513, chatbot response 517, LLM(s) 519, and the like can be stored in one or more computer-readable storage media or computer-readable storage devices. The technologies described herein can be generic to the specifics of operating systems or hardware and can be applied in any variety of environments to take advantage of the described features.

### Example 3—Example Method Implementing an Artificial Intelligence Agricultural Advisor Chatbot

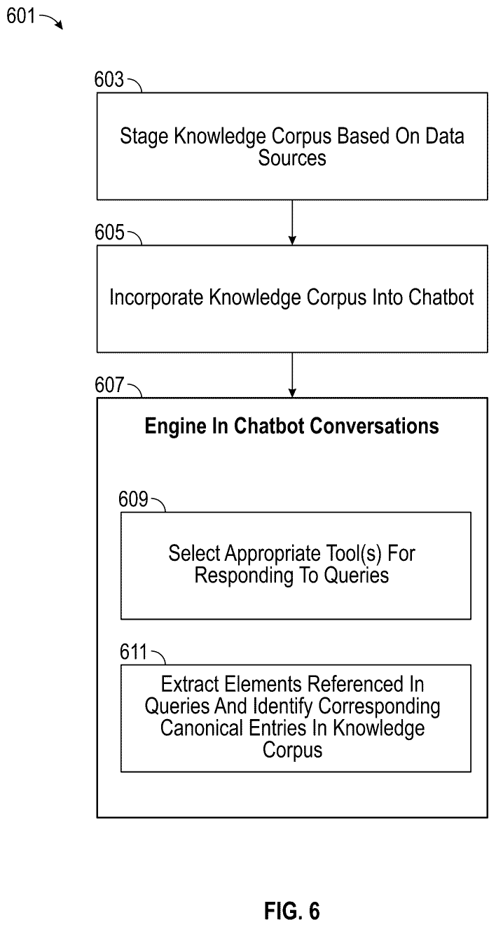

FIG. 6 is a flowchart of an example method 601 of implementing an artificial intelligence agricultural advisor chatbot and can be performed, for example, by the system of FIG. 5. The automated nature of the method 601 can be used in a variety of situations such as assisting users in answering questions, providing general agricultural advice, performing tasks related to running an agricultural business, or the like.

In the example, at 603, a knowledge corpus is staged based on a plurality of data sources, such as data sources 503 . . . . N of FIG. 5.

At 605, the knowledge corpus is incorporated into the chatbot.

At 607, the chatbot engages in conversations. As shown, this can include selecting one or more appropriate tools for responding to queries at 209. Engaging in chatbot conversations can also include, at 611, extracting elements referenced in the queries and identifying corresponding canonical entries in the knowledge corpus.

The method 601 and any of the other methods described herein can be performed by computer-executable instructions (e.g., causing a computing system to perform the method) stored in one or more computer-readable media (e.g., storage or other tangible media) or stored in one or more computer-readable storage devices. Such methods can be performed in software, firmware, hardware, or combinations thereof. Such methods can be performed at least in part by a computing system (e.g., one or more computing devices).

The illustrated actions can be described from alternative perspectives while still implementing the technologies. For example, receiving data can be described as sending data depending on perspective.

### Example 4—Example Method for Responding to a Text Query

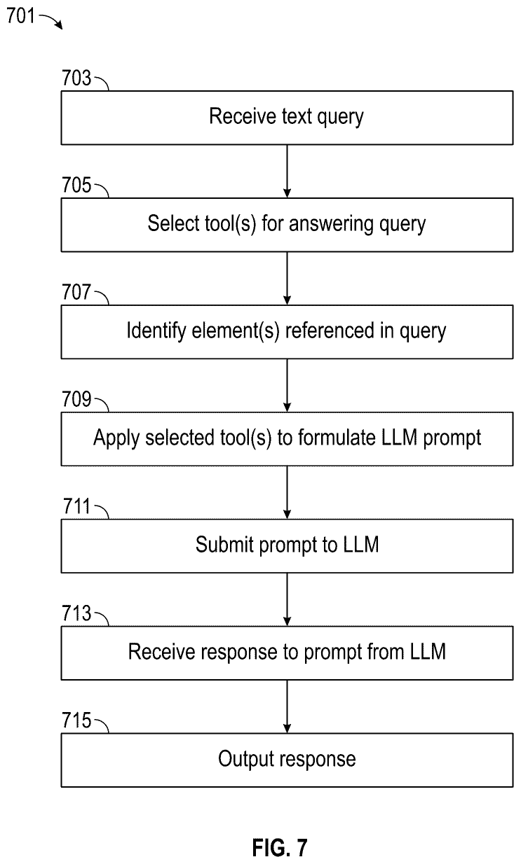

FIG. 7 is a flowchart of an example method 701 for responding to a text query submitted to a chatbot, such as an artificial intelligence agricultural advisor chatbot, and can be performed, for example, by the system of FIG. 5.

In the example, at 703, a text query is received, e.g., from a user via a user interface. The text query can be an unstructured query containing a question that references one or more elements. As used herein, the term “element” can represent a particular agricultural product (e.g., chemical product name), agricultural chemical, crop, pest, or other entity.

At 705, one or more tools are selected for answering the query. For example, the chatbot system can reference information in its knowledge corpus (e.g., previous questions and answers) to determine which types of information will be required to answer the question. Based on this determination, the chatbot system can select one or more tools from its set of tools (e.g., chatbot tools 521 of FIG. 5) which can provide the appropriate information.

At 707, one or more elements referenced in the query are identified. For example, the chatbot system can input the query to an LLM (e.g., one of LLMs 519 of FIG. 5), and the LLM can identify any elements referenced in the query. The LLM used in this context can be a general foundation model, for example. The chatbot system can then perform structured and natural language processing on any identified elements to convert the user's input for the element into a “canonical” entry. For example, when the element is a chemical product, the canonical entry for the element can be the official registered name of the chemical product. Accordingly, the chatbot system can harness LLMs to intelligently interpret a user's informal input as referencing a particular element, and then perform additional processing to convert the user input into a canonical entry for the element.

At 709, the selected tool(s) are applied to formulate a prompt for an LLM. Applying a tool can include executing code associated with the tool by one or more processors of the chatbot system to produce an output (e.g., a text output). The output of the tool can then be used by the chatbot system to formulate a prompt for an LLM (e.g., another one of LLMs 519). In some examples, the prompt comprises structured examples of questions and answers to guide the LLM in formulating an appropriate response (e.g., a response which best matches a desired output in format, tone, and content).

At 711, the prompt is submitted to the LLM. The LLM receiving the prompt can be an AI or machine learning model that is designed to understand and generate human language. Such models typically leverage deep learning techniques such as transformer-based architectures to process language with a very large number (e.g., billions) of parameters. Examples include the Generative Pre-trained Transformer (GPT) developed by OpenAI (e.g., ChatGPT), Bidirectional Encoder Representations from Transforms (BERT) by Google, A Robustly Optimized BERT Pretraining Approach developed by Facebook AI, Megatron-LM of NVIDIA, or the like. Pretrained models are available from a variety of sources.

At 713, a response to the prompt is received from the LLM.

At 715, the response is output by the chatbot system. For example, the chatbot system can output the response to the user who initially submitted the text query via a user interface.

### Example 5—Example Method for Generating Vector Embeddings

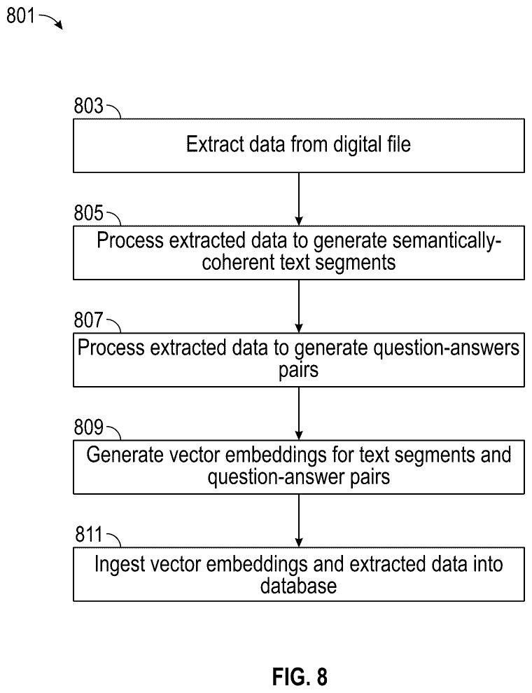

FIG. 8 is a flowchart of an example method 801 of generating vector embeddings for use by an AI agricultural advisor chatbot and can be performed, for example, by the system of FIG. 5. A chatbot tool, such as product label tool 523 of FIG. 5, can perform method 801 to facilitate retrieval of data by the chatbot when responding to user queries. For example, method 801 can be performed during staging of the chatbot's knowledge corpus.

In the example, at 803, data is extracted from a digital file. As described herein, the digital file can be a PDF file, or a digital file with another format. The digital file can originate from a data source such as one of data sources 503 . . . . N of FIG. 5. As an example, the digital file can include label data for an agricultural product (e.g., a product that contains one or more agricultural chemicals). While method 801 describes extracting data from a single digital file, in practice, the method can be performed for multiple digital files (e.g., in parallel or sequentially).

At 805, the extracted data is processed to generate semantically coherent text segments. This can include the chatbot system applying a natural language processing algorithm to group text of the extracted data into text segments (e.g., “chunks” of text), where each text segment contains relevant context for a specific subsection of the digital file. The natural language processing algorithm can be a proprietary natural language algorithm which leverages a combination of open-source software and proprietary code. The chatbot system can store an internal representation of the natural language processing algorithm in memory.

Applying the natural language processing algorithm to group the text of the extracted data into text segments can include detecting formatting data and/or metadata tags in the extracted data. The formatting data and/or metadata tags can include section titles, table headings, etc. The text of the extracted data can then be grouped, using the natural language processing algorithm, into a set of preliminary text segments based on the detected formatting and/or metadata tags.

The preliminary text segments generated by the algorithm may be broken-up and incoherent. Accordingly, after grouping the text into the set of preliminary text segments, the natural language processing algorithm can identify any text segments that would benefit from recombination among the set of preliminary text segments. The identified text segments can be removed from the set of preliminary text segments and recombined as appropriate. The recombined text segments can then be added to the set of preliminary text segments.

The natural language processing algorithm can also include determining that a selected preliminary text segment requires additional context from an adjacent portion of the text. In response to such a determination, the selected preliminary text segment can be concatenated with the additional context. After any necessary recombining and/or concatenation has been performed on the set of preliminary text segments, the text segments in the set can be referred to as semantically coherent text segments.

At 807, the extracted data is processed to generate question-answer pairs. This can include the chatbot system applying another LLM (e.g., another one of LLMs 519) to generate question-answer pairs from the text of the extracted data. The LLM used in this context can be a chat-tailored LLM, for example. The chatbot system can submit a prompt to the chat-tailored LLM which asks the LLM to summarize a single one of the semantically coherent text segments (e.g., the semantically coherent text segments produced at 805) by generating a set of questions and their answers based on that text segment. The questions and answers regarding the original text that are generated by the LLM will produce a text block which might more closely resemble (semantically) a future user's hypothetical query. Further, because the chatbot system is configured to search for text segments based on embedding vector similarity as described herein, producing a more similar text to a user's query can give the chatbot system a better chance of finding the correct information to respond to the query.

At 809, vector embeddings are generated for the text segments and question-answer pairs. For example, the chatbot system can generate a vector embedding for a semantically coherent text segment by encoding semantic information associated with the semantically coherent text segment into a fixed-length numeric vector. Similarly, the chatbot system can generate a vector embedding for a question-answer pair by encoding semantic information associated with the question-answer pair into a fixed-length numeric vector.

At 811, the vector embeddings and extracted data are ingested into a database. For example, the vector embeddings as well as the extracted data (e.g., the unmodified extracted data) can be ingested into a vector database as entries. The database can be part of the knowledge corpus of the chatbot system, for example.

### Example 6—Example Flow Diagram for Generating Vector Embeddings from a Pdf File

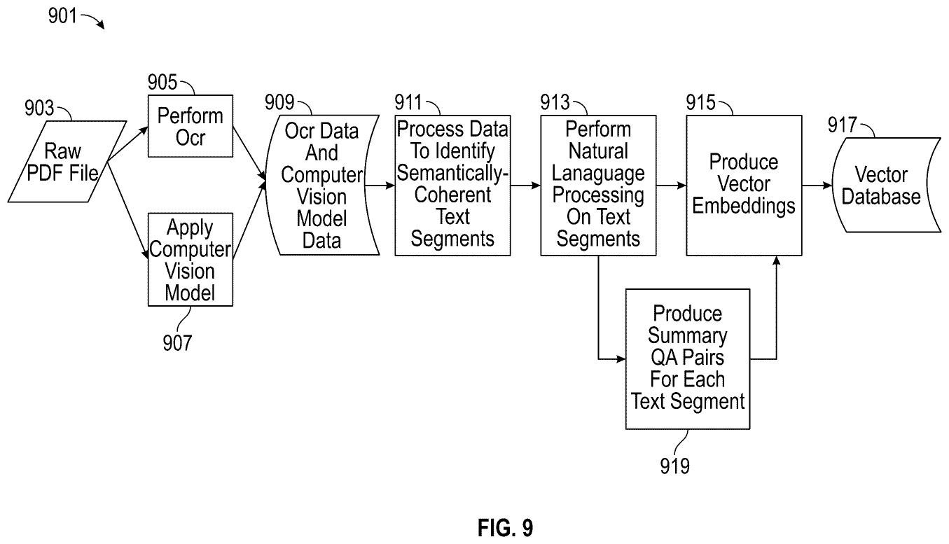

FIG. 9 is a flow diagram 901 depicting data and processes associated with generating vector embeddings from a PDF file and can be performed, for example, by the system of FIG. 5. In particular, diagram 901 corresponds an example of the method of FIG. 8 in which the digital file is a PDF.

In the example, a raw PDF file is shown at 903. Optical character recognition (OCR) is performed on the PDF file at 905. Performing OCR on the PDF file can include extracting text and other data from the PDF file. The other data can include formatting data and metadata tags (e.g., section titles, table headings, etc.).

At 907, a Computer Vision Model is applied to the PDF file. Applying a Computer Vision Model to the PDF file can include extracting tabular data (e.g., data related to tables present in the PDF file) from the PDF file.

The OCR data and Computer Vision Model data, shown at 909, is then processed at 911 to identify semantically coherent text segments, e.g., in the manner described herein with reference to FIG. 8.

At 913, natural language processing is performed on the identified semantically coherent text segments, e.g., in the manner described herein with reference to FIG. 8.

At 919, summary question-answer pairs are produced for each text segment. For example, the chatbot system can apply an LLM (e.g., one of LLMs 519 of FIG. 1) to produce question-answer pairs from the text of the extracted data, e.g., from the semantically coherent text segments. The question-answer pairs can act as a form of summarization of the text. Because the vector embedding for a question-answer pair may be very similar to a hypothetical user text query, include such vector embeddings in the database can help the chatbot system to fetch text segments which are better-matched to answer users' questions.

At 915, vector embeddings are produced. The vector embeddings produced can include a vector embedding for each semantically coherent text segment, as well as a vector embedding for each question-answer pair.

At 917, the vector embeddings are ingested into a vector database. The vector database can then be subsequently accessed by the chatbot system during formulation of an LLM prompt for a user query.

### Example 7—Example Method for Selecting a Database Entry Relevant to a Chatbot Query

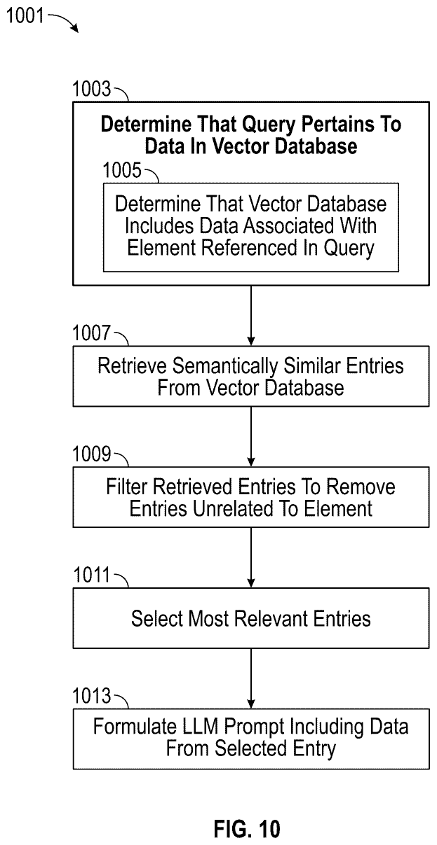

FIG. 10 is a flowchart of an example method 1001 for selecting a database entry relevant to a chatbot query, such as a query input by a user to a user interface of an AI agricultural advisor chatbot, and can be performed, for example, by the system of FIG. 5.

In the example, at 1003, it is determined that a text query input to a chatbot pertains to data in a vector database. As shown, this includes determining at 1005 that the vector database includes data associated with an element referenced in the query (e.g., data associated with an agricultural product, chemical, crop, pest, or other entity.) The determination can be made by applying an LLM to the query (e.g., one of LLMs 519 of FIG. 5). The LLM applied in this context can be a general foundation model, for example.

At 1007, one or more entries that are semantically similar to the query are retrieved from the vector database. For example, the chatbot system can initiate a retrieval process which searches the vector database for entries which have similar semantic information to the query. The vector entries searched can include both the raw text and the summarized question text (e.g., question-answer pairs). When a text segment corresponding to a summarized question-answer pair is selected, the actual content returned from the search will be the original text from the digital file from which the question was generated.

At 1009, the retrieved entries are filtered to remove entries unrelated to the element referenced in the query. For example, if the element referenced in the query is an agricultural product whose label data has been processed and ingested in the vector database, the chatbot system can filter the retrieved entries to remove entries that originated in the label data for a different agricultural product. This step is important as even a semantically similar text segment from a different product's label would not be applicable.

At 1011, the most relevant entries are selected from among the remaining entries. For example, after the chatbot system retrieves the initial results from the database, it can apply another specialized LLM (e.g., another one of LLMs 519) to find the entries most relevant to answering the user's question. This LLM can be a cross-encoder model which is fine-tuned to compare two text entries and provide a score that rates their similarity. Towards this end, the LLM can identify, among the initial results, two entries with the highest relevance to the query. The specialized LLM can then generate, for each of the two entries with the highest relevance to the query, a score rating the similarity of the entry to the query, and select, among the two entries, the entry with a higher value for the score as the entry that is most relevant to the query. This additional step is performed after the initial semantic vector search because cross-encoder models more accurately rank the similarity of text entries due to their fine-tuning for that application; the tradeoff is that cross-encoder comparison is not tenable for large amounts of text pairs, and thus the method includes narrowing in on a candidate set before applying cross-encoder reranking to select the most similar entries.

At 1013, a prompt for an LLM is formulated, the prompt including data from the selected entry. The data from the selected entry can include the text and tabular elements originally extracted from the digital file which were selected, via the procedure described above, to provide the most relevant content for answering the query. The prompt can include structured examples of questions and responses to guide the LLM to produce a response which best matches a desired output in format, tone, and content. An example structure of the prompt is set forth below.
[Instructions on guardrails, desired output tone, output formatting]
[Generalized examples that demonstrate the above instructions in practice]
[Relevant factual content to supplement the foundation LLM's knowledge base]

### Example 8—Example Architecture

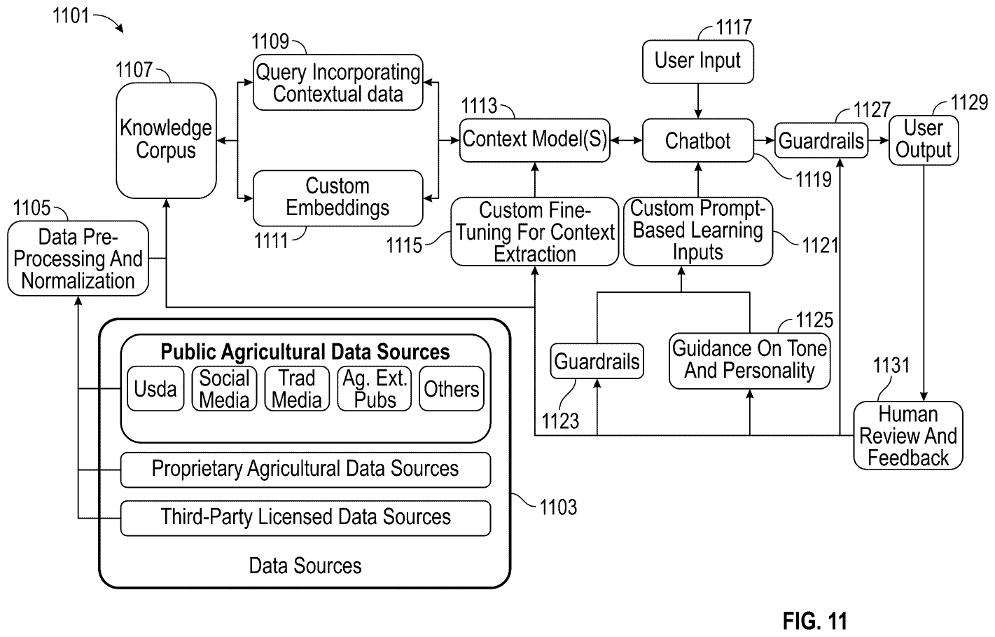

FIG. 11 is a block diagram of an example architecture of an AI agricultural advisor chatbot system 1101 that can be used in any of the examples herein. The architecture of chatbot system 1101 can be considered an example of a Retrieval-Augmented Generation (RAG) architecture, in which receipt of a query triggers the retrieval of custom data from a database which is then incorporate in a prompt to an LLM which formulates a response to the query.

The chatbot system 1101 receives user input 1117 to a chatbot 1119, which can correspond to chatbot 515 of FIG. 5. The various components of chatbot system 1101 can be accessed by the chatbot 1119 to formulate a prompt for an LLM based on the user input 1117, and optionally, to fine-tune the output of the LLM to the prompt before it is output to the user as user output 1129.

As shown, chatbot system 1101 includes a knowledge corpus 1107 which receives data from data sources 1103. Data sources 1103 can include public agricultural data sources (e.g., USDA data, social media data, traditional media data, data from agricultural extension publications, etc.), proprietary agricultural data sources (e.g., an internal product recommendation system, live pricing and availability data, etc.), and third-party licensed data sources (e.g., structured product registration data, weather data, etc.), among other data sources. In some examples, the data undergoes data pre-processing and normalization at 1105 before being ingested into the knowledge corpus 1107. As described herein, the data pre-processing can include generation of vector embeddings representing semantically coherent text segments and question-answer pairs.

Upon receipt of the user input 1117 (e.g., a user query), the chatbot system 1101 can utilize context model(s) 1113 to incorporate contextual data into the query as shown at 1109. Custom embeddings 1111 (e.g., vector embeddings) relevant to the query can be obtained from the knowledge corpus 1107. In some examples, custom fine-tuning is performed during the context extraction process, as shown at 1115, which can take into account human review and feedback 1131. Human review and feedback 1131, which can also be referred to as human-in-loop function, can aid in the training and fine-tuning process. For example, as shown, the human review and feedback 1131 can serve as an input to the generation of guidance on tone and personality, as shown at 1125.

To ensure quality results, the chatbot system 1101 can include a series of heuristic-based guardrails 1127. The guardrails 1127 can include one or more of a topical layer that restricts the chatbot to agriculture-related topics; a legal review layer that intercepts all responses that might violate local, state, or federal laws; and a trust and safety layer that ensures civil and constructive responses. As shown, the guardrails 1127, along with the guidance on tone and personality 1125, can be used to generate custom prompt-based learning inputs 1121 for use by chatbot 1119.

### Example 9—Other Example Use Cases

In any of the examples herein, an implementation can perform the following use cases, in addition to those describe above.

As one example, the chatbot system described herein can implement a cart development support in-shop experience for users accessing a website or Cloud service which sells agricultural products. Similarly, the chatbot system can act as a customer experience (CX) chatbot in such contexts.

As another example, a user (e.g., a farmer) can utilize the chatbot system described herein to obtain answers to general questions related to agronomy.

As yet another example, the chatbot system described herein can be used to implement an active response option within the context of a provider's social media platform (e.g., a community forum associated with the provider).

Further, the chatbot system can be used to facilitate automated data capture for agronomic contexts (e.g., by assisting with capture of data pertaining to agricultural attributes such as crop yield, nutrition plan, and chemical plan).

The chatbot system described herein can also be used to guide users to features within a provider's offerings. For example, a user can submit a query regarding a desired feature, and the chatbot system can return a response listing one or more products offered by the provider which provide the specified feature.

In addition, the chatbot system described herein can include “farmer verification” functionality. For example, the chatbot can present a series of questions to a user that are designed to determine if the user is indeed a farmer. Such functionality could assist with a provider's farmer verification process.

As another example, the knowledge corpus of the chatbot system can be populated with information from a seed selection tool. The chatbot system can then function as consultative seed salesperson by answering questions from users regarding seed selection (e.g., “What's the best variety for my location?”).

Further, the chatbot system's knowledge corpus can be configured to access real-time data (e.g., weather data, grain market data, news data, etc.), such that users can query the chatbot system to obtain updated information on such topics.

Other example use cases for the chatbot system can include facilitating semantic data queries regarding agricultural Direct Benefit Transfer (DBT) mechanisms, generative agricultural appraisal narratives, and generating agricultural loan narratives.

### Example 10—Example Computing Systems

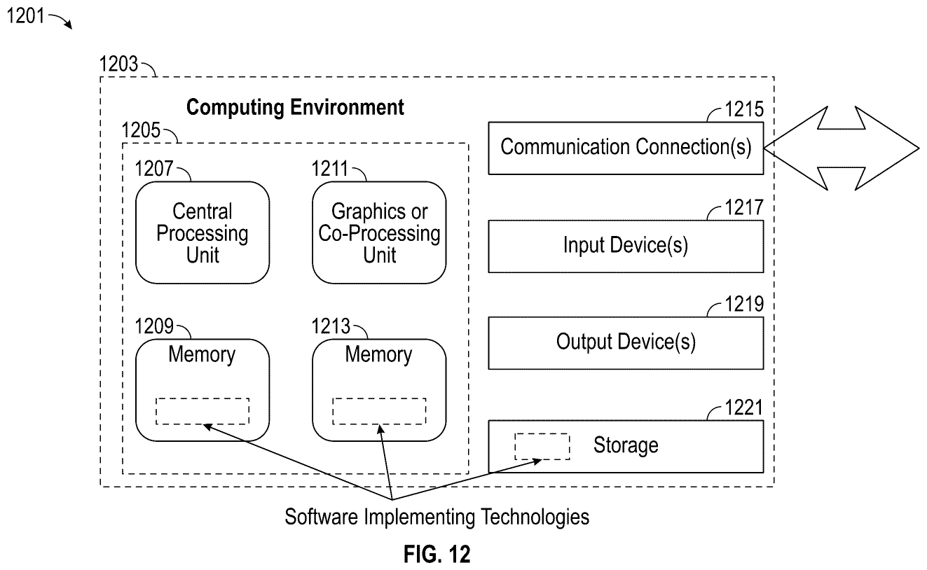

FIG. 12 depicts an example of a suitable computing system 1203 in which the described innovations can be implemented. The computing system 1203 is not intended to suggest any limitation as to scope of use or functionality of the present disclosure, as the innovations can be implemented in diverse computing systems.

With reference to FIG. 12, the computing system 1203 includes one or more processing units 1207, 1211 and memory 1209, 1213. In FIG. 12, this basic configuration 1205 is included within a dashed line. The processing units 1207, 1211 execute computer-executable instructions, such as for implementing the features described in the examples herein. A processing unit can be a general-purpose central processing unit (CPU), processor in an application-specific integrated circuit (ASIC), or any other type of processor. In a multi-processing system, multiple processing units execute computer-executable instructions to increase processing power. For example, FIG. 12 shows a central processing unit 1207 as well as a graphics processing unit or co-processing unit 1211. The tangible memory 1209, 1213 can be volatile memory (e.g., registers, cache, RAM), non-volatile memory (e.g., ROM, EEPROM, flash memory, etc.), or some combination of the two, accessible by the processing unit(s) 1207, 1211. The memory 1209, 1213 stores software 1201 implementing one or more innovations described herein, in the form of computer-executable instructions suitable for execution by the processing unit(s) 1207, 1211.

A computing system 1203 can have additional features. For example, the computing system 1203 includes storage 1221, one or more input devices 1217, one or more output devices 1219, and one or more communication connections 1215, including input devices, output devices, and communication connections for interacting with a user. An interconnection mechanism (not shown) such as a bus, controller, or network interconnects the components of the computing system 1203. Typically, operating system software (not shown) provides an operating environment for other software executing in the computing system 1203, and coordinates activities of the components of the computing system 1203.

The tangible storage 1221 can be removable or non-removable, and includes magnetic disks, magnetic tapes or cassettes, CD-ROMs, DVDs, or any other medium which can be used to store information in a non-transitory way and which can be accessed within the computing system 1203. The storage 1221 stores instructions for the software 1201 implementing one or more innovations described herein.

The input device(s) 1217 can be an input device such as a keyboard, mouse, pen, or trackball, a voice input device, a scanning device, touch device (e.g., touchpad, display, or the like) or another device that provides input to the computing system 1203. The output device(s) 1219 can be a display, printer, speaker, CD-writer, or another device that provides output from the computing system 1203.

The communication connection(s) 1215 enable communication over a communication medium to another computing entity. The communication medium conveys information such as computer-executable instructions, audio or video input or output, or other data in a modulated data signal. A modulated data signal is a signal that has one or more of its characteristics set or changed in such a manner as to encode information in the signal. By way of example, and not limitation, communication media can use an electrical, optical, RF, or other carrier.

The innovations can be described in the context of computer-executable instructions, such as those included in program modules, being executed in a computing system on a target real or virtual processor (e.g., which is ultimately executed on one or more hardware processors). Generally, program modules or components include routines, programs, libraries, objects, classes, components, data structures, etc. that perform particular tasks or implement particular abstract data types. The functionality of the program modules can be combined or split between program modules as desired in various embodiments. Computer-executable instructions for program modules can be executed within a local or distributed computing system.

For the sake of presentation, the detailed description uses terms like “determine” and “use” to describe computer operations in a computing system. These terms are high-level descriptions for operations performed by a computer and should not be confused with acts performed by a human being. The actual computer operations corresponding to these terms vary depending on implementation.

### Example 11—Example Cloud Computing Environment

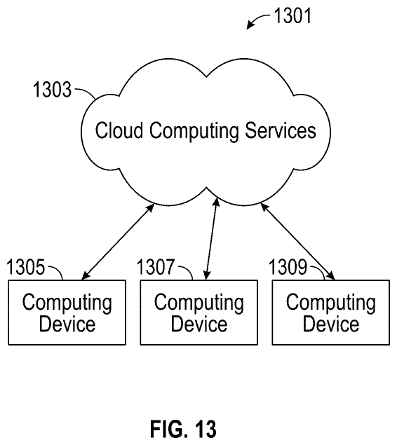

FIG. 13 depicts an example cloud computing environment 1301 in which the described technologies can be implemented, including, e.g., the system 501 of FIG. 5 and other systems herein. The cloud computing environment 1301 comprises cloud computing services 1303. The cloud computing services 1303 can comprise various types of cloud computing resources, such as computer servers, data storage repositories, networking resources, etc. The cloud computing services 1303 can be centrally located (e.g., provided by a data center of a business or organization) or distributed (e.g., provided by various computing resources located at different locations, such as different data centers and/or located in different cities or countries).

The cloud computing services 1303 are utilized by various types of computing devices (e.g., client computing devices), such as computing devices 1305, 1307, and 1309. For example, the computing devices (e.g., 1305, 1307, and 1309) can be computers (e.g., desktop or laptop computers), mobile devices (e.g., tablet computers or smart phones), or other types of computing devices. For example, the computing devices (e.g., 1305, 1307, and 1309) can utilize the cloud computing services 1303 to perform computing operations (e.g., data processing, data storage, and the like).

In practice, cloud-based, on-premises-based, or hybrid scenarios can be supported.

### Example 12—Example Implementations

Although the operations of some of the disclosed methods are described in a particular, sequential order for convenient presentation, such manner of description encompasses rearrangement, unless a particular ordering is required by specific language set forth herein. For example, operations described sequentially can in some cases be rearranged or performed concurrently.

### Example 13—Example Alternatives

The technologies from any example can be combined with the technologies described in any one or more of the other examples. In view of the many possible embodiments to which the principles of the disclosed technology can be applied, it should be recognized that the illustrated embodiments are examples of the disclosed technology and should not be taken as a limitation on the scope of the disclosed technology.

In example embodiments, a GAIE may be combined with a machine learning system in a transaction environment. Input to the GAIE may include images, video, audio, text, programmatic code, data, and the like. Outputs from a GAIE may include structured and organized prose, images, video, audio content, software/programming source code, formatted data (e.g., arrays), algorithms, definitions, context-specific structures (e.g., smart contacts, transaction platform configuration data sets, and the like), machine language-based data (e.g., API-formatted content), and the like. For GAIE instances in which the models are designed to process text data, the GAIE may interface to other programmatic systems (such as traditional machine learning engines) to process other forms of data into text data. In example embodiments, the other programmatic systems, including systems executing machine learning algorithms, may produce textual based (optionally at volume) that may be consumed by GAIE. For example, consider such another system building a series of one thousand text-based observations on the other-formatted data; this may be a useful input for a GAIE model to learn and process (e.g., summarize) into text-formatted output information. In example embodiments, an interface between the GAIE and its combined machine learning system may be extended to include a dialogue between the systems, where the GAIE includes and/or accesses a capability to ask the machine learning system specific questions to facilitate the refining of its knowledge. For example, the dialogue capability may include a request of the machine learning system to provide an assessment of current market trading positions. In another example, the dialogue capability may encode numeric outputs from the machine learning engine into text (e.g., words, such as high, medium, low) that may be input for interpretation by the GAIE.

In example embodiments, the data processed by a GAIE may include one or more types of content. For example, a GAIE may receive, as input, data that represents one or more natural-language expressions, single- or multidimensional shapes or models, real-world and/or virtual scene representations, LIDAR point-cloud representations, sensor inputs and/or outputs, vehicle and/or machine telemetry, geographic maps, authentication credentials, financial transactions, smart contracts, processing directives and/or resources such as shaders, device configurations such as HDL specifications for programming FPGAs, databases and/or database structural definitions, or the like, including metadata associated with any such data types. Input to the GAIE may also include data that represents one or more features of another machine learning model, such as a configuration (e.g., model type, parameters, and/or hyperparameters), input, internal state (e.g., weights and biases of at least a portion of the model), and/or output of the other machine learning model. These and other forms of content may be received as various forms of data. For example, a natural-language expression received as input by a GAIE could be encoded as one or more of: encoded text, an image of a writing, a sound recording of human speech, a video of an individual exhibiting sign language, an encoding according to a machine learning model embedding, or the like, or any combination thereof. In example embodiments, an input received and processed by the GAIE can include an internal state of the GAIE, such as a partial result of a partial processing of an input, or a set of weights and/or biases of the GAIE as a result of prior processing (e.g., an internal state of a recurrent neural network (RNN)).

In some embodiments, the data and/or content received and processed by a GAIE originates from one or more individuals, such as a person speaking a natural-language expression. In some embodiments, the data and/or content received and processed by a GAIE originates from one or more natural sources, such as patterns formed by nature. In some embodiments, the data and/or content received and processed by a GAIE originates from one or more other devices, such as another machine learning model executing on another device, or from another component of the same device executing the GAIE, such as output of another machine learning model executing on the same device executing the GAIE, or a sensor in an Internet-of-Things (IoT) and/or cloud architecture. In some embodiments, the data and/or content received and processed by a GAIE is artificially synthesized, such as synthetic data generated by an algorithm to augment a training data set. In some embodiments, the data and/or content received and processed by a GAIE is generated by the same GAIE, such as an internal state of the GAIE in response to previous and/or concurrent processing, or a previous output of the GAIE in the manner of a recurrent neural network (RNN).

In some embodiments, at least some or part of the data and/or content received and processed by a GAIE is also used to train the GAIE. For example, a variational GAIE could be trained on an input and a corresponding acceptable output, and could later receive the same input in order to output one or more variations of the acceptable output. In some embodiments, at least some or part of the data and/or content received and processed by a GAIE is different than data and/or content that was used to train the GAIE. In some such embodiments, the data and/or content received and processed by the GAIE is different than but similar to the data and/or content that was used to train the GAIE, such as new inputs that are exhibit a similar statistical distribution of features as the training data. In some such embodiments, the data and/or content received and processed by the GAIE is different than and dissimilar to the data and/or content that was used to train the GAIE, such as new inputs that exhibit a significantly different statistical distribution of features than the training data. In scenarios that involve dissimilar inputs, one or more first outputs of the GAIE in response to a new input may be compared to one or more second outputs of the GAIE in response to inputs of the training data set to determine whether the first outputs and the second outputs are consistent. The GAIE may request and/or receive additional training based on the new inputs and corresponding acceptable outputs. In scenarios that involve dissimilar inputs, the GAIE may present an alert and/or description that indicates how the new inputs and/or corresponding outputs differ from previously received inputs and/or corresponding outputs.

In example embodiments, the output of a GAIE may include one or more types of content. For example, a GAIE may generate, as output, data that represents one or more natural-language expressions, single- or multidimensional shapes or models, real-world and/or virtual scene representations, LIDAR point-cloud representations, sensor inputs and/or outputs, vehicle and/or machine telemetry, geographic maps, authentication credentials, financial transactions, smart contracts, processing directives and/or resources such as shaders, device configurations such as HDL specifications for programming FPGAs, databases and/or database structural definitions, or the like, including metadata associated with any such data types. Output of the GAIE may also include data that represents one or more features of another machine learning model, such as a configuration (e.g., model type, parameters, and/or hyperparameters), input, internal state (e.g., weights and biases of at least a portion of the model), and/or output of the other machine learning model. These and other forms of content may be generated by the GAIE as various forms of data. For example, a natural-language expression generated as output by the GAIE could be encoded as one or more of: encoded text, an image of a writing, a sound recording of human speech, a video of an individual exhibiting sign language, an encoding according to a machine learning model embedding, or the like, or any combination thereof. In example embodiments, an output of the GAIE can include an internal state of the GAIE, such as a partial result of a partial processing of an input, or a set of weights and/or biases of the GAIE as a result of prior processing (e.g., an internal state of a recurrent neural network (RNN)).

In example embodiments, a language-based dialogue-enabled GAIE may be configured to produce (e.g., write) new machine learning models that may process various types of data to provide new and extended text input for processing by the GAIE. In example embodiments, humans may observe and interact with this ongoing dialogue between the two systems. In example embodiments, the dialogue is initiated by an expression of a conversation partner (e.g., a human or another device), and the GAIE generates one or more expressions that are responsive to the expression of the conversation partner. In example embodiments, the GAIE generates an expression to initiate the dialogue, and further responds to one or more expressions of the conversation partner in response to the initiating expression. In example embodiments, the ongoing dialogue occurs in a turn-taking manner, wherein each of the conversational partner and the GAIE generating an expression based on a previous expression of the other of the conversation partner and the GAIE. In example embodiments, the ongoing dialogue occurs extemporaneously, with each of the conversation partner and the GAIE generating expressions irrespective of a timing and/or sequential ordering of previous and/or concurrent expressions of the conversation partner and/or the GAIE.

In example embodiments, the dialogue occurs between a GAIE and a plurality of conversation partners, such as two or more humans, two or more other GAIEs, or a combination of one or more humans and one or more other GAIEs. In some such example embodiments, the GAIE and each of the other conversation partners take turns generating expressions in response to prior expressions from the GAIE and the other conversation partners. In some such embodiments, one or more sub-conversations occur among one or more subsets of the GAIE and the plurality of conversation partners. Such sub-conversations may occur concurrently (e.g., the GAIE concurrently engages in a first conversation with a first conversation partner and a second conversation with a second conversation partner) and/or consecutively (e.g., the GAIE concurrently engages in a first conversation with a first conversation partner, followed by a second conversation with a second conversation partner). Such sub-conversations may involve the same or similar topics or expressions (e.g., the GAIE may present the same or similar conversation-initiating expression to each of a plurality of conversation partners, and may concurrently engage each of the plurality of conversation partners in a separate conversation on the same or similar topic). Such sub-conversations may involve different topics or expressions (e.g., the GAIE may present different conversation-initiating expressions to each of a plurality of conversation partners, and may concurrently engage each of the plurality of conversation partners in a separate conversation on different topics). In example embodiments, a first conversation among a first subset of the GAIE and conversation partners may be related to a second conversation among a second subset of the GAIE and conversation partners (e.g., the second subset may engage in a second conversation based on content of the first conversation among a first subgroup).

In example embodiments, one or more of the GAIE and the conversation partner may embody one or more roles. For example, the GAIE may generate expressions based on a role of a conversation starter, a conversation responder, a teacher, a student, a supervisor, a peer, a subordinate, a team member, an independent observer, a researcher, a particular character in a story, an advisor, a caregiver, a therapist, an ally or enabler of a conversation partner, or a competitor or opponent of a conversation partner (e.g., a “devil's advocate” that presents opposing and/or alternative viewpoints to a belief or argument of a conversation partner). In example embodiments, at least one of the one or more conversation partner embodies one or more aforementioned roles or other rules. In example embodiments, a role of a GAIE is relative to a role of a conversation partner (e.g., the GAIE may embody a superior, peer, or subordinate role with respect to a role of a conversation partner). In example embodiments, a role of a GAIE in a first conversation among a first subset of the GAIE and a plurality of conversation partners may be the same as or similar to a role of a GAIE in a second conversation among a first subset of the GAIE and the plurality of conversation partners. In example embodiments, a role of a GAIE in a first conversation among a first subset of the GAIE and a plurality of conversation partners may differ from a role of a GAIE in a second conversation among a first subset of the GAIE and the plurality of conversation partners (e.g., the GAIE may embody a role of a teacher in a first conversation and a role of a student in a second conversation). In example embodiments, a role of a GAIE in a conversation may change over time (e.g., the GAIE may first embody a role of a student in a conversation, and may later change to a role of a teacher in the same conversation). In example embodiments, a GAIE may embody two or more roles in a conversation (e.g., the GAIE may exhibit two personalities in a conversation that respectively represent one of two characters in a story). In example embodiments, a GAIE generates expressions between two or more roles in a conversation (e.g., the GAIE may generate a dialogue between each of two characters in a story). In example embodiments, a GAIE may engage in each of multiple conversations in a same or similar modality (e.g., engaging in multiple text-based conversations concurrently). In example embodiments, a GAIE may engage in each of multiple conversations in different modalities (e.g., engaging in a first conversation via text and a second conversation via voice).

In example embodiments, a GAIE participating in a conversation is associated with an avatar (e.g., a name, color, image, two- or three-dimensional model, voice, or the like). Expressions generated by the GAIE may be presented as if originating from the GAIE (e.g., in the voice associated with the GAIE, or in a speech bubble that is displayed near a visual position of a GAIE in a virtual or augmented-reality environment). In example embodiments, an avatar of a GAIE may be based on a role of the GAIE (e.g., a GAIE embodying a role of a teacher may be associated with an avatar depicting a teacher). In example embodiments, an avatar of a GAIE may be included in a real-world actor, such as a robot in a real-world environment such as a stage performance.

In example embodiments, a GAIE may include generative pretrained transformer elements that may be configured as a language model designed to understand various types of input and produce chat commands for a chat-type interface system. These commands may include software development tasks, API calls, and the like. In example embodiments, such a language model may include input functions that support receiving images, including video, to build textual output, functions, and additional questions that may be injected into the dialogue between the two systems in the dialogue embodiment described above. In example embodiments, this multimodal support may allow for contextual analysis of images and other media formats. In an example, users/customers may upload images or other media into a GAIE enabled platform. Based on aspects of a corresponding input prompt, a multi-modal GAIE may be configured for use in a valuation workflow to identify both macro and micro attributes and their correlated effects on valuation from a plurality of perspectives. In this example, photographs/images of an old car may be input along with a valuation-related prompt. In response, the GAIE may identify one or more typical values based on detected attributes of the car, such as the make/model, etc. The GAIE may further take into account finer details in the image to suggest potential value-altering metrics. In one example, a finer detail in the image such as damaged body panels may reduce the car value below a typical value. In another example, a finer detail in the image that shows a marking consistent with a limited production run may increase the valuation.

In example embodiments, such a GAIE may facilitate workflow orchestration for a process that uses a conversational, generative AI agent and another AI-supported process in an orchestrated sequence. In example embodiments, a GAIE may generate, perform, maintain, and/or supervise one or more workflows in a robotic process automation (RPA) environment. For example, a GAIE may be trained to monitor expressions and/or actions of an individual during interaction with other individuals, and may generate similar expressions and/or perform similar actions during similar interactions between the GAIE and other individuals. In some such scenarios, the GAIE passively observes the individual during the interactions with other individuals and self-trains to behave similarly to the individual in similar interactions with other individuals. In some such scenarios, the individual actively trains and/or teaches the GAIE to generate expressions and/or actions (e.g., by creating and/or performing example or pedagogical interactions the GAIE), and based on the training and/or teaching, the GAIE behaves similarly during subsequent interactions between the GAIE and other individuals. In example embodiments, the GAIE is trained and/or taught by an individual to perform a behavior while interacting with individuals, and subsequently performs the behavior while interacting with the same individual who provided the training and/or teaching.

In example embodiments, a pretrained GAIE system may have a smart contract analysis engine that determines one or more features of a smart contract that is under consideration by a user. The GAIE may further have a conversation engine that explains the features of the smart contract to the user, including summarizing contents of smart contracts.

In example embodiments, a GAIE may be pre-trained to perform prompt generation based on a data story or a plurality of sources across systems. Example generated prompts may include instructing and/or requesting the pre-trained GAIE to tell a story about a journey of a product, a business relationship, an event, a service provider, a smart container fleet, a robotic fleet, and the like.

In example embodiments, a GAIE may be pre-trained to generate multi-modal and/or multi-media data stories. In an example of in-cabin push-narration of maintenance/repair sequence of events and locations based on a sensor reading, a sensor detects a drop in oil pressure while an automobile is in use. A data story narrative may be created based on datasets such as 1) the historical oil pressure readings for the specific car; 2) data about oil pressure issues with the make/model/year of the specific car (e.g., service reports, recalls, prevalence of given issues, points of failure etc.); 3) data regarding remediation of potential issues (timing and types of recommended remediation or repair; 4) data regarding the location of organizations qualified to inspect or repair the diagnosed issue that might be causing the drop in oil pressure, based on proximity to current location of the car, cost, quality of customer reviews, certifications of employees and so on. This may be presented to the driver or rider of the vehicle automatically in the form of a paragraph narration similar to “The oil pressure of the vehicle may be X % lower than the recommended level. This may be caused by X, Y or Z. Based on the reading from the Z sensor, it appears that the most likely cause of the oil pressure drop may be X. There are two known part points of failures known to potentially cause this pressure drop and there are 5 service facilities within 5 miles of the car's current location that are qualified to evaluate and repair this problem. Of these, Shop 1 has the highest customer satisfaction, Shop 2 has the lowest part cost and Shop 3 has the highest number of certified employees for your make and model. The phone number for Shop 1 is. Please indicate if you would like to initiate a call to arrange an appointment for the car to be inspected. . . . ”

In example embodiments, the GAIE may receive a plot or outcome of the story, and may generate content that is content with the plot or that produces the outcome. In example embodiments, the GAIE may generate a plot or outcome of the story, and may also generate content that is consistent with the GAIE-generated plot or outcome of the story. In example embodiments, the GAIE may receive a world or environment of a story, and may generate content that occurs within the given world or environment. In example embodiments, the GAIE may generate a world or environment of a story, and may also generate content that occurs within the GAIE-generated world or environment. In example embodiments, the GAIE may receive a character or event to be included in a story, and may generate content that includes the given character or event in the story. In example embodiments, the GAIE may generate a character or event to be included in a story, and may also generate content that includes the GAIE-generated character or event in the story. In example embodiments, the GAIE may generate a world, environment, character, event, or the like “from scratch” (e.g., based on randomized inputs). In example embodiments, the GAIE may generate a world, environment, character, event, or the like based on a given world, environment, character, event, or the like (e.g., a story that is based on a real-world public figure or event).

In example embodiments, the GAIE may receive a first story and may generate a second story that is related to the first story. For example, the GAIE may generate a second story that is an alternative retelling of the first story (e.g., a second story that includes a retelling of the first story from a perspective of a different character than a narrating character of the first story). The GAIE may generate a second story that occurs in a same or similar world or environment as the first story, or a different world or environment that is related to a world or environment of the first story. The GAIE may generate a second story that features a character or event of the first story, or a different character or event that is related to a character or event of the first story.

In example embodiments, the GAIE may generate a story from the perspective of a narrator or independent observer of the story (e.g., a third-person story). In example embodiments, the GAIE may generate a story from the perspective of a character or point of view within the story (e.g., a first-person story), including a character generated and/or embodied by the GAIE. In example embodiments, the GAIE may generate a story from the perspective of a listener or audience member to whom the story is presented (e.g., a second-person story). In example embodiments, the GAIE may generate a story from multiple perspectives, such as a first part of a story generated from a perspective of a first character, a second part of the story generated from a perspective of a second character, and a third part of a story generated from a perspective of a narrator. In example embodiments, the GAIE may generate a story involving a sequence of two or more events (e.g., a story that involves two or more events observed by a character). In example embodiments, the GAIE may generate a story involving an event that is portrayed from multiple perspectives (e.g., a story that describes an event from a perspective of a first character, and that also describes the same event from a perspective of a second character).

In example embodiments, a GAIE may generate a static story that remains the same upon retelling. In example embodiments, the GAIE may generate a dynamic story that changes upon retelling (e.g., adding more detail to a story upon each retelling). In example embodiments, a GAIE may change a story based on an input of a user (e.g., based on a choice of outcomes selected by one or more receivers of the story). In example embodiments, a GAIE may generate a story based on one or more inputs received from one or more receivers of the story (e.g., based on a prompt of a user, such as a request to create a story that includes a certain event specified by the user). In example embodiments, a GAIE may receive feedback from a receiver about a story (e.g., an expression of pleasure, displeasure, approval, disapproval, delight, dissatisfaction, confusion, or the like regarding a character, event, or property of the story), and the GAIE may update the story based on the feedback (e.g., adding, removing, or clarifying an event in the story, or switching a perspective of an event from a first character in the story to a second character in the story).

In example embodiments, a GAIE may be trained by loading data (such as structured and un-structured data that may be dominated by numerical or non-text values) to the GAIE. Examples of such training data may include one or more database schemas. Techniques for curation and integration of purpose-specific data, including curation of models as inputs to a GAIE may include curating domain-specific data, data and model discovery.

Candidate areas of innovation enabled by and/or associated with GAIE advances may include user behavior models (optionally with feedback and personalization), group clustering and similarity, personality typing, governance of inputs and process, explaining the basis of GAIE knowledge and proof points, genetic programming with feedback functions, intelligent agents, voice assistants and other user experiences, transactional agents (counterparty discovery and negotiation), agents that deal with other agents, opportunity miners, automated discovery of opportunities for agent generation and application, user interfaces that adapt to the user and context, hybrid content generation, collaboration units of humans and generative AI, purpose-specific data integration, a selected set of data sources, curation of data as models as input to generative AI, and the like.

In embodiments of a GAIE-enabled system, such as one for robotic process automation, the GAIE system may summarize a set of actions being subjected to robotic automation and describe context for the actions, such as, “I found these properties as fitting your criteria because of the following features. Which ones are most attractive?” In this way, a process automation system enabled with GAIE may solicit feedback for faster feedback-based training.

In example embodiments, emerging capabilities of GAIE technology may greatly improve upon earlier versions in terms of, for example, integration of domain-specific knowledge (e.g., math) with a chat interface. Further emerging capabilities may include being better informed about and for processing prompts of complex topics. Yet further, knowledge organization is becoming much improved as GAIE systems evolve. In example embodiments, updated GAIEs may correctly answer a prompt asking about today's date, whereas prior versions may answer that today's date (e.g., the current date) may be the date on which the GAIE was last trained.

In example embodiments, a context pretrained (e.g., subject matter focused) GAIE may provide better personalization than a base GAIE instance. In general, while a base GAIE, if explicitly informed of details of the user may attempt to personalize its responses, a subject matter focused or other pre-trained GAIE may be configured with and/or with access to structured information about users (e.g., determined based on user identification and/or prompt-based clues, and the like) to provide inherent, latent context for a dialogue that includes user personalized responses.

In example embodiments, a GAIE is configured to support interpretability and/or explainability of its outputs. In example embodiments, a GAIE provides, along with an output, a description of a basis of the output, such as an explanation of the reason for generating this particular output in response to an input. In example embodiments, a GAIE provides, along with an output, a description of an internal state of the GAIE that resulted in the output, such as a set of variational parameters of a variational encoder that were processed in combination with an input to produce an output, and/or an internal state of the GAIE due to a previous processing of the GAIE that resulted in the output (e.g., similar to a recurrent neural network (RNN)). In example embodiments, a GAIE provides, along with an output, an indication of one or more subsets of features of an input that are particularly associated with the output (e.g., in a GAIE that outputs a caption or summary of an image, the GAIE can also identify the particular portions or elements of the image that are associated with the caption or portions of the summary).

In example embodiments, an advanced GAIE, such as one pretrained for subject matter specific operation, may be trained for improved epistemology, to help determine evidence of the content that it represents as facts in responses that it provides. One example of improved epistemology may include citing sources of knowledge pertinent to facts in a response as a step toward proof of facts of a response-essentially a way of the GAIE “showing its work,” or at least where its work originates. In example embodiments, a GAIE generates output based on information received from one or more external sources (e.g., one or more messages in a message set, or one or more websites on the Internet), and the GAIE indicates one or more portions of the information that are associated with the output (e.g., one or more websites on the Internet that provided information that is included in the output of the GAIE).

An advanced GAIE as described and envisioned herein may maintain contextual awareness across chat (user-prompt/GAIE-response) interactions. Maintaining contextual awareness may help avoid the GAIE beginning each chat session from scratch, with no context as to prior chats with the same user. Maintaining contextual awareness may also enable picking up and resuming a conversation from earlier interactions between the GAIE and a user. Yet further maintaining contextual awareness and awareness of passage of time between interaction sessions may facilitate adapting responses to prompts in a later resumed chat session based on trained knowledge of the intervening passage of time and/or changing circumstances. In an example, a GAIE may determine that a deadline described in an earlier chat has expired, a consequential intervening event has occurred (your home-town team lost the big game), and the like. Further, contextual awareness across time-separate chat sessions may be highly valuable when being employed for projects that may have real-world physical constraints on time (e.g., smart contract negotiation may involve human evaluation, discussion, and decision making that may take time based, for example on other priorities seeking involvement of the human). This may determine the difference between treating each conversation as individual/compartmentalized/isolated, and treating ongoing, time-separated conversations as resumable, optionally as if (almost) no time had passed. In example embodiments, a GAIE may be configured with a contextualization module that maintains some notion of conversation sessions and interconnections that may be referred (e.g., a conversation from yesterday) for details and continuity. This contextualization may further enable avoiding repeating responses, making it more efficient to reference a previous conversation. Yet further, a contextualization module may provide context to the GAIE of other conversations between the user and the system, between other users and the system, and the like.

In such a contextually maintained instance, a context-enabled GAIE may provide a response regarding forecasted weather that references an earlier period of time. In an example, a context-enabled GAIE may provide a weather-related response such as, “On Monday, we discussed the weather, you asked if you would need an umbrella on Wednesday, and I answered ‘probably not’ based on the forecast at that time. I need to inform you that the updated weather forecast indicates that rain may be more likely on Wednesday, so you probably may need an umbrella.”

Other capabilities of emerging GAIE systems may include adapting a GAIE to the generation and operation of digital avatars. In example embodiments, digital avatars may be programmed with their own visual representations. To accomplish greater similarity between an avatar and its owner based on visual and audio interpretation of users, a GAIE training and/or pre-training data set may require information about body language and nonverbal cues, such as gaze, posture, speech pitch and volume, and the like.

Emerging GAIE systems may include determining and adapting responses with variations and nuances based on, for example, user activities. A user's physical disposition may influence content production by a GAIE (e.g., presenting different cues) based on if the user is sitting, walking, driving, exercising, and the like. Further, a GAIE system may adapt responses to prompts based on variations and nuances of real-life interactions versus voice interfaces versus virtual reality. Other aspects that may impact GAIE responding to prompts may include variations and nuances of different cultures, demographics, and the like. Yet further, in example embodiments, methods and systems for advanced GAIE training and operation may include recognition of higher-level communication features of users (humor, sarcasm, dishonesty, double entendre, etc.) and user emotional state, for example.

In example embodiments, methods and systems for enhancing GAIE platforms, such as those described herein, may include configuring a GAIE to participate in multi-user dialogue, where strict turn-taking interaction with one person might be difficult in a group setting, where the context of who may be speaking to whom matters for each expression. The more fluid multi-user conversational structure vs. turn-taking structure may indicate advances to a GAIE may include developing understanding of: social interactions and cues, such as to whom each expression may be directed; group dynamics (e.g., who may be the group leader?) and interpersonal relationships; the notion of threaded discussions with branches; concurrent discussions between various sub-groups of a group; when to chime in with input so as to avoid interrupting other users; some notion about conversational balance, to avoid dominating the conversation; tact: users' sensitivity about personal information, and when it may and cannot be shared in a group setting based on context, relationships with other users, and the like.

Independent of whether interactions are one-on-one or multi-user, it is envisioned that a GAIE may be adapted to evolve beyond a turn-taking paradigm. In an example, a GAIE may currently create media (images, music, video, and the like) based on a user prompt (that itself may be one or more types of media), and may refine the created media based on user interactions, such as changing the content in certain ways or extending the boundaries of an image with more content that may be consistent with the existing content. A more sophisticated version of generative AI may flexibly and continuously adapt its generated content to contextual user input and interactions. In an example, generating media may be adapted by the GAIE in response user integration with the generated media content, such as in response to allowing a user to virtually walk around inside the content to interact with and/or react to content items. Such a media-adapting GAIE may generate new content or update the content based on the user input/content virtual interactions. Yet further to facilitate a user to virtually interact immersively with generated content details about the user may be considered part of the criteria for newly generating and/or updating the media.

In example embodiments, a media-output enabled GAIE without user immersive interaction and feedback may generate media (e.g., a first image) based on a prompt in which a user specifies a theme for a story. The user may then specify a series of scenes that follow, and the GAIE generates an image for each scene, leading to a storyboard series for the story.

When a media-out enabled GAIE is teamed with user immersive capabilities, the user may control, for example, an avatar that may walk around within the scene and interact with generated media objects. Based, for example, on an order and manner with which the user traverses the scene and interacts with the objects, the generative algorithm may generate new content (e.g., the user looks at a particular painting on the wall of a gallery and then opens the curtains of a window). Outside the window may be an entire world that may be consistent with the particular painting that the user viewed. If the user chooses to move the avatar into that world, the painting on the wall updates to reflect the user's interactions.

In another example of immersive user-generated media content engagement, a user may request a science fiction story. In addition to generating a story based on tropes that are generally relevant to science fiction, the GAIE may include tropes that are likely familiar to the user, such as based on the user's age, culture, other interests, etc. (such as science fiction versions of characters that are well-known in the oeuvre of myth and literature to which the user belongs). In some cases, the algorithm may even include individuals in the created story that are analogous to celebrities or public figures in the user's culture or generation, or even the user's own friends and acquaintances.

In example embodiments, a superintelligence system may be based on a pre-trained GAIE that facilitates automated discovery of relevant domain-specific knowledge and examples. The superintelligence system may further leverage pre-trained advanced GAIE to leverage domain-specific examples to generate content. Yet further the superintelligence system may include a genetic programming capability to create novel variation. In example embodiments, a superintelligence system may further include feedback systems (e.g., collaborative filtering and automated outcome tracking) to prune variation to favorable outcomes (financial, personalization, group targeting, and the like).

In example embodiments, an adapted GAIE system may improve rider satisfaction through, for example generative itineraries that facilitate automated discovery of relevant domain-specific knowledge and examples. Such an AI system may facilitate user discovery of a series of available routes to a known destination (e.g., where a tourist's next hotel reservation takes place). Such a GAIE system may discover and express to the rider content for potential waypoints on those routes, including dining, shopping, and tourism opportunities, as well as friends or potential group activities (a lesson, a hike, an exercise class).

In example embodiments, an adapted GAIE system may improve rider satisfaction by leveraging domain-specific examples to generate content. In an example, the GAIE may generate an itinerary for a day of travel from a current location (or a planned location) to the destination, including recommendations and ratings, photographs, time windows, and contingency options (if this goes quickly, you may add a side trip to that).

In example embodiments, an adapted GAIE system may improve rider satisfaction through use of genetic programming to create and present novel variation, such as by generating a variety of new itineraries and novel ways of presenting them (e.g., with a variety of styles of graphic art, introduction of humor, introduction of deep historical background (e.g., coverage of historical/indigenous people, and the like.). Novel ways of presenting may include gamifying the content of the itinerary, ascribing rewards for hypermiling the itinerary, ascribing rewards for completion of tasks related to experiencing it, offering a scavenger hunt, setting up a content for the best photograph, funniest photograph, and the like. Other aspects of use of an adapted GAIE for novel presentation may include competing for the best addition of content for the next version of the itinerary, generating legacy content that memorializes the experience, generating varied legacy content elements for sharing to different audiences including parents, travel companions, friends, emphasizing specific areas of interest of the intended audience (e.g., deep content on birds for a birder, etc.). An adapted GAIE system may improve rider satisfaction through use of genetic programming plus feedback systems (e.g., collaborative filtering and automated outcome tracking) to prune variation to favorable outcomes (financial, personalization, group targeting, etc., etc.), tracking financial impact on local businesses (spending), tracking user satisfaction as reported, tracking user satisfaction as indicated by physiological monitoring, tracking time at each destination as an indicator of enjoyment, adjusting future itineraries based on feedback functions, and the like.

In example embodiments, other features may include an in-cabin voice interface for processing of information regarding objects in proximity of a current location; allow querying the agriculture-pretrained GAIE by voice for everything from physical entities in proximity to the vehicle to the history of the area, average cost of housing employment data, crime data, recommended route based on criteria specified by vehicle occupant (“take me through NYC on a route that maximizes the prior residences of well-known artists”), and the like. The GAIE system may interface with a vehicle navigation system to map a route. In this regard, an adapted GAIE system may improve rider satisfaction through deployment of a voice interface for constructing a route based upon a criterion provided by a vehicle occupant.

In example embodiments, an agriculture subject matter based GAIE system may interact with a machine learning and/or AI system trained using a corpus of data relating to a defined geographic location. This system may include an in-cabin voice interface for accessing and querying the machine learning and/or AI system. The system may be configured with a processor for automatically selecting from the corpus those data that relate to a current location datum associated with a vehicle. Yet further, a navigation system interface for facilitating presentation (for presenting) of a route to a vehicle occupant, wherein the route may be selected based on a query datum provided by the vehicle occupant and the resulting output of the machine learning/AI system.

In example embodiments, a GAIE system may include a tool to query maintenance records for models of vehicles to offer a user a prospective view of the likely timing of failure and points of failure in a particular model (e.g., struts to first fail after 38 months of daily use and/or X miles); offer comparisons to other models; integrate location data into the forecast based on areas traveled, types of roads, amount of traffic, and the like. In example embodiments, a GAIE system may be adapted and/or pretrained for use in an agriculture domain and may predict points of failure in a vehicle make/model based upon a criterion related to vehicle usage, and the like.

Another candidate use of an agriculture-domain focused GAIE may include establishing a conversational dialogue and/or interaction with a passenger and/or driver about a topic of the user's choice, simply to maintain passenger and/or driver alertness on long routes. In example embodiments, a system may include an individual alertness sensor that determines an alertness of an individual in a vehicle, and a conversation engine that engages the individual in a conversation based on the alertness of the individual.

In example embodiments, deployment of an agriculture subject matter configured GAIE may include dialogue-driven trip planning. In example embodiments, a user prompts the GAIE to plan a trip from origin to destination with stops for food and fuel along the way. In response, the GAIE may provide some initial suggestions. The user may interact via dialogue to make explicit changes and/or prompt the GAIE to provide another/alternate suggestion. For example, the user may say “I'd rather stop at a restaurant than get fast food,” or “I'd prefer not to use this highway because there may be a lot of traffic,” or “I'd like to stop for a break every 60-90 minutes.” In response to this dialogue prompt, the GAIE may update the suggestion based on the user's specific feedback; this may be much more fluid and natural than conventional, hard-coded travel planning and adjustment. In example embodiments, a system having a route planning engine may determine a suggested route for travel of a user, and a conversation engine may adjust the suggested route based on a conversation with the user about the suggested route.

In example embodiments, deployment of an agriculture subject matter configured GAIE may facilitate defusing driver frustration, such as by settling down the user through calming conversation.

In example embodiments, deployment of a configured GAIE may facilitate dialogue-driven knowledge discovery about a travel condition. In an example, a high number of vehicles are stopping or performing erratically at a particular intersection. A prompted conversation may be initiated between the GAIE and drivers (perhaps just past the location of the anomaly) in which the rider may ask what was happening there and why the other vehicles were behaving as they did. This type of conversational interface may be much more fluid than conventional, facts-only information gathering processes (e.g., searching for traffic issues and the like). A more fluid conversational interaction may ultimately determine that there was an accident at the location. However, the dialogue may lead to the GAIE presenting a range of different candidate actions and/or outcomes, such as advising other users who are approaching the location, contacting first responders based on the nature of the problem, and the like. In example embodiments, a system may include a travel anomaly detector that detects a location associated with an anomalous behavior of an operator of a vehicle, and a conversation engine that determines information about the anomaly based on a conversation with the operator of the vehicle. In embodiments, the system may be GAIE-based. The GAIE may be adapted and/or pre-trained for use in an agriculture deployment environment.

In example embodiments, a GAIE platform may include an interactive recommendation engine for nearby or en route options related to entertainment, dining, scenic viewing, and the like. A voice enabled user interface for a GAIE may include a recommendation engine that may be configured to provide recommendations for dining, entertainment, or scenic viewing destinations wherein the destinations are within a prescribed distance from the desired travel route.

In example embodiments, an adapted GAIE deployment may include conversational interfaces for personal assistants, such as voice-based interaction with drivers; this by itself may be a vast improvement over known interfaces, (e.g., visual/tactile input with some very simple and low-spec voice interfaces).

A pre-trained GAIE may overcome problems with current agriculture system voice interfaces that may be limited in bandwidth to communicate with a driver, due to a driver's fluctuating attention span and degree of perceived safety. In example embodiments, when a driver may be driving on a familiar highway with cruise control engaged, their ability to listen, speak, and interact may be much higher than when they are driving (a) somewhere new and unfamiliar, (b) in circumstances that require fast reflexes and many decisions in a short period of time, such as stop-and-go traffic, (c) in poor weather conditions, and/or (d) in circumstances where vehicle passengers are loud or engaging in distracting behaviors. Therefore, a voice interface for a pre-trained GAIE may be adapted to be selective as to: (1) what information to present (e.g., prioritizing based on subject matter: emergency information vs. driving-related information vs. social media updates) and (2) when to present information (e.g., don't talk to the user while they are driving in tense circumstances, such as approaching a highway exit ramp; wait for a moment when the user has available attention, such as waiting at a traffic light, ask the user if now is a good time to discuss).

In example embodiments, a GAIE may be pre-trained for use by and/or in cooperative operation with a digital twin engine, such as an instance of an executive digital twin and the like. In an exemplary deployment, a GAIE may interact with a digital twin to provide a narrative about a topic of the digital twin to give to a viewer. In this example, the digital twin may interact with the GAIE (e.g., through an API and the like) to generate a narrative summary for a CEO and a detailed narrative for a CFO.

Executive digital twins may be configured for a particular role or user. Therefore, a GAIE system with a digital twin interface may improve executive digital twin capabilities by curating the data for and populating content for consumption by executive digital twins for different roles. In an example a GAIE may receive information about the executive digital twin as well as about the intended human being represented by the executive digital twin (e.g., the role of the user). The GAIE may determine a degree of narrative detail for each executive digital twin. This may be based on generic executive digital twin/user role criteria and/or refined through interaction with a particular user for the executive digital twin. In example embodiments, a CEO with a tech focus may receive more “in-depth” narrative relating to tech or R&D, whereas a CEO with a financial background may end up receiving narratives that are more focused on financial analysis but less granular on tech-related features.

In example embodiments, a GAIE system that interacts with a digital twin engine (e.g. an executive digital twin instance and/or engine) may determine of the potential universe of content on which it is trained, what may be relevant and what may be noise or unrelated for the specific narrative topic, the target human consumer, and the like. Based on this relevance determination, the GAIE system may generate the output data based on the relevant data and the determined degree of detail.

Further, the GAIE system may also select real time data sources to connect to a target/requesting executive digital twin. The GAIE may further configure consumption pipelines for those sources on the spot (e.g., data source identification, data requests for identified data sources, API configuration, and the like). Therefore, in this example the GAIE system would be identifying data sources and connecting them to an executive digital twin instance/engine.

An example use case may include an executive digital twin that has access to full financial data from a previous time-frame (e.g., a previous year/quarter/month, and the like). The executive digital twin may enable access by the GAIE to all of this data. The GAIE may determine a degree of detail of the data for the intended viewer (e.g., target consumer of a narrative regarding a topic captured in the full financial data).

In the case of a target consumer/view having a role of CEO, the GAIE may determine that the narrative for the CEO will include key insights but not full details. The GAIE may then generate a narrative of the top insights for a target time-frame (e.g., a current quarter) from at least the received data.

A pre-trained GAIE may be used to generate, manage, and/or manipulate digital twins, such as by describing attributes of a digital twin, describing interactions with other digital twins or environments, describing simulations, using digital twin simulation data to generate content, enabling context-adaptive executive digital twins, facilitating development of narratives about ongoing, real time operations, tuned to the preferred conversation style of a user represented by a digital twin, and the like. In example embodiments, a context-adaptive executive digital twin integrated with a generative conversational AI system may be configured to generate a set of narratives about operations of an enterprise based on an input data set of real-time sensor data from the operations of the enterprise. The digital twin (or human user) may prompt the GAIE and/or conversational AI system to compare financials with real-time sensor data.

A GAIE may be adapted (e.g., pre-trained) to facilitate enhancement of AI training data associated with a digital twin application. In example embodiments, a method may include using an AI conversational agent to create synthetic training data.

Further in association with digital twin technology, a GAIE may be adapted for summarizing highly granular data for consumption by an executive digital twin. In this regard, an executive digital twin system may include an intelligent agent that receives a set of customization features from a user (e.g., an executive represented by the digital twin) that include a role of the user within an organization. The intelligent agent may also determine a respective granularity level of a report based on the customization features. In example embodiments, the set of customization features include granularity designations for different types of reports. Yet further, the intelligent agent determines the granularity level of a report based on the role of the user within an organization. Further, the subject matter of the report may be generated based on the role of the user within the organization.

In example embodiments, a speech-based user interface for customizing a level of specificity for generating executive digital twin reports may be operatively coupled to a customized GAIE that processes the speech into a set of report instructions (and optionally report content) based on aspects of the user(s). An example of a speech-based request that may be processed as described may include, “I'd like an executive-summary level report on predictive maintenance” or “I'd like a detailed report on competitor analysis.” The speech-based user interface may respond to such a request by directing a corresponding executive digital twin system to feed a specificity level for parameters to a generative AI engine (e.g., GAIE) as additional input along with the data. In this example, IoT data from manufacturing facilities may be used in predictive maintenance. A response to a prompt regarding preventive maintenance may be customized with a level of specificity based on target report consumer role(s), such as for an operations-based role. A level of specificity may include what are the costs, when is the maintenance needed by, what may be the predicted downtime, how to offset and/or time the maintenance activity, and the like. For a financial-based role, specificity levels may be adapted to address what may be the disruption going to do for the bottom line in the short term; how does this impact our supply; what may the disruption do to our market-share; will it impact our stock price, and the like.

When a digital twin may be used to model an individual, a fine-tuned GAIE may be used to coordinate the digital twin with the human for improved fidelity (e.g., when the human behaves or reacts differently than the digital twin predicts, a GAIE may initiate a dialogue with the user to determine why, and the results may be used to update the digital twin model for the individual). Instead of having a human expert occasionally participate in automated digital twin model training (e.g., to correct errors or provide new examples, and the like), a corresponding GAIE may be occasionally querying the user to solicit more information to update the digital twin model of the individual. As an example, a system may include a digital twin that models an individual, and may further include a conversation engine that facilitates determining an update of the digital twin based on a conversation with the individual that is associated with a difference between an action of the individual and a corresponding action prediction by the digital twin.

In example embodiments, a GAIE system may be configured for use in an automated manufacturing environment. In one example, a user may prepare a descriptive prompt of a desired product to have it 3D printed. The GAIE system may generate a 3D printing set of instructions, such as a configuration of an automated 3D printing machine and a rendering indicative of a result of the 3D printing machine following the instructions. In another example, a user may include a photo/video of product as a prompt along with a request for instructions to 3D print an improved version, such as “I want this bike but I want different tires and I want it to be red.”

Another exemplary use of a pre-trained GAIE may include using user behavioral data to generate guiding recommendations for energy conservation, usage shifting, and the like. In particular, a recommendation system for energy conservation, usage shifting, or optimization may include an integrated generative, conversational AI system that adapts generated output based on user behavior from a user behavior data set.

In example embodiments, an adapted GAIE may facilitate management of energy resources. An energy resource management system may be enhanced to provide advanced intelligence (e.g., superintelligence) to plan, manage, and/or govern DERs and energy generation, storage, consumption, and transmission facilities. Elements of a superintelligent energy management system may include automated discovery of relevant domain-specific knowledge and examples, generative AI to leverage domain-specific examples to generate content, genetic programming to create novel variation, feedback systems (e.g., collaborative filtering and automated outcome tracking) to prune variation to favorable outcomes (financial, personalization, group targeting, etc., etc.), and the like. In an example, a superintelligent AI-enabled management system may be configured to manage a plurality of systems of an energy edge platform via automated discovery, generative AI, genetic programming, and feedback systems.

In example embodiments, a GAIE may be adapted (e.g., trained, pre-trained, and the like) for the field of patents to generate patent claims responsive to being provided a patent disclosure. An enabled GAIE may receive patent claims as a prompt and may generate a supportive patent disclosure therefrom. In example embodiments, an enabled GAIE may be trained to understand a patent structure and a claim structure for a plurality of jurisdictions.

In example embodiments, a GAIE may be pretrained (e.g., finetuned) with a private instance of an enterprise's intellectual property data (e.g., products, business goals, competitive considerations, core inventive ideas, and the like). In example embodiments, a private instance of enterprise data for patent generation may be configured (e.g., as prompt-response pairs) for finetuning the GAIE instance.

Beyond patent disclosure and figure preparation, a GAIE may be fine-tuned to generate figures, disclosure from figures, claims from figures, office action responses, evidence of use (EOU) for patent monetizing, preparing a matrix of patent claims across a portfolio, high level landscape search strings, enhancement of search strings, and the like. Finetuning may include preparation of prompt-response sets for a range of IP-related actions, such as patent claim assertion, infringement analysis and discovery, claim (term) acceptance and/or rejection, estimate of claim scope broadness, claim quality, and the like. In example embodiments, an IP-tuned GAIE may be pre-trained with information from proceedings related to infringement cases to understand the likelihood of infringement, and the like.

GAIE training and IP-integration may facilitate elaboration of broadly stated inventive concepts into disclosure that reflects robust enablement and/or support. In an example, an outline may be an input prompt for the purposes of drafting a patent application (e.g., disclosure, figures, summary, abstract, and optionally claims). A generated result may become a portion of a subsequent prompt along with a description of the general theme, category, focus area and/or other categorization or classification of innovation. In an example, one may describe a transaction environment processing platform and ask for examples of a technical implementation, system, and/or method design, such as: “In the context of a transaction environment processing platform as previously described, what types of hardware and software might be used to implement a governance engine for the transaction environment?”

Regarding an intellectual property (e.g., patent) monetization-focused development process, a GAIE may facilitate predicting, from a market development view, which domains to select and which categories within domains to emphasize based on the ability to determine where business may be shifting over a longer time (e.g., beyond short-term trends). This may include analyzing historical data and current data for one or more IP domains, optionally in near-real time. An IP-monetization-focused GAIE may tie historical and/or current data to investments and actions having occurred in the IP world for, among other things, patent sales and licensing. An IP-monetizing trained GAIE may also develop particular leads and domain categories with the highest probability of success based on previous sales and/or licensing and/or where the market may be heading. There may be risk in making these decisions but using a trained GAIE may lower this risk so that these decisions become more predictable in the future, especially with company data increasing and likely accessible through various channels.

A GAIE may be configured, trained, and/or fine-tuned for a range of functions, including, for example, ingestion of proprietary data, determination of a route, determination of an outcome, approval of release/access to data, making a prediction, pattern recognition, and the like. Yet another example application of a fine-tuned GAIE may include layering of voice and visual commands that may be graduated in sound, volume, or spacing similar to flight avionics, thereby generating scripts for voice over of data and/or presentation material. This may enable the development of synthetic speech technology that generates lifelike (AI-generated) voices for podcasts, slideshows, and professional presentations. This may mitigate needs for hiring a voice artist or using any complex recording equipment (e.g., background noise separation, dubbing, and the like).

In example embodiments, GAIE systems may be configured for facilitating news delivery from NPC-type avatars to adapt current “clickbait” content to conversationally conveyed world news/happenings. In this example, a metaverse environment may include a news-based GAIE conversation agent configured to conversationally inform users of recent events.

Further in context of metaverse technology, a generative AI conversational agent may be configured to populate the metaverse.

Yet further within a context of metaverse technology, a GAIE system may be enabled to augment training data for a customized conversational agent with real-time sensor data sets through collecting information from real-world sensors. In an example, a training data augmentation system may be configured for augmenting training of a conversational agent with data from a real-time sensor data set. Further, a metaverse-associated GAIE system may facilitate augmenting training data for a customized conversational agent with process outcome data. A training data augmentation system may be configured for augmenting training of a conversational agent with process outcome data from a process outcome data set, user behavior data, and the like. In example embodiments, a training data augmentation system based on a GAIE may be enabled (e.g., pre-trained) for augmenting training of a conversational agent with user behavior data from a user behavior data set.

In example embodiments, application of fine-tuned GAIE systems in the field of governance may facilitate advances in automation of governance, such as governing use of copyrighted material. GAIE-based governance systems may further enhance governing AI training, such as conversational AI training data sets for bias and error, governing conversational AI for contextual appropriateness and other stylistic requirements, and the like. A fine-tuned GAIE system may further improve governing secrecy, such as a progression of what elements of secret, proprietary or confidential information are allowed based on a depth of conversation. Governance may further apply to individuals. Therefore, a governance fine-tuned GAIE system may enhance and/or automate determining a measure of trustworthiness of a user that may be interacting with a generative conversational AI system. Further a governance fine-tuned GAIE system may enrich governance for a generative AI system, such as determining a measure of trustworthiness of a generative conversational AI system. In general, governance use cases may be expanded further in light of GAIE topic-targeting training capabilities.

A fine-tuned GAIE system may play a role in systematic risk identification, management, and opportunity mining. GAIE-based risk identification systems may respond to risk-related prompts, such as “What may else might we know and should be paying attention to?” by curating data sets and automating the processes of identification of systemic risks, identifying a set of likely scenarios and the risks and opportunities arising from those scenarios, identifying paths for resolution and recommending resolutions.

Yet another area of risk identification and/or management may involve security concerns with GAIE systems that are configured to generate computer executable code. At the least relying on computers to write computer code raises questions about what security measures are effective and what measures are able to be circumvented by the AI.

A further area of risk identification, management and/or opportunity harvesting may apply to copyright material. Automated computer code generation may inadvertently introduce copyrighted material, such as algorithms. A risk-finetuned copyright GAIE may assist in detecting candidate copyright violations in any programmatic code, including machine generated code.

Risk identification of visual training sets (e.g., images, graphs, and the like) may be enhanced by a fine-tuned GAIE that can process these visual training data sets for authenticity indicators that are coded as non-visual data. This may be similar to tail voltage devices providing messages on the end of sine waves. Visual training sets may be coded with non-visual indicators of authenticity that may be detectable by a fine-tuned GAIE.

Yet another risk-identification related area includes fraud detection. Integrating customer fraud reporting and questioning into pretraining data may enrich holistic scoring, which may comprise a composite score that bridges customer evidence, transactions, and environmental trends. In an example, an AI based fraud detection system may integrate customer fraud reports and questioning into a training/query data set to produce a holistic scoring system, utilizing a composite score that combines customer evidence, transaction data, and environmental trends to provide a comprehensive approach to fraud detection.

Imaging applications may benefit from fine-tuned GAIE systems. In example embodiments, optical content (e.g., screen shots and the like) may be processed by machine vision systems so that the GAIE may describe a scene in the optical content using a generative conversational AI agent. In example embodiments, a GAIE may be configured as a first AI/NN sub-system in a Dual Process Artificial Neural Network (DPANN) architecture. Such a DPANN architecture may include, as a second NN sub-system, a formal logic-based and/or fuzzy-based system. Together these DPANN systems may implement learning processes, model management, and the like. In example embodiments, a DPANN architecture may include features that describe building and managing large scale models.

Referring to FIG. 1, a platform for the application of generative AI 400 may include a robust task-agnostic next-token prediction artificial intelligence model 402 that operates to predict a next token given a set of inputs encoded as embedded tokens. A robust task-agnostic next-token prediction AI engine 402 may include deep learning models, which use multi-layered neural networks to process, analyze, and make predictions with complex data, such as language. An objective of the robust next-token prediction AI engine 402 may include data science modeling through, among other things, use of topic-specific embeddings, attention mechanisms, and decoder-only transformer models. Capabilities of such an engine 402 may include a pre-training capability to facilitate configuring next-token prediction for specific subject matter (e.g., marketplace item valuation), a tokenizing capability to facilitate converting complex terms into actionable tokens (e.g., converting compound chemical names into fundamental elements), access to distributed training (e.g., data-parallel training and/or model-parallel training, and the like), few-shot learning to reduce training demand for updates, such as new business intelligence data, and the like. In general the next-token prediction AI engine 402 may combine large language modeling techniques and decoder-only transformer models to generate powerful foundation models for next-token prediction AI content generation.

In example embodiments, the next-token prediction AI engine 402 may be structured with a machine learning (sparse Multi-Layer Perceptron) architecture configured to sparsely activate conditional computation using, for example mixture-of-experts (MoE) techniques. A machine learning architecture may be configured with expert modules that may be used to process inputs and a gating function that may facilitate assigning expert modules to process portion(s) of input tokens. A machine learning architecture may further include a combination of deterministic routing of input tokens to expert modules and learned routing that uses a portion of input tokens to predict the expert modules for a set of input tokens.

In embodiments, a GAIE 400 may be trained to operate within a domain, such as written language, computer programming language, subject matter-specific domains (e.g., a software orchestrated marketplace domain), and the like to generate content (constructs) that comply with rules of the domain. In general, a GAIE may generate content for any topic for which the GAIE is trained. So, for example, a GAIE may be trained on a topic of pig farmers and may therefore generate language-based descriptions, images, contracts, breeding guidance, textual output, and the like for any of a potentially wide range of pig farmer sub-topics.

Adapting a generative AI engine for subject matter-specific applications may include pretraining a next-token prediction AI model-based system through the use of, for example, in-context (e.g., application, domain, topic-specific) examples that are responsive to a corresponding prompt. While the next-token predictive capabilities of the underlying next-token prediction AI engine may remain unaffected by this pre-training, subject matter-specific pre-trained instances may be developed/deployed.

In example embodiments, a platform for the application of generative AI 400 may include a set of subject matter-specific pretrained examples and prompts 404. This set 404 may be configured by analyzing (e.g., by a human expert and/or computer-based expert and/or digital twin) information that characterizes various aspects of the domain to generate example prompts and preferred and/or correct responses. Pretraining may also include training the next-token prediction AI engine 402 by sampling some text (e.g., prompt/response sets) from the set of subject matter-specific pretrained examples and prompts 404 and training it to predict a next word, object, and/or term. Pretraining may also include sampling some images, contracts, architectures, and the like to predict a next token. These prompt-response sub-sets may facilitate pre-training the prediction AI engine 402 for predicting a next token (e.g., word, object, image element, and the like) for various aspects.

When an instance is implemented for textual generation, such a GAIE instance may be referred to as a natural language generation system that constructs words (e.g., from sub-word tokens), sentences, and paragraphs for a target subject and/or domain.

In example embodiments, real-world instances of the platform 400 may require ongoing updates to facilitate the platform 400 being responsive as aspects of a domain (e.g., a business entity in the domain) change, such as business goals change, new products are released, competitors merge, new markets emerge, and the like. In this regard, training the platform 400 with in-context prompts and examples may be automated and repeated as new data is released for an enterprise to prevent snapshot-in-time data aging-based errors. The platform the application of generative AI 400 may include an ongoing pre-training module 428 that processes new and updated content into prompt and/or response sets and interactively iterates through rounds of pre-training. New and updated data and/or information may regularly be found in various subject matter specific information sets, such as: a dataset of medical records (e.g., to assist with medical diagnoses), a dataset of legal documents and court decisions (e.g., to provide legal advice), a release of a new product (e.g., images of the product), or a financial dataset such as SEC filings or analyst reports. In example embodiments, uses of the platform 400 may include applying the pre-training and optimizing techniques to a range of different domains (e.g., medical diagnosis, business operation, marketplace operation, and the like) to produce a fine-tuned domain specific token-predictive engine including ongoing refinement through (daily) in-context pretraining.

In example embodiments, an ongoing pre-training module 428 may work with the next-token prediction AI engine 402 to update a set of subject matter specific tokens that may be maintained in a subject matter specific instance token storage facility 408. This subject matter specific instance token storage facility 408 may be referenced by a subject matter specific instance of the next-token prediction AI engine 402 during an operational mode (e.g., when processing inputs/prompts). In example embodiments, the platform 400 may include a plurality of sets of subject matter specific tokens that may be maintained by corresponding ongoing pre-training modules 428.

Training, however, may not ensure that the responses to prompts are correct every time. In general, a business entity is likely to be less interested in a tool that provides answers that are probably right and may differ from time to time. A product that can provide accurate responses (e.g., including taking actions) based on what the end-user wants vastly increases the potential use cases and product value. A high level of accuracy and integration with operational systems may enable such a tool to go beyond just generating new content to be more productive; through integration with workflows, it may facilitate automating workflow actions. In this regard, the platform for the application of generative AI 400 may also include a pre-training optimizing module 406 that may work cooperatively with the ongoing pre-training module 428 to further refine accuracy of responses to prompts for a domain. The pre-training optimizing circuit 406 may facilitate improved accuracy of in-context responses, task-specific fine-tuning, and for sparse model variants of the platform 400, enrich few-shot learning capabilities. In example embodiments, fine tuning may further benefit the platform by reducing bias that may be present in the training data. This may be essential to ensure subject matter specific jargon is adapted as training data changes (e.g., in the digital marketing/promotional space, ensure that “influencer” is replaced with “creator”). Further, a pre-training optimizing engine 406 may provide a wider range of prompts and responses based on user preferences (e.g., speaking styles) to enrich the platform's ability to provide user-centric responses. In example embodiments, user-centric responses may include fine tuning the platform 400 for different roles in an organization. As an example, when a user in a financial planning role inquires about a business development topic, responses may be directed toward the financial planning role (e.g., as compared to a customer/client inquiry about that topic).

A platform for the application of generative AI 400 may be used to produce text-based content for a multi-national entity with employees who speak different languages. While the platform 400 may be trained (and pre-trained) to operate interactively in a plurality of languages, generating automated content may benefit from use of a neural machine translation module 410. In example embodiments, a portion of the entity in a first jurisdiction may produce content in a first language and resulting recurring generated output (e.g., types of reports and the like) may be generated in the first language. However, employees who speak a second language may benefit from the type of report when translated into the employee's native language. Therefore, associating the neural machine translation module 410 with the platform may prove valuable while reducing compute demand for the platform 400.

Emerging next-token prediction AI systems feature increasingly adaptable next token prediction capabilities. These capabilities may be further adapted to assist in closed problem set solution prediction, such as allocation of resources, deployment of a robotic fleet and the like. To achieve greater prediction capabilities, a subject matter specific next-token prediction AI-based engine, such as the platform for the application of generative AI 400, may include a solution-predictive engine 412 that leverages next-token (e.g., next word) predictive capabilities to predict a most-likely solution to a closed solution-set problem. This may be accomplished optionally through use of sets of problem domain-specific pre-training prompts and examples. Such examples may be adapted for different user preferences. In example embodiments, each user in a closed problem set environment may generate prompts and responses that may enable the platform 400 to respond to the user based on the user's inquiry style. Alternatively, the solution prediction engine 412 may adapt a user's prompt and/or configure a prompt based on user preferences to attempt to deliver responses that are consistent with a user's preferences (e.g., engineering-based responses for an engineer role-user and legal-based responses for a lawyer).

For more complex analysis and decision making/predicting, a formal logic-based AI system 414 may be incorporated into and/or be referenced by the subject matter specific platform 400.

Further, the basic concepts of next-token prediction of a generative AI engine, such as the platform for subject matter based application of generative AI 400 may be applied to analyzed expressions of images, audio (e.g., encoded text), video (e.g., sequences of related images), programmatic code (domain-specific text with readily understood rules), and the like. Therefore, a next-token prediction AI platform (e.g., platform 400) may further include an image/video analysis engine 416 (optionally NN-based) that adds a spatial aspect to the next-token predictive capabilities of a next-token prediction AI system. Images used for training may include 3D CAD images (for a domain that includes physical devices such as vehicles), radiologic images (for a medical analysis domain), business performance graphs, schematics, and the like. In example embodiments, aspects of the underlying task-agnostic next-token prediction AI engine 402 may be adapted (e.g., different embeddings, neural network structures and the like) for different input formats, such as images, temporal-spatial content, and the like.

The platform 400 may further include an expert review and approval portal 418 through which an expert (e.g., human/digital twin, and the like) can review, edit, and approve content generated. Examples include review and adaptation by a subject matter specific data story expert; a data scientist, and the like. The expert review and approval portal 418 may operate cooperatively with, for example, the pre-training optimizing module 406 that may receive and analyze expert feedback (e.g., edits to the content and the like) for opportunities to further optimize the platform 400.

The platform 400 may further include a training data generation facility 420 that may generate natural language prompts, such as subject matter specific prompts that may be applied by, for example, the pre-training optimizing engine 406 to increase platform response accuracy and/or efficiency while fine tuning a subject matter specific instance.

In example embodiments, the platform 400 may further be configured to access a corpus of domain and/or problem relevant content as a step in responding to a prompt. In example embodiments, the platform may be pre-trained on the content of the corpus. While the content of the corpus may not be directly included in the response, such as if it provides a level of detail beyond what the platform 400 has been trained to provide in a response, it may be cited in the response to facilitate identifying and expressing sources from which a response is derived. These external source references may be handled via a citation module 422.

Business decisions are often context-based. Understanding both the context for a decision and aspects and/or assumptions of the decision process may prove highly valuable for evaluating, for example, competing decisions and/or recommendations. Context may include both tangible and intangible factors. An intangible factor may include historical interactions between parties involved in the evaluation process, for example. A decision process may include not only assumptions on which a decision or recommendation is based, but also criteria by which tangible factors are processed, evaluated, analyzed, and the like. To provide such context for generated output of the platform 400, an interpretability engine 424 may be incorporated into and/or be accessible to the platform 400. An objective of use of the interpretability engine 424 may be to generate additional content that reflects context for, among other things, how the next-token prediction AI instance operates and/or generates a corresponding output.

In example embodiments, the next-token predictive capabilities of a next-token prediction AI engine 402 may be utilized for developing a set of emergent data science predictive and/or interpretive skills. While such a platform may be trained directly on various data sets, context for elements and results in such data sets may be a rich source of complementary training data. By associating data elements with descriptions thereof, the platform 400 may gain data science capabilities, such as to group by or pivot categorical sums, infer feature importance, derive correlations, predict unseen test cases, and the like. In this regard, a data science emergent skill development system 426 may be utilized by the platform to enhance further subject matter specific applicability and utility. The methods and/or processes described in the disclosure, and steps associated therewith, may be realized in hardware, software or any combination of hardware and software suitable for a particular application. The hardware may include a general-purpose computer and/or dedicated computing device or specific computing device or particular aspect or component of a specific computing device. The processes may be realized in one or more microprocessors, microcontrollers, embedded microcontrollers, programmable digital signal processors or other programmable devices, along with internal and/or external memory. The processes may also, or instead, be embodied in an application specific integrated circuit, a programmable gate array, programmable array logic, or any other device or combination of devices that may be configured to process electronic signals. It will further be appreciated that one or more of the processes may be realized as a computer executable code capable of being executed on a machine-readable medium.

### Computer-Based Implementations

The elements described and depicted herein, including in flow charts and block diagrams throughout the figures, imply logical boundaries between the elements. However, according to software or hardware engineering practices, the depicted elements and the functions thereof may be implemented on machines through computer executable code using a processor capable of executing program instructions stored thereon as a monolithic software structure, as standalone software modules, or as modules that employ external routines, code, services, and so forth, or any combination of these, and all such implementations may be within the scope of the disclosure. Examples of such machines may include, but may not be limited to, personal digital assistants, laptops, personal computers, mobile phones, other handheld computing devices, medical equipment, wired or wireless communication devices, transducers, chips, calculators, satellites, tablet PCs, electronic books, gadgets, electronic devices, devices, artificial intelligence, computing devices, networking equipment, servers, routers and the like. Furthermore, the elements depicted in the flow chart and block diagrams or any other logical component may be implemented on a machine capable of executing program instructions. Thus, while the foregoing drawings and descriptions set forth functional aspects of the disclosed systems, no particular arrangement of software for implementing these functional aspects should be inferred from these descriptions unless explicitly stated or otherwise clear from the context. Similarly, it will be appreciated that the various steps identified and described in the disclosure may be varied, and that the order of steps may be adapted to particular applications of the techniques disclosed herein. All such variations and modifications are intended to fall within the scope of this disclosure. As such, the depiction and/or description of an order for various steps should not be understood to require a particular order of execution for those steps, unless required by a particular application, or explicitly stated or otherwise clear from the context.

Thus, in one aspect, methods described in the disclosure and combinations thereof may be embodied in computer executable code that, when executing on one or more computing devices, performs the steps thereof. In another aspect, the methods may be embodied in systems that perform the steps thereof and may be distributed across devices in a number of ways, or all of the functionality may be integrated into a dedicated, standalone device or other hardware. In another aspect, the means for performing the steps associated with the processes described in the disclosure may include any of the hardware and/or software described in the disclosure. All such permutations and combinations are intended to fall within the scope of the disclosure.

### Special-Purpose Systems

A special-purpose system includes hardware and/or software and may be described in terms of an apparatus, a method, or a computer-readable medium. In various embodiments, functionality may be apportioned differently between software and hardware. For example, some functionality may be implemented by hardware in one embodiment and by software in another embodiment. Further, software may be encoded by hardware structures, and hardware may be defined by software, such as in software-defined networking or software-defined radio.

In this application, including the claims, the term module refers to a special-purpose system. The module may be implemented by one or more special-purpose systems. The one or more special-purpose systems may also implement some or all of the other modules.

In this application, including the claims, the term “module” may be replaced with the terms “controller” or “circuit.”

In this application, including the claims, the term platform refers to one or more modules that offer a set of functions.

In this application, including the claims, the term system may be used interchangeably with module or with the term special-purpose system.

The special-purpose system may be directed or controlled by an operator. The special-purpose system may be hosted by one or more of assets owned by the operator, assets leased by the operator, and third-party assets. The assets may be referred to as a private, community, or hybrid cloud computing network or cloud computing environment.

For example, the special-purpose system may be partially or fully hosted by a third-party offering software as a service (SaaS), platform as a service (PaaS), and/or infrastructure as a service (IaaS).

The special-purpose system may be implemented using agile development and operations (DevOps) principles. In embodiments, some or all of the special-purpose systems may be implemented in a multiple-environment architecture. For example, the multiple environments may include one or more production environments, one or more integration environments, one or more development environments, etc.

### DEVICE EXAMPLES

A special-purpose system may be partially or fully implemented using or by a mobile device. Examples of mobile devices include navigation devices, cell phones, smart phones, mobile phones, mobile personal digital assistants, palmtops, netbooks, pagers, electronic book readers, tablets, music players, etc.

A special-purpose system may be partially or fully implemented using or by a network device. Examples of network devices include switches, routers, firewalls, gateways, hubs, base stations, access points, repeaters, head-ends, user equipment, cell sites, antennas, towers, etc.

A special-purpose system may be partially or fully implemented using a computer having a variety of form factors and other characteristics. For example, the computer may be characterized as a personal computer, as a server, etc. The computer may be portable, as in the case of a laptop, netbook, etc. The computer may or may not have any output device, such as a monitor, line printer, liquid crystal display (LCD), light emitting diodes (LEDs), etc. The computer may or may not have any input device, such as a keyboard, mouse, touchpad, trackpad, computer vision system, barcode scanner, button array, etc. The computer may run a general-purpose operating system, such as the WINDOWS operating system from Microsoft Corporation, the MACOS operating system from Apple, Inc., or a variant of the LINUX operating system.

Examples of servers include a file server, print server, domain server, internet server, intranet server, cloud server, infrastructure-as-a-service server, platform-as-a-service server, web server, secondary server, host server, distributed server, failover server, and backup server.

### Hardware

The term “hardware” encompasses components such as processing hardware, storage hardware, networking hardware, and other general-purpose and special-purpose components. Note that these are not mutually exclusive categories. For example, processing hardware may integrate storage hardware and vice versa.

Examples of a component are integrated circuits (ICs), application specific integrated circuit (ASICs), digital circuit elements, analog circuit elements, combinational logic circuits, gate arrays such as field programmable gate arrays (FPGAs), digital signal processors (DSPs), complex programmable logic devices (CPLDs), etc.

Multiple components of the hardware may be integrated, such as on a single die, in a single package, or on a single printed circuit board or logic board. For example, multiple components of the hardware may be implemented as a system-on-chip. A component, or a set of integrated components, may be referred to as a chip, chipset, chiplet, or chip stack.

Examples of a system-on-chip include a radio frequency (RF) system-on-chip, an artificial intelligence (AI) system-on-chip, a video processing system-on-chip, an organ-on-chip, a quantum algorithm system-on-chip, etc.

The hardware may integrate and/or receive signals from sensors. The sensors may allow observation and measurement of conditions including temperature, pressure, wear, light, humidity, deformation, expansion, contraction, deflection, bending, stress, strain, load-bearing, shrinkage, power, energy, mass, location, temperature, humidity, pressure, viscosity, liquid flow, chemical/gas presence, sound, and air quality. A sensor may include image and/or video capture in visible and/or non-visible (such as thermal) wavelengths, such as a charge-coupled device (CCD) or complementary metal-oxide semiconductor (CMOS) sensor.

The methods and systems described herein may transform physical and/or intangible items from one state to another. The methods and systems described herein may also transform data representing physical and/or intangible items from one state to another.

### Computer-Readable Media Examples

The computer software, program codes, and/or instructions may be stored and/or accessed on machine readable media that may include: computer components, devices, and recording media that retain digital data used for computing for some interval of time; semiconductor storage known as random access memory (RAM); mass storage typically for more permanent storage, such as optical discs, forms of magnetic storage like hard disks, tapes, drums, cards and other types; processor registers, cache memory, volatile memory, non-volatile memory; optical storage such as CD, DVD; removable media such as flash memory (e.g., USB sticks or keys), floppy disks, magnetic tape, paper tape, punch cards, standalone RAM disks, Zip drives, removable mass storage, off-line, and the like; other computer memory such as dynamic memory, static memory, read/write storage, mutable storage, read only, random access, sequential access, location addressable, file addressable, content addressable, network attached storage, storage area network, bar codes, magnetic ink, network-attached storage, network storage, NVME-accessible storage, PCIE connected storage, distributed storage, and the like.

### Processing Hardware

The methods and systems described herein may be deployed in part or in whole through machines that execute computer software, program codes, and/or instructions on processing hardware (also referred to as a “processor”). The disclosure may be implemented as a method on the machine(s), as a system or apparatus as part of or in relation to the machine(s), or as a computer program product embodied in a computer readable medium executing on one or more of the machines. In embodiments, the processor may be part of a server, cloud server, client, network infrastructure, mobile computing platform, stationary computing platform, or other computing platforms. A processor may be any kind of computational or processing device capable of executing program instructions, codes, binary instructions and the like, including a central processing unit (CPU), a general processing unit (GPU), a logic board, a chip (e.g., a graphics chip, a video processing chip, a data compression chip, or the like), a chipset, a controller, a system-on-chip (e.g., an RF system on chip, an AI system on chip, a video processing system on chip, or others), an integrated circuit, an application specific integrated circuit (ASIC), a field programmable gate array (FPGA), an approximate computing processor, a quantum computing processor, a parallel computing processor, a neural network processor, or other type of processor. The processor may be or may include a signal processor, digital processor, data processor, embedded processor, microprocessor or any variant such as a co-processor (math co-processor, graphic co-processor, communication co-processor, video co-processor, AI co-processor, and the like) and the like that may directly or indirectly facilitate execution of program code or program instructions stored thereon. In addition, the processor may enable execution of multiple programs, threads, and codes. The threads may be executed simultaneously to enhance the performance of the processor and to facilitate simultaneous operations of the application. By way of implementation, methods, program codes, program instructions and the like described herein may be implemented in one or more threads. The thread may spawn other threads that may have assigned priorities associated with them; the processor may execute these threads based on priority or any other order based on instructions provided in the program code. The processor, or any machine utilizing one, may include non-transitory memory that stores methods, codes, instructions and programs as described herein and elsewhere. The processor may access a non-transitory storage medium through an interface that may store methods, codes, and instructions as described herein and elsewhere. The storage medium associated with the processor for storing methods, programs, codes, program instructions or other type of instructions capable of being executed by the computing or processing device may include but may not be limited to one or more of a CD-ROM, DVD, memory, hard disk, flash drive, RAM, ROM, cache, network-attached storage, server-based storage, and the like.

A processor may include one or more cores that may enhance speed and performance of a multiprocessor. In embodiments, the process may be a dual core processor, quad core processors, other chip-level multiprocessor and the like that combine two or more independent cores (sometimes called a die).

Examples of processing hardware include a central processing unit (CPU), a graphics processing unit (GPU), an approximate computing processor, a quantum computing processor, a parallel computing processor, a neural network processor, a signal processor, a digital processor, a data processor, an embedded processor, a microprocessor, and a co-processor. The co-processor may provide additional processing functions and/or optimizations, such as for speed or power consumption. Examples of a co-processor include a math co-processor, a graphics co-processor, a communication co-processor, a video co-processor, and an artificial intelligence (AI) co-processor.

### Processor Architecture

The processor may enable execution of multiple threads. These multiple threads may correspond to different programs. In various embodiments, a single program may be implemented as multiple threads by the programmer or may be decomposed into multiple threads by the processing hardware. The threads may be executed simultaneously to enhance the performance of the processor and to facilitate simultaneous operations of the application.

A processor may be implemented as a packaged semiconductor die. The die includes one or more processing cores and may include additional functional blocks, such as cache. In various embodiments, the processor may be implemented by multiple dies, which may be combined in a single package or packaged separately.

### Network Infrastructure and Networking Hardware

The methods and systems described herein may be deployed in part or in whole through network infrastructures. The network infrastructure may include elements such as computing devices, servers, routers, hubs, firewalls, clients, personal computers, communication devices, routing devices and other active and passive devices, modules and/or components as known in the art. The computing and/or non-computing device(s) associated with the network infrastructure may include, apart from other components, a storage medium such as flash memory, buffer, stack, RAM, ROM and the like. The processes, methods, program codes, instructions described herein and elsewhere may be executed by one or more of the network infrastructural elements. The methods and systems described herein may be adapted for use with any kind of private, community, or hybrid cloud computing network or cloud computing environment, including those which involve features of software as a service (SaaS), platform as a service (PaaS), and/or infrastructure as a service (IaaS).

The methods, program codes, and instructions described herein and elsewhere may be implemented on a cellular network with multiple cells. The cellular network may either be frequency division multiple access (FDMA) network or code division multiple access (CDMA) network. The cellular network may include mobile devices, cell sites, base stations, repeaters, antennas, towers, and the like. The cell network may be a GSM, GPRS, 3G, 4G, 5G, LTE, EVDO, mesh, or other network types.

The networking hardware may include one or more interface circuits. In some examples, the interface circuit(s) may implement wired or wireless interfaces that connect, directly or indirectly, to one or more networks. Examples of networks include a cellular network, a local area network (LAN), a wireless personal area network (WPAN), a metropolitan area network (MAN), and/or a wide area network (WAN). The networks may include one or more of point-to-point and mesh technologies. Data transmitted or received by the networking components may traverse the same or different networks. Networks may be connected to each other over a WAN or point-to-point leased lines using technologies such as Multiprotocol Label Switching (MPLS) and virtual private networks (VPNs).

Examples of cellular networks include GSM, GPRS, 3G, 4G, 5G, LTE, and EVDO. The cellular network may be implemented using frequency division multiple access (FDMA) network or code division multiple access (CDMA) network.

Examples of a LAN are Institute of Electrical and Electronics Engineers (IEEE) Standard 802.11-2020 (also known as the WIFI wireless networking standard) and IEEE Standard 802.3-2018 (also known as the ETHERNET wired networking standard).

Examples of a WPAN include IEEE Standard 802.15.4, including the ZIGBEE standard from the ZigBee Alliance. Further examples of a WPAN include the BLUETOOTH wireless networking standard, including Core Specification versions 3.0, 4.0, 4.1, 4.2, 5.0, and 5.1 from the Bluetooth Special Interest Group (SIG).

A WAN may also be referred to as a distributed communications system (DCS). One example of a WAN is the internet.

### Storage Hardware

Storage hardware is or includes a computer-readable medium. The term computer-readable medium, as used in this disclosure, encompasses both nonvolatile storage and volatile storage, such as dynamic random-access memory (DRAM). The term computer-readable medium only excludes transitory electrical or electromagnetic signals propagating through a medium (such as on a carrier wave). A computer-readable medium in this disclosure is therefore non-transitory and may also be considered tangible.

### EXAMPLES

Examples of storage implemented by the storage hardware include a database (such as a relational database or a NoSQL database), a data store, a data lake, a column store, a data warehouse.

Examples of storage hardware include nonvolatile memory devices, volatile memory devices, magnetic storage media, a storage area network (SAN), network-attached storage (NAS), optical storage media, printed media (such as bar codes and magnetic ink), and paper media (such as punch cards and paper tape). The storage hardware may include cache memory, which may be collocated with or integrated with processing hardware.

Storage hardware may have read-only, write-once, or read/write properties. Storage hardware may be random access or sequential access. Storage hardware may be location-addressable, file-addressable, and/or content-addressable.

Examples of nonvolatile memory devices include flash memory (including NAND and NOR technologies), solid state drives (SSDs), an erasable programmable read-only memory device such as an electrically erasable programmable read-only memory (EEPROM) device, and a mask read-only memory device (ROM).

Examples of volatile memory devices include processor registers and random-access memory (RAM), such as static RAM (SRAM), dynamic RAM (DRAM), synchronous DRAM (SDRAM), synchronous graphics RAM (SGRAM), and video RAM (VRAM).

Examples of magnetic storage media include analog magnetic tape, digital magnetic tape, and rotating hard disk drive (HDDs).

Examples of optical storage media include a CD (such as a CD-R, CD-RW, or CD-ROM), a DVD, a Blu-ray disc, and an Ultra HD Blu-ray disc.

Examples of storage implemented by the storage hardware include a distributed ledger, such as a permissioned or permissionless blockchain.

Entities recording transactions, such as in a blockchain, may reach consensus using an algorithm such as proof-of-stake, proof-of-work, and proof-of-storage.

Elements of the present disclosure may be represented by or encoded as non-fungible tokens (NFTs). Ownership rights related to the non-fungible tokens may be recorded in or referenced by a distributed ledger.

Transactions initiated by or relevant to the present disclosure may use one or both of fiat currency and cryptocurrencies, examples of which include bitcoin and ether.

Some or all features of hardware may be defined using a language for hardware description, such as IEEE Standard 1364-2005 (commonly called “Verilog”) and IEEE Standard 1076-2008 (commonly called “VHDL”). The hardware description language may be used to manufacture and/or program hardware.

A special-purpose system may be distributed across multiple different software and hardware entities. Communication within a special-purpose system and between special-purpose systems may be performed using networking hardware. The distribution may vary across embodiments and may vary over time. For example, the distribution may vary based on demand, with additional hardware and/or software entities invoked to handle higher demand. In various embodiments, a load balancer may direct requests to one of multiple instantiations of the special purpose system. The hardware and/or software entities may be physically distinct and/or may share some hardware and/or software, such as in a virtualized environment. Multiple hardware entities may be referred to as a server rack, server farm, data center, etc.

### Software

The computer executable code may be created using a structured programming language such as C, an object oriented programming language such as C++, or any other high-level or low-level programming language (including assembly languages, hardware description languages, and database programming languages and technologies) that may be stored, compiled or interpreted to run on one of the devices described in the disclosure, as well as heterogeneous combinations of processors, processor architectures, or combinations of different hardware and software, or any other machine capable of executing program instructions. Computer software may employ virtualization, virtual machines, containers, dock facilities, portainers, and other capabilities.

Software includes instructions that are machine-readable and/or executable. Instructions may be logically grouped into programs, codes, methods, steps, actions, routines, functions, libraries, objects, classes, etc. Software may be stored by storage hardware or encoded in other hardware. Software encompasses (i) descriptive text to be parsed, such as HTML (hypertext markup language), XML (extensible markup language), and JSON (JavaScript Object Notation), (ii) assembly code, (iii) object code generated from source code by a compiler, (iv) source code for execution by an interpreter, (v) bytecode, (vi) source code for compilation and execution by a just-in-time compiler, etc. As examples only, source code may be written using syntax from languages including C, C++, JavaScript, Java, Python, R, etc.

Software also includes data. However, data and instructions are not mutually exclusive categories. In various embodiments, the instructions may be used as data in one or more operations. As another example, instructions may be derived from data.

The functional blocks and flowchart elements in this disclosure serve as software specifications, which can be translated into software by the routine work of a skilled technician or programmer.

Software may include and/or rely on firmware, processor microcode, an operating system (OS), a basic input/output system (BIOS), application programming interfaces (APIs), libraries such as dynamic-link libraries (DLLs), device drivers, hypervisors, user applications, background services, background applications, etc. Software includes native applications and web applications. For example, a web application may be served to a device through a browser using hypertext markup language 5th revision (HTML5).

Software may include artificial intelligence systems, which may include machine learning or other computational intelligence. For example, artificial intelligence may include one or more models used for one or more problem domains.

When presented with many data features, identification of a subset of features that are relevant to a problem domain may improve prediction accuracy, reduce storage space, and increase processing speed. This identification may be referred to as feature engineering. Feature engineering may be performed by users or may only be guided by users. In various implementations, a machine learning system may computationally identify relevant features, such as by performing singular value decomposition on the contributions of different features to outputs.

Examples of the models include recurrent neural networks (RNNs) such as long short-term memory (LSTM), deep learning models such as transformers, decision trees, support-vector machines, genetic algorithms, Bayesian networks, and regression analysis. Examples of systems based on a transformer model include bidirectional encoder representations from transformers (BERT) and generative pre-trained transformer (GPT).

Training a machine-learning model may include supervised learning (for example, based on labelled input data), unsupervised learning, and reinforcement learning. In various embodiments, a machine-learning model may be pre-trained by their operator or by a third party.

Problem domains include nearly any situation where structured data can be collected, and includes natural language processing (NLP), computer vision (CV), classification, image recognition, etc.

### Architectures

The methods and systems described herein may be deployed in part or in whole through machines that execute computer software on various devices including a server, client, firewall, gateway, hub, router, switch, infrastructure-as-a-service, platform-as-a-service, or other such computer and/or networking hardware or system. The software may be associated with a server that may include a file server, print server, domain server, internet server, intranet server, cloud server, infrastructure-as-a-service server, platform-as-a-service server, web server, and other variants such as secondary server, host server, distributed server, failover server, backup server, server farm, and the like. The server may include one or more of memories, processors, computer readable media, storage media, ports (physical and virtual), communication devices, and interfaces capable of accessing other servers, clients, machines, and devices through a wired or a wireless medium, and the like. The methods, programs, or codes as described herein and elsewhere may be executed by the server. In addition, other devices required for execution of methods as described in this application may be considered as a part of the infrastructure associated with the server.

The server may provide an interface to other devices including, without limitation, clients, other servers, printers, database servers, print servers, file servers, communication servers, distributed servers, social networks, and the like. Additionally, this coupling and/or connection may facilitate remote execution of programs across the network. The networking of some or all of these devices may facilitate parallel processing of a program or method at one or more locations without deviating from the scope of the disclosure. In addition, any of the devices attached to the server through an interface may include at least one storage medium capable of storing methods, programs, code and/or instructions. A central repository may provide program instructions to be executed on different devices. In this implementation, the remote repository may act as a storage medium for program code, instructions, and programs.

The software program may be associated with a client that may include a file client, print client, domain client, internet client, intranet client and other variants such as secondary client, host client, distributed client and the like. The client may include one or more of memories, processors, computer readable media, storage media, ports (physical and virtual), communication devices, and interfaces capable of accessing other clients, servers, machines, and devices through a wired or a wireless medium, and the like. The methods, programs, or codes as described herein and elsewhere may be executed by the client. In addition, other devices required for the execution of methods as described in this application may be considered as a part of the infrastructure associated with the client.

The client may provide an interface to other devices including, without limitation, servers, other clients, printers, database servers, print servers, file servers, communication servers, distributed servers and the like. Additionally, this coupling and/or connection may facilitate remote execution of programs across the network. The networking of some or all of these devices may facilitate parallel processing of a program or method at one or more locations without deviating from the scope of the disclosure. In addition, any of the devices attached to the client through an interface may include at least one storage medium capable of storing methods, programs, applications, code and/or instructions. A central repository may provide program instructions to be executed on different devices. In this implementation, the remote repository may act as a storage medium for program code, instructions, and programs.

In a client-server model, some of the software executes on first hardware identified functionally as a server, while other of the software executes on second hardware identified functionally as a client. The identity of the client and server is not fixed: for some functionality, the first hardware may act as the server while for other functionality, the first hardware may act as the client. In different embodiments and in different scenarios, functionality may be shifted between the client and the server. In one dynamic example, some functionality normally performed by the second hardware is shifted to the first hardware when the second hardware has less capability. In various embodiments, the term “local” may be used in place of “client,” and the term “remote” may be used in place of “server.”

Some or all of the software may run in a virtual environment rather than directly on hardware. The virtual environment may include a hypervisor, emulator, sandbox, container engine, etc. The software may be built as a virtual machine, a container, etc. Virtualized resources may be controlled using, for example, a DOCKER™ container platform, a pivotal cloud foundry (PCF) platform, etc.

Some or all of the software may be logically partitioned into microservices. Each microservice offers a reduced subset of functionality. In various embodiments, each microservice may be scaled independently depending on load, either by devoting more resources to the microservice or by instantiating more instances of the microservice. In various embodiments, functionality offered by one or more microservices may be combined with each other and/or with other software not adhering to a microservices model.

Some or all of the software may be arranged logically into layers. In a layered architecture, a second layer may be logically placed between a first layer and a third layer. The first layer and the third layer would then generally interact with the second layer and not with each other. In various embodiments, this is not strictly enforced—that is, some direct communication may occur between the first and third layers.

The methods, program codes, and instructions described herein and elsewhere may be implemented on or through mobile devices. The mobile devices may include navigation devices, cell phones, mobile phones, mobile personal digital assistants, laptops, palmtops, netbooks, pagers, electronic book readers, music players and the like. These devices may include, apart from other components, a storage medium such as flash memory, buffer, RAM, ROM and one or more computing devices. The computing devices associated with mobile devices may be enabled to execute program codes, methods, and instructions stored thereon. Alternatively, the mobile devices may be configured to execute instructions in collaboration with other devices. The mobile devices may communicate with base stations interfaced with servers and configured to execute program codes. The mobile devices may communicate on a peer-to-peer network, mesh network, or other communications network. The program code may be stored on the storage medium associated with the server and executed by a computing device embedded within the server. The base station may include a computing device and a storage medium. The storage device may store program codes and instructions executed by the computing devices associated with the base station.

### CONCLUSION

While only a few embodiments of the disclosure have been shown and described, it will be obvious to those skilled in the art that many changes and modifications may be made thereunto without departing from the spirit and scope of the disclosure as described in the following claims. All patent applications and patents, both foreign and domestic, and all other publications referenced herein are incorporated herein in their entireties to the full extent permitted by law.

While the disclosure has been disclosed in connection with the preferred embodiments shown and described in detail, various modifications and improvements thereon will become readily apparent to those skilled in the art. Accordingly, the spirit and scope of the disclosure is not to be limited by the foregoing examples, but is to be understood in the broadest sense allowable by law.

The use of the terms “a” and “an” and “the” and similar referents in the context of describing the disclosure (especially in the context of the following claims) is to be construed to cover both the singular and the plural, unless otherwise indicated herein or clearly contradicted by context. The terms “comprising,” “with,” “including,” and “containing” are to be construed as open-ended terms (i.e., meaning “including, but not limited to,”) unless otherwise noted. Recitations of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosure and does not pose a limitation on the scope of the disclosure unless otherwise claimed. The term “set” may include a set with a single member. No language in the specification should be construed as indicating any non-claimed element as essential to the practice of the disclosure.

While the foregoing written description enables one skilled to make and use what is considered presently to be the best mode thereof, those skilled in the art will understand and appreciate the existence of variations, combinations, and equivalents of the specific embodiment, method, and examples herein. The disclosure should therefore not be limited by the above-described embodiment, method, and examples, but by all embodiments and methods within the scope and spirit of the disclosure.

All documents referenced herein are hereby incorporated by reference as if fully set forth herein.

1. A crop growth modeling system comprising:
a memory configured to store computer-readable instructions that, when executed by at least one processor of a computing device, cause the computing device to use:
a digital twin component configured to create and manage a digital twin of a farm;
a data input component configured to receive data related to a defined set of land characteristics and environmental attributes for the farm;
a processing component configured to integrate the received data with the digital twin and to simulate at least one crop growth scenario based on the integrated data; and
a prediction component configured to determine a predicted crop growth rate for the farm based on the simulations conducted by the processing component.

2. The system of claim 1 wherein the digital twin component is further configured to update the digital twin in real-time based on continuous data input from at least one device associated with the farm.

3. The system of claim 2 wherein the at least one device includes sensors for measuring soil moisture, temperature, pH levels, and nutrient content.

4. The system of claim 2 wherein the at least one device includes an API associated with an application used in conjunction with operation of the farm.

5. The system of claim 1 wherein the processing component is configured to perform scenario analysis to evaluate and effect of different farming practices on predicted crop growth.

6. The system of claim 5 wherein the different farming practices include variations in irrigation schedules, fertilizer applications, and crop rotation strategies.

7. The system of claim 1 wherein the digital twin component is further configured to simulate an impact of climate variations on crop growth over a defined time period.

8. The system of claim 1 wherein the digital twin component is further configured to simulate an impact on crop growth includes using historical weather data to model potential future environmental conditions.

9. The system of claim 8 wherein the historical weather data is used to model scenarios including droughts and floods.

10. The system of claim 7 wherein the simulation includes variations in CO2 levels, temperature, and precipitation patterns.

11. The system of claim 1 wherein the prediction component is further configured to provide recommendations for optimizing crop yield based on the predicted growth rates.

12. The system of claim 11 wherein the recommendations include at least one specified adjustment to a planting date or harvesting time.

13. The system of claim 1 wherein the system is implemented as part of an integrated farm management platform that includes components for financial planning and market analysis.

14. A method for predicting crop growth rates in a farm, the method comprising:
collecting data related to land characteristics and environmental attributes of the farm;
creating a digital twin of the farm using the collected data;
integrating the collected data with the digital twin;
simulating crop growth scenarios using the integrated digital twin; and
determining a predicted crop growth rate for the farm based on the simulated crop growth scenarios.

15. The method of claim 14 wherein collecting data includes receiving input from remote sensing technologies.

16. The method of claim 15 wherein the remote sensing technologies are used to assess crop health and detect signs of disease or pest infestation.

17. The method of claim 14 wherein integrating the collected data with the digital twin includes aligning the data with a geographic information system (GIS) to enhance spatial accuracy.

18. The method of claim 17 wherein the GIS integration provides at least one recommendation for an application location of land enhancers including at least one of water or fertilizer based on a defined need of a section of the farm.

19. The method of claim 14 wherein of determining the predicted crop growth rate includes comparing at least one simulated outcome with actual crop performance data to refine a model.

20. The method of claim 19 wherein the actual crop performance data is collected through automated systems integrated within farm machinery.

21. A method for predicting an agricultural product need in a geographic region, comprising:
collecting data related to attributes of farmers in the geographic region, transactions made by farmers in the geographic region, and predicted climate characteristics in the geographic region during a prescribed time frame;
processing the collected data using a machine learning and artificial intelligence system; and
analyzing the processed data to predict at least one agricultural product need for the geographic region.

22. The method of claim 21 wherein the data related to attributes of farmers includes at least one of demographic data, economic data, or farming practice data.

23. The method of claim 21 wherein the transactions made by farmers include sales transactions, purchase transactions, or leasing transactions.

24. The method of claim 21 wherein the predicted climate characteristics include temperature, rainfall, or humidity levels.

25. The method of claim 21 further comprising updating the predictions in real-time based on real-time environmental data received.

26. The method of claim 21 wherein processing and analyzing utilizes a neural network model.

27. The method of claim 21 wherein processing and analyzing utilizes a decision tree model.

28. The method of claim 21 wherein the predictions are further used to optimize supply chain logistics for at least one agricultural product in the geographic region.

29. The method of claim 21 wherein the predictions are used to advise a farmer on optimal planting and harvesting times.

30. The method of claim 21 wherein the data processing includes data normalization and data cleaning steps.

31. The method of claim 21 wherein the machine learning and artificial intelligence system is configured to learn continuously from new data inputs to improve prediction accuracy.

32. A system for predicting an agricultural product need in a geographic region, comprising:
a memory configured to store computer-readable instructions that, when executed by at least one processor of a computing device, cause the computing device to use:
a data collection component configured to collect data concerning attributes of farmers in the geographic region, transactions made by farmers, and predicted climate characteristics during a prescribed time frame;
a machine learning and artificial intelligence component configured to process and analyze the collected data; and
an output component configured to provide at least one prediction for an agricultural product need based on the analyzed data.

33. The system of claim 32 wherein the data collection component is further configured to receive inputs from at least one device associated with the geographic region.

34. The system of claim 32 wherein the machine learning and artificial intelligence component uses reinforcement learning techniques.

35. The system of claim 32 wherein the output component is configured to generate visual representations of the predicted agricultural product need.

36. The system of claim 32 wherein the output component is configured to send notifications to stakeholders about the predicted agricultural product need.

37. The system of claim 32 wherein the data collection component includes a user interface for manual data entry by a user associated with the geographic region.

38. The system of claim 32 wherein the machine learning and artificial intelligence component is further configured to perform predictive maintenance on farming equipment based on the collected data.

39. The system of claim 32 wherein the output component includes an integration with a marketplace platform for at least one agricultural product.

40. The system of claim 32 wherein the system is implemented as a cloud-based service accessible to multiple stakeholders in an agricultural sector.

41. A computer-implemented method for predicting agricultural product needs and optimizing procurement workflows, the method comprising:
receiving data inputs including attributes of farmers, transaction histories of farmers, and predicted climate characteristics for a geographic region during a prescribed time frame;
processing the received data using a machine learning and artificial intelligence system to predict the need for at least one agricultural product in the geographic region; and
optimizing a procurement workflow to acquire or ship the at least one predicted needed agricultural product to a location in proximity to the geographic region.

42. The method of claim 41 wherein the attributes of farmers include at least one of: farm size, crop types, historical yield data, and equipment usage.

43. The method of claim 42 wherein the transaction histories include purchases of seeds, fertilizers, and agricultural chemicals.

44. The method of claim 41 wherein the predicted climate characteristics are obtained from a third-party weather forecasting service.

45. The method of claim 41 further comprising using a neural network within the machine learning and artificial intelligence system to process the data.

46. The method of claim 41 wherein the optimizing of the procurement workflow includes automated contracting with suppliers.

47. The method of claim 46 wherein the automated contracting includes the use of smart contracts on a blockchain platform.

48. The method of claim 41 wherein the optimization includes scheduling shipments based on predicted optimal delivery times.

49. The method of claim 48 wherein the scheduling of shipments is adjusted in real-time based on updates to the predicted climate characteristics.

50. The method of claim 41 wherein the data inputs are further processed to identify trends and anomalies in farmer behavior and climate conditions.

51. The method of claim 50 wherein identified trends are used to adjust the predictions of agricultural product needs.

52. A system for predicting agricultural product needs and optimizing procurement workflows, the system comprising:
a memory configured to store computer-readable instructions that, when executed by at least one processor of a computing device, cause the computing device to use:
a data input module configured to collect data relating to attributes of farmers, transaction histories of farmers, and predicted climate characteristics for a geographic region during a prescribed time frame;
a machine learning and artificial intelligence module configured to analyze the collected data and predict the need for at least one agricultural product in the geographic region; and
a procurement optimization module configured to manage an acquisition and shipment of the at least one predicted needed agricultural product to a location in proximity to the geographic region.

53. The system of claim 52 wherein the data input module is further configured to receive real-time updates on farmer activities and climate changes.

54. The system of claim 52 wherein the machine learning and artificial intelligence module utilizes regression analysis to predict the agricultural product needs.

55. The system of claim 54 wherein the regression analysis includes polynomial regression techniques.

56. The system of claim 52 wherein the procurement optimization module is configured to select suppliers based on at least one of cost, proximity, and reliability.

57. The system of claim 56 wherein the selection of suppliers is further based on historical performance data stored within the system.

58. The system of claim 52 wherein the procurement optimization module includes an interface for manual override by a system operator.

59. The system of claim 52 wherein the machine learning and artificial intelligence module is further configured to generate reports on predicted product needs for review by stakeholders.

60. The system of claim 52 wherein the machine learning and artificial intelligence module is further configured to update its predictive models based on feedback received from the procurement optimization module regarding a success of previous procurement workflows.

61. A computer-implemented method for automatically generating an insurance policy offer for a farm, the method comprising:
receiving, by one or more processors, data relating to climate attributes of a geographic region in which the farm is located;
accessing, by the one or more processors, historical insurance claims made by farmers in the geographic region;
retrieving, by the one or more processors, data regarding crop productivity of farms in the geographic region;
predicting, by the one or more processors, crop performance characteristics in the geographic region during a prescribed time frame; and
generating, by the one or more processors, an insurance policy offer for the farm based on the received, accessed, retrieved, and predicted data.

62. The method of claim 61 wherein the data relating to climate attributes includes temperature, rainfall, and humidity data.

63. The method of claim 62 wherein the historical insurance claims data includes data related to crop damage due to weather events.

64. The method of claim 63 wherein the data regarding crop productivity includes yield per acre and quality of crop produced.

65. The method of claim 64 wherein the prediction of crop performance characteristics includes use of a machine learning model trained on historical crop performance data.

66. The method of claim 65 wherein the machine learning model is further trained using real-time climate data.

67. The method of claim 61 further comprising adjusting the insurance policy offer based on predicted economic conditions in the geographic region.

68. The method of claim 67 wherein the predicted economic conditions include market prices for crops commonly grown in the geographic region.

69. The method of claim 61 wherein calculating a risk score based on the accessed, retrieved, and predicted data.

70. The method of claim 69 wherein the risk score influences a premium of the insurance policy offer.

71. The method of claim 61 further comprising providing the generated insurance policy offer to the farmer via a digital platform.

72. A system for automatically generating an insurance policy offer for a farm, the system comprising:
a memory configured to store computer-readable instructions that, when executed by at least one processor of a computing device, cause the computing device to use:
a data reception component configured to receive data relating to climate attributes of a geographic region in which the farm is located;
a data access component configured to access historical insurance claims made by farmers in the geographic region;
a data retrieval component configured to retrieve data regarding crop productivity of farms in the geographic region;
a prediction component configured to predict crop performance characteristics in the geographic region during a prescribed time frame; and
an insurance policy generation component configured to generate an insurance policy offer for the farm based on the data received, accessed, retrieved, and predicted by the respective components.

73. The system of claim 72 wherein the data reception component is further configured to receive real-time climate data from Internet of Things (IOT) devices.

74. The system of claim 73 wherein the data access component is further configured to access data from a blockchain ledger containing historical insurance claims.

75. The system of claim 74 wherein the data retrieval component is further configured to interface with agricultural databases for crop productivity data.

76. The system of claim 75 wherein the prediction component utilizes a neural network to predict crop performance characteristics.

77. The system of claim 76 wherein the insurance policy generation component is further configured to customize the insurance policy offer based on farmer preferences.

78. The system of claim 72 wherein the prediction component is further configured to update predictions based on feedback received from policyholders.

79. The system of claim 78 wherein the feedback includes data on accuracy of previous crop performance predictions.

80. The system of claim 72 wherein the insurance policy generation component is integrated with a digital farming management platform.

81. A computer-implemented method for improving a productivity metric of a farm, comprising:
automatically monitoring operational data of the farm using a machine learning and artificial intelligence system;
wherein the operational data includes sensor data derived from implements associated with the farm, environmental data, financial data, and simulated data;
wherein the simulated data is based in part on predicted climate characteristics of a current growing season on the farm;
producing automated recommendations of procedural changes to implement to improve the productivity metric of the farm; and
providing a generative-AI interface through which a user queries the machine learning and artificial intelligence system for recommended procedural changes.

82. The method of claim 81 wherein the sensor data includes data from soil moisture sensors.

83. The method of claim 82 wherein the sensor data further includes data from weather stations located on the farm.

84. The method of claim 81 wherein the environmental data includes data related to air quality and temperature.

85. The method of claim 81 wherein the financial data includes data related to costs of inputs such as seeds, fertilizers, and pesticides.

86. The method of claim 81 wherein the simulated data includes output from crop growth models.

87. The method of claim 86 wherein the crop growth models take into account historical yield data of the farm.

88. The method of claim 81 wherein the productivity metric is crop yield.

89. The method of claim 88 wherein the procedural changes include changes in irrigation schedules.

90. The method of claim 89 wherein the changes in irrigation schedules are based on soil moisture data.

91. A system for improving a productivity metric of a farm, comprising:
a processor; and
a memory storing instructions that, when executed by the processor, cause the system to:
monitor operational data of the farm automatically using a machine learning and artificial intelligence system;
wherein the operational data includes sensor data derived from implements associated with the farm, environmental data, financial data, and simulated data;
wherein the simulated data is based in part on predicted climate characteristics of a current growing season on the farm;
generate automated recommendations of procedural changes to improve the productivity metric of the farm; and
provide a generative-AI interface for user interaction to query for recommended procedural changes.

92. The system of claim 91 wherein the generative-AI interface includes a natural language processing model.

93. The system of claim 92 wherein the natural language processing model is trained specifically on agricultural terminology.

94. The system of claim 91 wherein the machine learning and artificial intelligence system includes a neural network.

95. The system of claim 94 wherein the neural network is configured to perform regression analysis to predict future productivity metrics based on current operational data.

96. The system of claim 91 wherein the machine learning and artificial intelligence system is configured to update its models in real-time based on incoming operational data.

97. The system of claim 91 wherein the user can customize a type of procedural changes the system recommends.

98. The system of claim 97 wherein the user can set preferences for cost-effectiveness of the recommended procedural changes.

99. The system of claim 91 further comprising a component for generating reports on effectiveness of implemented procedural changes.

100. The system of claim 99 wherein the reports include comparisons of predicted and actual changes in the productivity metric.

101. A system of platforms for agricultural monitoring and remote decision-making support, the system of platforms comprising:
a memory configured to store computer-readable instructions that, when executed by at least one processor of a computing device, cause the computing device to use:
an analysis module, wherein an artificial intelligence module receives external data through a security layer, performs data processing and analytics, and shares at least one output with a segment analysis module, a configured intelligence service or a stakeholder service module, and a reporting and optimization module produces a report for distribution;
a stakeholder systems integration module, wherein results-based analysis and feedback is performed; and
a stakeholder systems module, wherein stakeholder-adapted services and reporting, and stakeholder-specific configured intelligence services are performed.
